(19) United States
(12) Patent Application Publication
(10) Pub. No.: US 2007/0216292 A1
(43) Pub. Date: Sep. 20, 2007

(54) Composite Material Including organic Compound And Inorganic Compound Light-Emitting Element And Light-Emitting Device Using The Composite Compound, And Manufacturing Method Of The Light-Emitting Element

(76) Inventors: Satoshi Seo, Kanagawa (JP); Satoko Shitagaki, Kanagawa (JP); Hiroko Abe, Tokyo (JP); Takako Takasu, Kanagawa (JP); Ryoji Nomura, Kanagawa (JP)

Correspondence Address: COOK, ALEX, MCFARRON, MANZO, CUMMINGS & MEHLER LTD, SUITE 2850, 200 WEST ADAMS STREET, CHICAGO, IL, 60606, US

(21) Appl. No.: 11/659,900

(22) PCT Filed: Dec. 2, 2005
(86) PCT No.: PCT/JP05/22602

§ 371 Date: Feb. 9, 2007

(30) Foreign Application Priority Data
Dec. 6, 2004 (JP) 2004-353452
Dec. 6, 2004 (JP) 2004-353449
Dec. 6, 2004 (JP) 2004-353450

(51) Int. Cl. H01L 51/54; H01L 51/56

(52) U.S. Cl. 313/506; 428/690; 428/917; 313/504; 427/66; 257/E51.026; 257/E51.033; 257/E51.036

(57) ABSTRACT

The present invention provides a composite material having high conductivity, a light-emitting element and a light-emitting device using the composite material. Further, the present invention provides a manufacturing method of a light-emitting element which is suitable for mass production. A light-emitting element of the present invention includes a layer including a luminescent substance between a pair of electrodes. The layer including a luminescent substance has a composite material which includes an organic compound, and an inorganic compound showing an electron donating property to the organic compound. Since the light-emitting element of the present invention includes a composite material made by combining an organic compound and an inorganic compound, the carrier injecting property, carrier transporting property, and conductivity thereof are excellent, and thus, the driving voltage can be reduced.

### TECHNICAL FIELD

The present invention relates to a composite material including an organic compound and an inorganic compound. Further, the present invention relates to a light-emitting element having a layer including a luminescent substance between a pair of electrodes, and a manufacturing method thereof. Moreover, the present invention relates to a light-emitting device using a light-emitting element.

### BACKGROUND ART

A light-emitting element using a light-emitting material has features of thinness, lightness in weight, high response speed, low direct-current voltage drive, and the like, and is expected to be applied to the next-generation flat panel displays. A light-emitting device in which light-emitting elements are arranged in matrix is said to have superiority in wide viewing angle and high visibility as compared with conventional liquid crystal display devices.

A basic structure of a light-emitting element is a structure in which a layer containing a light-emitting organic compound is interposed between a pair of electrodes. By applying voltage to the element, electrons from one of the pair of electrodes and holes from the other electrode are transported to a light-emitting layer, so that current flows. The electrons and holes (i.e., carriers) are recombined, and thus, the light-emitting organic compound is excited. The light-emitting organic compound returns to a ground state from the excited state, thereby emitting light.

It is to be noted that the excited state generated by an organic compound can be a singlet excited state or a triplet excited state, and luminescence from the singlet excited state is referred to as fluorescence, and luminescence from the triplet excited state is referred to as phosphorescence.

Since light-emitting element like this is usually formed by using a thin film with a thickness approximately on the order of submicron, it is a great advantage that the light-emitting element can be manufactured to be thin and lightweight. In addition, since it takes the time on the order of microseconds or less to generate luminescence after carrier injection, it is also one of the features that the speed of response is quite fast. Further, since sufficient luminescence can be obtained at a direct-current voltage of several to several tens of volts, the power consumption is relatively low. From these advantages, light-emitting elements have attracted a lot of attention as the elements for the next-generation flat panel displays. In particular, the light-emitting elements are expected to be applied to mobile devices and the like, taking advantage of the features of thinness, lightness in weight and the like.

For example, when such light-emitting elements are applied to mobile devices and the like, power consumption needs to be low, and thus, further decrease in driving voltage becomes necessary. For this reason, electron injecting layers and hole injecting layers have been devised in various ways.

For example, there is a report that driving voltage is reduced by using a layer formed by co-evaporation of an organic compound and an alkali metal salt or an alkali metal oxide, as an electron injecting layer (Reference 1: Japanese Patent Laid-Open No. H10-270172).

Further, there is a report that driving voltage is reduced by using a layer combining a high molecular weight compound having an arylamine skeleton and an electron accepting compound as a hole injecting layer (Reference 2: Japanese Patent Laid-Open No. 2000-150169). It is considered that charge transfer occurs by using the high molecular weight compound having an arylamine skeleton and the electron accepting compound in combination, and thus, driving voltage is reduced.

Furthermore, there is also a report that a hole injecting layer by the conception similar to that of Reference 2 is used to achieve a light-emitting element that can operate at a low voltage, even when the thickness is as thick as 650 nm (Reference 3: Asuka Yamamori, and three others, Applied Physics Letters, vol.72, No. 17, pp. 2147-2149 (1998)). It is reported that such materials are superior in conductivity.

However, the electron injecting layer disclosed in Reference 1 can be formed only by a vacuum evaporation method. The vacuum evaporation method is not suitable for mass-production, since it is difficult to respond to increase in substrate size.

Since the hole injecting layer disclosed in References 2 and 3 is formed by a wet method, it is easy to respond to an increase in substrate size. However, a highly acidic compound is used as an electron accepting compound, and thus, there is a problem such as corrosion of an electrode. Further, the antimony compound used in References 2 and 3 is highly toxic. Therefore, there are fears of the antimony compound having adverse affects on the environment or on human body, and thus, it is not suitable for industrial use.

### DISCLOSURE OF INVENTION

In view of the above problems, it is an object of the present invention to provide a highly conductive composite material, a light-emitting element and a light-emitting device each using the composite material. Further, it is another object of the present invention to provide a manufacturing method of a light-emitting element which is suitable for mass production.

The present inventors have found that the above objects can be achieved by forming a composite material containing an organic compound, and an inorganic compound showing an electron accepting property to the organic compound by a wet method.

In the present invention, in consideration of film-quality when a film is formed by a wet method, and in the case where the organic compound is a low molecular weight compound, a composite material of the present invention further includes a material which serves as a binder (hereinafter, a binder substance). In addition, in the case where the organic compound is a high molecular weight compound (in this specification, the category of the high molecular weight compound includes compounds having middle molecular weight such as oligomer or dendrimer), a composite material of the present invention may additionally include a binder substance; however, it is not necessarily required.

In other words, a structure of the present invention is a composite material including an organic compound, a binder substance, and an inorganic compound showing an electron donating property to the organic compound.

Another structure of the present invention is a composite material including an organic compound of a high molecular weight compound, and an inorganic compound showing an electron donating property to the organic compound.

Note that, in the composite material of the present invention, the binder substance is preferably polyvinyl alcohol, polymethyl methacrylate, polycarbonate, or a phenol resin. In addition, the organic compound preferably has one or plural of a pyridine skeleton, an imidazole skeleton, a triazole skeleton, an oxadiazole skeleton, a thiadiazole skeleton, an oxazole skeleton, and a thiazole skeleton. The inorganic compound is preferably an oxide containing an alkali metal or an alkaline earth metal, specifically, one or plural of lithium oxide, calcium oxide, and barium oxide.

An oxide of the alkali metals or the alkaline earth metals described above may include a hydroxyl group.

In addition, a light-emitting element using the above-described composite material of the present invention is also one mode of the present invention. It should be noted that a layer including a composite material of the present invention is provided in such a location that the layer is in contact with an electrode of the light-emitting element, thereby reducing the driving voltage of the light-emitting element. Alternatively, a structure in which a layer including a composite material of the present invention and a layer generating holes are stacked, is provided in such a location that the structure is in contact with an electrode of the light-emitting element, thereby reducing the driving voltage of the light-emitting element.

A structure of the present invention is a light-emitting element comprising a layer including a luminescent substance between a pair of electrodes, wherein the layer including a luminescent substance includes an organic compound, a binder substance and an inorganic compound showing an electron donating property to the organic compound.

Another structure of the present invention is a light-emitting element comprising a layer including a luminescent substance between a pair of electrodes, wherein a layer which is included in the layer including a luminescent substance, and is in contact with one electrode of the pair of electrodes, includes an organic compound, a binder substance, and an inorganic compound showing an electron donating property to the organic compound.

Another structure of the present invention is a light-emitting element comprising a layer including a luminescent substance between a pair of electrodes, wherein the layer including a luminescent substance includes a first layer, a second layer, and a third layer, which are each stacked sequentially; wherein the first layer includes a luminescent substance; wherein the second layer includes an organic compound, a binder substance and an inorganic compound showing an electron donating property to the organic compound; and wherein the third layer includes a material generating holes.

Another structure of the present invention is a light-emitting element comprising a layer including a luminescent substance between a pair of electrodes, wherein the layer including a luminescent substance includes an organic compound which is a high molecular weight compound, and an inorganic compound showing an electron donating property to the organic compound.

Another structure of the present invention is a light-emitting element comprising a layer including a luminescent substance between a pair of electrodes, wherein a layer which is included in the layer including a luminescent substance, and is in contact With one electrode of the pair of electrodes, includes an organic compound which is a high molecular weight compound, and an inorganic compound showing an electron donating property to the organic compound.

Another structure of the present invention is a light-emitting element comprising a layer including a luminescent substance between a pair of electrodes, wherein the layer including a luminescent substance includes a first layer, a second layer, and a third layer, which are each stacked sequentially; wherein the first layer includes a luminescent substance; wherein the second layer includes an organic compound which is a high molecular weight compound, and an inorganic compound showing an electron donating property to the organic compound; and wherein the third layer includes a material generating holes.

In the light-emitting element of the present invention as described above, the binder substance is preferably polyvinyl alcohol, polymethyl methacrylate, polycarbonate or a phenol resin. In addition, the organic compound has one or plural of a pyridine skeleton, an imidazole skeleton, a triazole skeleton, an oxadiazole skeleton, a thiadiazole skeleton, an oxazole skeleton, and a thiazole skeleton. Moreover, the inorganic compound is preferably an oxide including an alkali metal or an alkaline earth metal, specifically, one or plural of lithium oxide, calcium oxide, and barium oxide is/are preferable.

Further, a light-emitting device having a light-emitting element described above is also one mode of the present invention. Note that the category of the light-emitting element of the present invention includes an image display device and a light-emitter using a light-emitting element. In addition, a module that has a connector, for example, a flexible printed circuit (FPC), a TAB (Tape Automated Bonding) tape, or a TCP (Tape Carrier Package), attached to a light-emitting element; a module that has a printed wiring board provided at the tip of a TAB tape or a TCP; and a module that has an IC (integrated circuit) directly mounted on a light-emitting element by a COG (Chip On Glass) method, are all included in the category of the light-emitting device.

A manufacturing method of a light-emitting element according to the present invention is based on a novel concept, and is also one mode of the present invention. One feature of the present invention is that a layer including an organic compound and an inorganic compound showing an electron donating property to the organic compound, is formed by a wet method. Further, a method in which layers are formed over the first electrode and another method in which layers are formed over the second electrode, can be considered.

Therefore, a structure of the present invention is a manufacturing method of a light-emitting element, comprising the steps of forming a first layer including a luminescent substance over a first electrode; forming, by a wet method, a second layer including an organic compound, and an inorganic compound showing an electron donating property to the organic compound over the first layer; and forming a second electrode over the second layer.

Another structure of the present invention is a manufacturing method of a light-emitting element, comprising the steps of forming, by a wet method, a second layer including an organic compound, and an inorganic compound showing an electron donating property to the organic compound over a second electrode; forming a first layer including a luminescent substance over the second layer; and forming a first electrode over the first layer.

Another structure of the present invention is a manufacturing method of a light-emitting element, comprising the steps of forming a first layer including a luminescent substance over a first electrode; forming, by a wet method, a second layer including an organic compound, and an inorganic compound showing an electron donating property to the organic compound; forming a third layer which generates holes over the second layer; and forming a second electrode over the third layer.

Another structure of the present invention is a manufacturing method of a light-emitting element, comprising the steps of forming a third layer which generates holes over a second electrode; forming, by a wet method, a second layer including an organic compound, and an inorganic compound showing an electron donating property to the organic compound over the third layer; forming a first layer including a luminescent substance over the second layer; and forming a first electrode over the first layer.

In the manufacturing method of a light-emitting element described above, the second layer can be formed by applying a solution including a metal alkoxide and an organic compound and baking it. At this time, hydrolysis is preferably conducted using water, and thus, the film formed by applying the solution may be exposed to water vapor before baking.

Therefore, a structure of the present invention is a manufacturing method of a light-emitting element, wherein the step of forming the second layer is a step of applying a solution of a metal alkoxide and an organic compound, and baking it; or a step of applying a solution including a metal alkoxide and an organic compound, exposing it to water vapor, and then, baking it.

In the method using a metal alkoxide described above, the solution may additionally include a stabilizer to prevent precipitation. As the stabilizer, β-diketones such as acetylacetone, ethyl acetoacetate, or benzoylacetone are preferred. In addition, the solution may additionally include water so as to promote hydrolysis of a metal alkoxide. The solution may also include a binder substance. As the binder substance, polyvinyl alcohol, polymethyl methacrylate, polycarbonate or a phenol resin is preferred.

Further, in the manufacturing method of a light-emitting element according to the present invention, the organic compound preferably has one or plural of a pyridine skeleton, an imidazole skeleton, a triazole skeleton, an oxadiazole skeleton, a thiadiazole skeleton, an oxazole skeleton, and a thiazole skeleton.

In addition, by the manufacturing method of a light-emitting element according to the present invention, a metal oxide having a strong electron donating property is formed from the metal alkoxide. Therefore, the metal is preferably an alkali metal or an alkaline earth metal. In particular, lithium, calcium, and barium are preferred.

The present inventors have found that the above described objects can be achieved by applying a composite material including an organic compound and an inorganic compound showing an electron accepting property to the organic compound, to a light-emitting element. Specifically, the present inventors have found that the objects can be achieved by employing a wet method to form the composite material when a light-emitting element is manufactured. It should be noted that a layer including the composite material is provided in such a location that the layer is in contact with an electrode of a light-emitting element, thereby lowering driving voltage of the light-emitting element. Alternatively, a structure in which a layer including a composite material of the present invention and a layer including a material generating electrons are stacked, is provided in such a location that the structure is in contact with an electrode of the light-emitting element, thereby reducing the driving voltage of the light-emitting element.

In the present invention, in consideration of film quality when a film is formed by a wet method, the composite material further includes a material which serves as a binder (hereinafter, a binder substance), in the case where the organic compound is a low molecular weight compound. In addition, in the case where the organic compound is a high molecular weight compound (in this specification, the category of the high molecular weight compound includes compounds having middle molecular weight such as oligomer or dendrimer), the composite material may further include a binder substance; however, it is not necessarily required.

Therefore, a structure of the present invention is a light-emitting element comprising a layer including a luminescent substance between a pair of electrodes, wherein the layer including a luminescent substance includes an organic compound, a binder substance and an inorganic compound showing an electron accepting property to the organic compound.

In addition, another structure of the present invention is a light-emitting element comprising a layer including a luminescent substance between a pair of electrodes, wherein a layer which is included in the layer including a luminescent substance, and is in contact with one electrode of the pair of electrodes, includes an organic compound, a binder substance, and an inorganic compound showing an electron accepting property to the organic compound.

Another structure of the present invention is a light-emitting element comprising a layer including a luminescent substance between a pair of electrodes, wherein the layer including a luminescent substance includes a first layer, a second layer, a third layer, and a fourth layer, which are each stacked sequentially; wherein the first layer includes a composite material having an organic compound, a binder substance, and an inorganic compound showing an electron accepting property to the organic compound, wherein the second layer includes a luminescent substance; wherein the third layer includes a material generating electrons; and wherein the fourth layer includes a material generating holes. Note that the fourth layer can be formed using a composite material of the present invention.

Another structure of the present invention is a light-emitting element comprising a layer including a luminescent substance between a pair of electrodes, wherein the layer including a luminescent substance includes a first layer, a second layer, a third layer, and a fourth layer, which are each stacked sequentially; wherein the first layer includes a material generating holes; wherein the second layer includes a luminescent substance; wherein the third layer includes a material generating electrons; and wherein the fourth layer includes a composite material having an organic compound, a binder substance, and an inorganic compound showing an electron accepting property to the organic compound.

Another structure of the present invention is a light-emitting element comprising a layer including a luminescent substance between a pair of electrodes, wherein the layer including a luminescent substance includes a high molecular weight compound, and an inorganic compound showing an electron accepting property to the organic compound.

Another structure of the present invention is a light-emitting element comprising a layer including a luminescent substance between a pair of electrodes, wherein a layer which is included in the layer including a luminescent substance, and is in contact with one electrode of the pair of electrodes, includes an organic compound which is a high molecular weight compound, and an inorganic compound showing an electron accepting property to the organic compound.

Another structure of the present invention is a light-emitting element comprising: a layer including a luminescent substance between a pair of electrodes, wherein the layer including a luminescent substance includes a first layer, a second layer, a third layer, and a fourth layer, which are each stacked sequentially; wherein the first layer includes a composite material having an organic compound which is a high molecular weight compound, and an inorganic compound showing an electron accepting property to the organic compound, wherein the second layer includes a luminescent substance; wherein the third layer includes a material generating electrons; and wherein the fourth layer includes a material generating holes. Note that the fourth layer can be formed using a composite material of the present invention at this time.

Another structure of the present invention is a light-emitting element comprising a layer including a luminescent substance between a pair of electrodes, wherein the layer including a luminescent substance includes a first layer, a second layer, a third layer, and a fourth layer, which are each stacked sequentially; wherein the first layer includes a material generating holes; wherein the second layer includes a luminescent substance; wherein the third layer includes a material generating electrons; and wherein the fourth layer includes a composite material having an organic compound which is a high molecular weight compound, and an inorganic compound showing an electron accepting property to the organic compound.

In the above light-emitting element of the present invention, the binder substance is preferably polyvinyl alcohol, polymethyl methacrylate, polycarbonate or a phenol resin.

The organic compound preferably has an arylamine skeleton. Alternatively, the organic compound is preferably any one of high molecular weight compounds represented by general formulas (1) to (10).

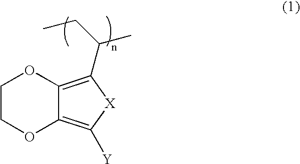

wherein X represents an oxygen atom (O) or a sulfur atom (S). Y represents a hydrogen atom, an alkyl group, an aryl group, or a silyl group having an alkyl group or an aryl group as a substituent. n is an integer of 2 or more.

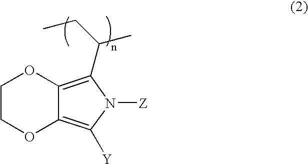

wherein Y represents a hydrogen atom, an alkyl group, an aryl group, or a silyl group having an alkyl group or an aryl group as a substituent. Z represents one of a hydrogen atom, an alkyl group, and a substituted or unsubstituted aryl group. n is an integer of 2 or more.

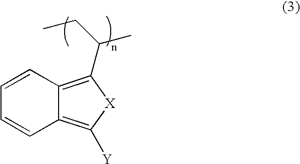

wherein X represents an oxygen atom (O) or a sulfur atom (S). Y represents a hydrogen atom, an alkyl group, an aryl group, or a silyl group having an alkyl group or an aryl group as a substituent. n is an integer of 2 or more.

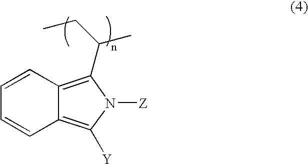

wherein Y represents a hydrogen atom, an alkyl group, an aryl group, or a silyl group having an alkyl group or an aryl group as a substituent. Z represents one of a hydrogen atom, an alkyl group, and a substituted or unsubstituted aryl group. n is an integer of 2 or more.

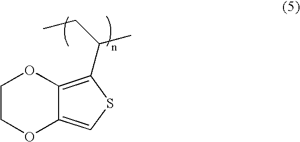

wherein n is an integer of 2 or more.

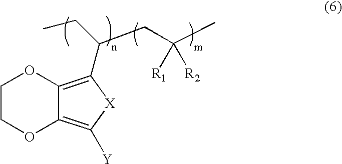

wherein X represents an oxygen atom (O) or a sulfur atom (S). Y represents a hydrogen atom, an alkyl group, an aryl group, or a silyl group having an alkyl group or an aryl group as a substituent. R₁ represents a hydrogen atom or an alkyl group. R₂ represents a substituted or unsubstituted aryl group, an ester group, a cyano group, an amide group, an alkoxy group, an oxycarbonyl alkyl group, or a diaryl amino group. n and m are individually an integer of 1 or more.

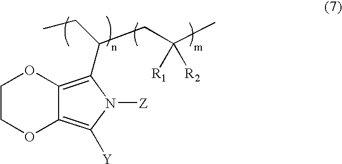

wherein Y represents a hydrogen atom, an alkyl group, an aryl group, or a silyl group having an alkyl group or an aryl group as a substituent. Z represents one of a hydrogen atom, an alkyl group, and a substituted or unsubstituted aryl group. R₁ represents a hydrogen atom or an alkyl group. R₂ represents a substituted or unsubstituted aryl group, an ester group, a cyano group, an amide group, an alkoxy group, an oxycarbonyl alkyl group, or a diaryl amino group. n and m are individually an integer of 1 or more.

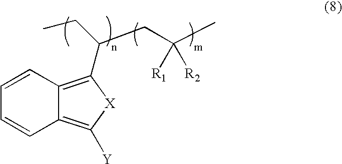

wherein X represents an oxygen atom (O) or a sulfur atom (S). Y represents a hydrogen atom, an alkyl group, an aryl group, or a silyl group having an alkyl group or an aryl group as a substituent. R₁ represents a hydrogen atom or an alkyl group. R₂ represents a substituted or unsubstituted aryl group, an ester group, a cyano group, an amide group, an alkoxy group, an oxycarbonyl alkyl group, or a diaryl amino group. n and m are individually an integer of 1 or more.

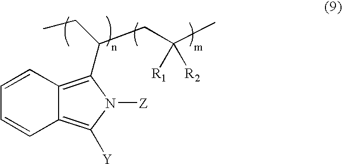

wherein Y represents a hydrogen atom, an alkyl group, an aryl group, or a silyl group having an alkyl group or an aryl group as a substituent. Z represents one of a hydrogen atom, an alkyl group, and a substituted or unsubstituted aryl group. R₁ represents a hydrogen atom or an alkyl group. R₂ represents a substituted or unsubstituted aryl group, an ester group, a cyano group, an amide group, an alkoxy group, an oxycarbonyl alkyl group, or a diaryl amino group. n and m are individually an integer of 1 or more.

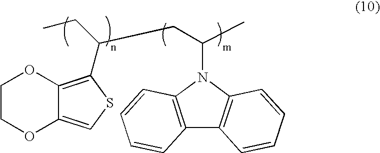

wherein n and m are individually an integer of 1 or more.

Moreover, in the above light-emitting element of the present invention, the inorganic compound is preferably an oxide containing a transition metal, in particular, titanium oxide, vanadium oxide, molybdenum oxide, tungsten oxide, rhenium oxide, and ruthenium oxide are preferred.

Further, a light-emitting device having a light-emitting element described above is also one mode of the present invention. Note that the category of the light-emitting element of the present invention includes an image display device and a light-emitter using a light-emitting element. In addition, a module that has a connector, for example, a flexible printed circuit (FPC), a TAB (Tape Automated Bonding) tape, or a TCP (Tape Carrier Package), attached to a light-emitting element; a module that has a printed wiring board provided at the tip of a TAB tape or a TCP; and a module that has an IC (integrated circuit) directly mounted on a light-emitting element by a COG (Chip On Glass) method, are all included in the category of the light-emitting device.

A manufacturing method of a light-emitting element according to the present invention is based on a novel concept, and is also one mode of the present invention. One feature of the present invention is that a layer including a composite material which includes an organic compound described above and an inorganic compound showing an electron accepting property to the organic compound, is formed by a wet method. Also, a method in which layers are formed over the first electrode and another method in which layer are formed over the second electrode, can be considered.

A structure of the present invention is a manufacturing method of a light-emitting element, comprising the steps of forming, by a wet method, a first layer including an organic compound, and an inorganic compound showing an electron accepting property to the organic compound over a first electrode; forming a second layer including a luminescent substance over the first layer; and forming a second electrode over the second layer.

Another structure of the present invention is a manufacturing method of a light-emitting element, comprising the steps of forming a second layer including a luminescent substance over a second electrode; forming, by a wet method, a first layer including an organic compound, and an inorganic compound showing an electron accepting property to the organic compound over the second layer; and forming a first electrode over the first layer.

Another structure of the present invention is a manufacturing method of a light-emitting element, comprising the steps of forming, by a wet method, a first layer including an organic compound, and an inorganic compound showing an electron accepting property to the organic compound over a first electrode; forming a second layer including a luminescent substance over the first layer; forming a third layer including a material generating electrons over the second layer; forming a fourth layer including a material generating holes over the third layer; and forming a second electrode over the fourth layer. Note that the fourth layer may be formed by a wet method, as well as the first layer, or may be formed by another method, for example an evaporation method.

Another structure of the present invention is a manufacturing method of a light-emitting element, comprising the steps of forming a fourth layer including a material generating holes over a second electrode; forming a third layer including a material generating electrons over the fourth layer; forming a second layer including a luminescent substance over the third layer; forming, by a wet method, a first layer including an organic compound, and an inorganic compound showing an electron donating property to the organic compound over the second layer; and forming a first electrode over the first layer. Note that the fourth layer may be formed by a wet method, as well as the first layer, or may be formed by another method, for example an evaporation method.

Another structure of the present invention is a manufacturing method of a light-emitting element comprising the steps of forming a first layer including a material generating holes over a first electrode; forming a second layer including a luminescent substance over the first layer; forming a third layer including a material generating electrons over the second layer; forming, by a wet method, a fourth layer including an organic compound and an inorganic compound showing an electron accepting property to the organic compound over the third layer; and forming a second electrode over the fourth layer. Note that the first layer may be formed by a wet method, as well as the fourth layer, or may be formed by another method, for example an evaporation method.

Another structure of the present invention is a manufacturing method of a light-emitting element, comprising the steps of forming, by a wet method, a fourth layer including an organic compound, and an inorganic compound showing an electron donating property to the organic compound over a second electrode; forming a third layer including a material generating electrons over the fourth layer; forming a second layer including a luminescent substance over the third layer; forming a first layer including a material generating holes over the second layer; and forming a first electrode over the first Layer. Note that the first layer may be formed by a wet method, as well as the fourth layer, or may be formed by another method, for example an evaporation method.

In the manufacturing method of a light-emitting element described above, the first and fourth layers can be formed by applying a solution including a metal alkoxide and an organic compound and baking it. At this time, hydrolysis is preferably conducted using water, and thus, the film formed by applying the solution may be exposed to water vapor before baking.

Therefore, a structure of the present invention is a manufacturing method of a light-emitting element, wherein the step of forming the first layer is a step of applying a solution of a metal alkoxide and an organic compound, and baking it; or a step of applying a solution of a metal alkoxide and an organic compound, exposing it to water vapor, and baking it.

Therefore, another structure of the present invention is a manufacturing method of a light-emitting element, wherein the step of forming the fourth layer is a step of applying a solution of a metal alkoxide and an organic compound, and baking it; or a step of applying a solution of a metal alkoxide and an organic compound, exposing it to water vapor, and baking it.

In the method using a metal alkoxide described above, the solution may additionally include a stabilizer to prevent precipitation. As the stabilizer, β-diketones such as acetylacetone, ethyl acetoacetate, or benzoylacetone are preferred. Also, the solution may additionally include water so as to promote hydrolysis of a metal alkoxide.

Moreover, the first and fourth layers can be formed by using a metal hydroxide, as well as by using a metal alkoxide as a raw material. In this case, there are advantageous effects of making precipitation difficult to occur, and making a reaction for forming an oxide easy to occur without conducting hydrolysis.

Thus, another structure of the present invention is a manufacturing method of a light-emitting element, wherein the step of forming the first layer is a step in which a solution including an organic compound, and a sol obtained by deflocculating a metal hydroxide is applied and baked.

Another structure of the present invention is a manufacturing method of a light-emitting element, wherein the step of forming the fourth layer is a step in which a solution including an organic compound, and a sol obtained by deflocculating a metal hydroxide is applied and baked.

In the above mentioned manufacturing method of a light-emitting element of the present invention, the solution may include a binder substance additionally. The binder substance is preferably polyvinyl alcohol, polymethyl methacrylate, polycarbonate or a phenol resin.

In the above manufacturing method of a light-emitting element, the organic compound preferably has an arylamine skeleton. Alternatively, the organic compound is any one of the high molecular weight compounds represented by general formulas (1) to (10) described above.

By the manufacturing method of a light-emitting element according to the present invention, a metal oxide having a strong electron accepting property is formed from a first metal alkoxide, or a first metal hydroxide obtained by deflocculation. Thus, the metal is preferably a transition metal in the above manufacturing method of a light-emitting element. In particular, titanium, vanadium, a molybdenum, tungsten, rhenium, or ruthenium is preferred.

The present inventors have found that the above described objects can be achieved by forming a light-emitting element having a structure in which a layer including a luminescent substance is sandwiched between a first composite material, which includes a first organic compound and a first inorganic compound showing an electron accepting property to the first organic compound, and a second composite material, which includes a second organic compound and a second inorganic compound showing an electron donating property to the second organic compound. Specifically, the present inventors have found that the objects can be achieved by employing a wet method to form both the first and the second composite materials when the light-emitting element is manufactured.

In the present invention, in consideration of film quality when a film is formed by a wet method, the first organic compound or the second organic compound additionally includes a material which serves as a binder (hereinafter, a binder substance), in the case where the first organic compound or the second organic compound is a low molecular weight compound. In addition, in the case where the first organic compound or the second organic compound is a high molecular weight compound (in this specification, the category of the high molecular weight compound includes compounds having middle molecular weight such as oligomer or dendrimer), the first organic compound or the second organic compound may further include a binder substance; however, it is not necessarily required.

Therefore, a structure of the present invention is a light-emitting element comprising a layer including a luminescent substance between a pair of electrodes; wherein the layer including a luminescent substance includes a first layer, a second layer, and a third layer, which are stacked sequentially; wherein the first layer includes a first composite material which includes a first organic compound, a first binder substance, and a first inorganic compound showing an electron accepting property to the first organic compound; wherein the second layer includes a luminescent substance; and wherein the third layer includes a second composite material which includes a second organic compound, a second binder substance, and a second inorganic compound showing an electron donating property to the second organic compound.

Another structure of the present invention is a light-emitting element comprising a layer including a luminescent substance between a pair of electrodes; wherein the layer including a luminescent substance includes a first layer, a second layer, and a third layer, which are stacked sequentially; wherein the first layer includes a first composite material including a first organic compound which is a high molecular weight compound, and a first inorganic compound showing an electron accepting property to the first organic compound; wherein the second layer includes a luminescent substance; and wherein the third layer includes a second composite material which includes a second organic compound, a second binder substance, and a second inorganic compound showing an electron donating property to the second organic compound.

Another structure of the present invention is a light-emitting element comprising a layer including a luminescent substance between a pair of electrodes; wherein the layer including a luminescent substance includes a first layer, a second layer, and a third layer, which are stacked sequentially; wherein the first layer includes a first composite material including a first organic compound, a binder substance, and a first inorganic compound showing an electron accepting property to the first organic compound; wherein the second layer includes a luminescent substance; and wherein the third layer includes a second composite material including a second organic compound which is a high molecular weight compound, and a second inorganic compound showing an electron donating property to the second organic compound.

Another structure of the present invention is a light-emitting element comprising a layer including a luminescent substance between a pair of electrodes; wherein the layer including a luminescent substance includes a first layer, a second layer, and a third layer, which are stacked sequentially; wherein the first layer includes a first composite material including a first organic compound which is a high molecular weight compound, and a first inorganic compound showing an electron accepting property to the first organic compound; wherein the second layer includes a luminescent substance; and wherein the third layer includes a second composite material including a second organic compound which is a high molecular weight compound, and a second inorganic compound showing an electron donating property to the second organic compound.

Here, the binder substance is preferably polyvinyl alcohol, polymethyl methacrylate, polycarbonate or a phenol resin. The first organic compound is preferably a compound having an arylamine skeleton. The second organic compound preferably has one or plural of a pyridine skeleton, an imidazole skeleton, a triazole skeleton, an oxadiazole skeleton, a thiadiazole skeleton, an oxazole skeleton, and a thiazole skeleton.

The first inorganic compound needs to have a highly electron accepting property, and thus, it is preferably an oxide including a transition metal. In particular, titanium oxide, vanadium oxide, molybdenum oxide, tungsten oxide, rhenium oxide, and ruthenium oxide are preferred.

On the other hand, the second inorganic compound needs to have a strong electron donating property, and thus, it is preferably an oxide including an alkali metal or an alkaline earth metal. In particular, lithium oxide, calcium oxide, and barium oxide are preferred.

The oxide including a transition metal, or the oxide including an alkali metal or an alkaline earth metal described above, may include a hydroxyl group.

As for the above light-emitting element of the present invention, a light-emitting element has a structure in which the layer including a luminescent substance additionally includes a fourth layer which is in contact with the third layer, and the fourth layer is formed using a third composite material including a third organic compound, and a third inorganic compound showing an electron accepting property to the third organic compound, is also one mode of the present invention.

In this case, the third organic compound preferably has an arylamine skeleton. The third inorganic compound is preferably an oxide including a transition metal. For example, titanium oxide, vanadium oxide, molybdenum oxide, tungsten oxide, rhenium oxide, and ruthenium oxide are preferred.

Further, a light-emitting device having a light-emitting element described above is also one mode of the present invention. Note that the category of the light-emitting element of the present invention includes an image display device and a light-emitter using a light-emitting element. In addition, a module that has a connector, for example, a flexible printed circuit (FPC), a TAB (Tape Automated Bonding) tape, or a TCP (Tape Carrier Package), attached to a light-emitting element; a module that has a printed wiring board provided at the tip of a TAB tape or a TCP; and a module that has an IC (integrated circuit) directly mounted on a light-emitting element by a COG (Chip On Glass) method, are all included in the category of the light-emitting device.

In addition, a manufacturing method of a light-emitting element according to the present invention is also based on a novel concept, and is also one mode of the present invention. One feature of the present invention is that the first layer and the third layer are formed by a wet method. Also, a method in which layers are formed over the first electrode and a method in which layers are formed over the second electrode can be considered.

Thus, a structure of the present invention is a manufacturing method of a light-emitting element, comprising the steps of forming, by a wet method, a first layer including a first organic compound and a first inorganic compound showing an electron accepting property to the first organic compound over a first electrode; forming a second layer including a luminescent substance over the first layer; forming, by a wet method, a third layer including a second organic compound, and a second inorganic compound showing an electron donating property to the second organic compound over the second layer; and forming a second electrode over the third layer.

In addition, another structure of the present invention is a manufacturing method of a light-emitting element, comprising the steps of forming, by a wet method, a third layer including a second organic compound and a second inorganic compound showing an electron donating property to the second organic compound over a second electrode; forming a second layer including a luminescent substance over the third layer; forming, by a wet method, a first layer including a first organic compound, and a first inorganic compound showing an electron accepting property to the first organic compound over the second layer; and forming a first electrode over the first layer.

In addition, another structure of the present invention is a manufacturing method of a light-emitting element, comprising the steps of forming, by a wet method, a first layer including a first organic compound and a first inorganic compound showing an electron accepting property to the first organic compound over a first electrode; forming a second layer including a luminescent substance over the first layer; forming, by a wet method, a third layer including a second organic compound, and a second inorganic compound showing an electron donating property to the second organic compound over the second layer; forming a fourth layer including a third organic compound and a third inorganic compound showing an electron accepting property to the third organic compound over the third layer; and forming a second electrode over the fourth layer.

In addition, another structure of the present invention is a manufacturing method of a light-emitting element, comprising the steps of forming a fourth layer including a third organic compound and a third inorganic compound showing an electron accepting property to the third organic compound over a second electrode; forming, by a wet method, a third layer including a second organic compound and a second inorganic compound showing an electron donating property to the second organic compound over the fourth layer; forming a second layer including a luminescent substance over the third layer; forming, by a wet method, a first layer including a first organic compound and a first inorganic compound showing an electron accepting property to the first organic compound over the second layer; and forming a first electrode over the first layer.

The fourth layer may be formed by a wet method, similarly to the first layer, or by another method such as an evaporation method.

In the manufacturing method of a light-emitting element described above, the first and third layers can be formed by applying a solution including a metal alkoxide and an organic compound and baking it. At this time, hydrolysis is preferably conducted using water, and thus, the film formed by applying the solution may be exposed to water vapor before baking. The fourth layer can be formed in the same manner as the first layer, when a wet method is employed.

Thus, a structure of the present invention is a manufacturing method of a light-emitting element, in which the step of forming the first layer is a step in which a solution including a first metal alkoxide and the first organic compound is applied and baked, or a step in which a solution including a first metal alkoxide and the first organic compound is applied, exposed to water vapor and baked.

Another structure of the present invention is a manufacturing method of a light-emitting element, in which the step of forming the third layer is a step in which a solution including a second alkoxide and the second organic compound is applied, and baked, or a step in which a solution including the second alkoxide and the second organic compound is applied, exposed to water vapor and baked.

Another structure of the present invention is a manufacturing method of a light-emitting element, in which the step of forming the fourth layer is a step in which a third solution including a third metal alkoxide and a third organic compound is applied and baked, or a step in which a third solution including a third metal alkoxide and a third organic compound is applied, exposed to water vapor and baked.

In the method using a metal alkoxide as described above, the first, second and third solutions may additionally include a stabilizer to prevent precipitation. As the stabilizer, β-diketones such as acetylacetone, ethyl acetoacetate, or benzoylacetone are preferred. In addition, the first, second and third solutions may additionally include water so as to promote hydrolysis of a metal alkoxide.

Moreover, the first and fourth layers can be formed using a metal hydroxide, instead of using a metal alkoxide. In this case, there are advantageous effects of making precipitation difficult to occur, and making a reaction for forming an oxide easy to occur without conducting hydrolysis.

Thus, another structure of the present invention is a manufacturing method of a light-emitting element, in which the step of forming the first layer is a step in which a first solution including the first organic compound and a sol obtained by deflocculating a first metal hydroxide is applied and baked.

Further, another structure of the present invention is a manufacturing method of a light-emitting element, in which the step of forming the fourth layer is a step in which a third solution including the third organic compound and a sol obtained by deflocculating a third metal hydroxide is applied and baked.

As described above, the above described first, third and fourth layers can be formed by a wet method using a metal alkoxide or a metal hydroxide.

In the above described manufacturing method of a light-emitting element, the first, second and third solutions may additionally include a binder substance. The binder substance is preferably polyvinyl alcohol, polymethyl methacrylate, polycarbonate or a phenol resin.

The first organic compound is preferably a compound having an arylamine skeleton. The second organic compound preferably has one or plural of a pyridine skeleton, an imidazole skeleton, a triazole skeleton, an oxadiazole skeleton, a thiadiazole skeleton, an oxazole skeleton, and a thiazole skeleton.

By the manufacturing method of a light-emitting element according to the present invention, a metal oxide having a strong electron accepting property is formed using a first metal hydroxide which is obtained by deflocculation, and a first metal alkoxide. Thus, the first metal is preferably a transition metal. In particular, titanium, vanadium, molybdenum, tungsten, rhenium, and ruthenium are preferred.

On the other hand, by the manufacturing method of a light-emitting element according to the present invention, a metal oxide with a strong electron donating property can be formed using a second metal alkoxide. Thus, the second metal is preferably an alkali metal or an alkaline earth metal. In particular, lithium, calcium, and barium are preferable.

A composite material of the present invention including an organic compound and an inorganic compound has high conductivity. A composite material of the present invention is also superior in the carrier injecting property and carrier transporting property.

Since a light-emitting element according to the present invention includes a composite material having a combination of an organic compound and an inorganic compound, it exhibits superior carrier injecting property, carrier transporting property, and conductivity. Thus, driving voltage of the light-emitting element can be lowered.

In a light-emitting device having a light-emitting element of the present invention, the light-emitting element can be driven at low voltage. Thus, power consumption can be reduced.

A light-emitting element of the present invention can be formed by a wet method. Thus, it can respond to an increase in substrate size and is suitable for mass-production.

Since a light-emitting element of the present invention employs a material that is less corrosive and harmful, effects on the environment and on the human body are low. Thus, it is suitable for mass-production.

### BRIEF DESCRIPTION OF DRAWINGS

In the accompanying drawings:

FIG. 1 shows a light-emitting element of the present invention;

FIG. 2 shows a light-emitting element of the present invention;

FIGS. 3A to 3C each show a light-emitting element of the present invention;

FIGS. 4A to 4C each show a light-emitting element of the present invention;

FIG. 5 shows a light-emitting element of the present invention;

FIGS. 6A to 6C each show a light-emitting element of the present invention;

FIGS. 7A to 7C each show a light-emitting element of the present invention;

FIG. 8 shows a light-emitting element of the present invention;

FIG. 9 shows a light-emitting element of the present invention;

FIGS. 10A to 10C each show a light-emitting element of the present invention;

FIGS. 11A to 11C each show a light-emitting element of the present invention;

FIG. 12 shows a light-emitting element of the present invention;

FIGS. 13A to 13C each show a light-emitting element of the present invention;

FIGS. 14A to 14C each show a light-emitting element of the present invention;

FIG. 15 shows a light-emitting element of the present invention;

FIG. 16 shows a light-emitting element of the present invention;

FIGS. 17A to 17C each show a light-emitting element of the present invention;

FIGS. 18A to 18C each show a light-emitting element of the present invention;

FIGS. 19A to 19C each show a light-emitting element of the present invention;

FIGS. 20A to 20C each show a light-emitting element of the present invention;

FIG. 21 shows a light-emitting device;

FIGS. 22A and 22B each show a light-emitting device;

FIGS. 23A to 23E each show an electronic device;

FIG. 24 is a graph showing voltage-luminescence characteristics of the light-emitting elements shown in Example 2 and the comparative example 1;

FIG. 25 is a graph showing voltage-current characteristics of the light-emitting elements shown in Example 3 and the comparative example 2;

FIGS. 26A and 26B are each a graph showing voltage-current characteristics of the light-emitting elements shown in Example 4 and the comparative example 3; and

FIGS. 27A and 27B are each a graph showing absorption spectra of the light-emitting elements shown in Example 5 and the comparative example 4.

### BEST MODE FOR CARRYING OUT THE INVENTION

Embodiment Modes according to the present invention will hereinafter be described with reference to the accompanying drawings. The present invention can be carried out in many different modes, and it is easily understood by those skilled in the art that modes and details herein disclosed can be modified in various ways without departing from the spirit and the scope of the present invention. It should be noted that the present invention should not be interpreted as being limited to the description of the embodiment modes to be given below.

As for a pair of electrodes of a light-emitting element according to the present invention, when a voltage is applied such that a potential of one electrode thereof is higher than that of the other electrode, light is emitted. At this time, one electrode having a higher potential, is referred to as an electrode serving as an anode, and the other electrode having a lower potential, is referred to as an electrode serving as a cathode.

In this specification, a wet method is a method in which a liquid is applied to form a film.

### Embodiment Mode 1

A composite material of the present invention will be described. The composite material is a material including an organic compound and an inorganic compound in combination.

The conductivity of a composite material of the present invention is increased by generating an interaction between an organic compound and an inorganic compound to generate carriers. This embodiment mode describes a case that electrons are generated as carriers.

A composite material for generating electrons is a composite material including an organic compound and an inorganic compound showing an electron donating property to the organic compound. By adopting this combination, electrons move into the organic compound from the inorganic compound, thereby generating electrons as carriers. As a result of the generated electrons, high conductivity can be obtained.

As an organic compound of the present invention, which is used for a composite material generating electrons, a material that is superior in electron transporting property is preferable. An organic compound having a pyridine skeleton, an imidazole skeleton, a triazole skeleton, an oxadiazole skeleton, an oxazole skeleton, or a thiazole skeleton is preferably used. Specifically, tris(8-quinolinolato) aluminum (Alq₃); tris(4-methyl-8-quinolinolato) aluminum (Almq₃); bis(10-hydroxybenzo[h]-quinolinato)beryllium (BeBq₂); bis(2-methyl-8-quinolinolato)(4-phenylphenolato)aluminium (BAlq); bis [2-(2′-hydroxyphenyl)-benzoxazolato]zinc (Zn(BOX)₂); bis[2-(2′-hydroxyphenyl)-benzothiazolato]zinc (Zn(BTZ)₂); bathophenanthroline (BPhen), bathocuproin (BCP), 2-(4-biphenylyl)-5-(4-tert-butylphenyl)-1,3,4-oxadiazole (PBD); 1,3-bis[5-(4-tert-butylphenyl)-1,3,4-oxadiazol-2-yl]benzene (OXD-7); 2,2′,2″-(1,3,5-benzenetriyl)-tris(1-phenyl-1H-benzimidazole) (TPBI); 3-(4-biphenylyl)-4-phenyl-5-(4-tert-butylphenyl)-1,2,4-triazole (TAZ); and 3-(4-biphenylyl)-4-(4-ethylphenyl)-5-(4-tert-butylphenyl)-1,2,4-triazole (p-EtTAZ); and poly(4-vinyl pyridine) (PVPy) and the like can be given. However, the present invention is not limited to these substances.

As the inorganic compound included in the composite material generating electrons, an oxide including an alkali metal or an alkaline earth metal is preferably used. Specifically, one or plural of lithium oxide, calcium oxide, and barium oxide is/are preferably used. A composite oxide including a skeleton of such oxides may also be used. The oxide including an alkali metal or an alkaline earth metal may include a hydroxyl group.

Since the oxide including an alkali metal or an alkaline earth metal is used, electron transfer is conducted between such a metal oxide and a pyridine skeleton or the like, thereby generating electrons as carriers. Since the electrons are generated internally, high conductivity can be obtained in applying an electric field.

A composite material of the present invention may take form in a variety of states, such as a state in which the organic compound becomes a matrix and the inorganic compound is dispersed therein, a state in which the inorganic compound becomes a matrix and the organic compound is dispersed therein, or a state in which the organic compound and the inorganic compound are contained in nearly equal amounts and bound to each other. In any state, since electron transfer is conducted between an organic compound and an inorganic compound, superior electron injecting property, electron transporting property and high conductivity can be obtained.

When a film is formed using a composite material generating electrons, a material functioning as a binder (a binder substance) may be added to improve the film quality. In particular, in the case of using a low molecular weight compound (specifically, a compound having a molecular weight of 500 or less) is used as the organic compound, a binder substance is needed in consideration of film quality. Needless to say, a binder substance may be added when a high molecular weight compound is used as the organic compound. As binder substances, polyvinyl alcohol (PVA), polymethylmethacrylate (PMMA), polycarbonate (PC), a phenol resin and the like can be given.

### Embodiment Mode 2

Embodiment Mode 2 will describe a manufacturing method of a composite material generating electrons, shown in Embodiment Mode 1.

A metal alkoxide is used as a component for forming an inorganic compound. As described in Embodiment Mode 1, an oxide including an alkali metal or an alkaline earth metal is preferably used as the inorganic compound. As the metal, an alkali metal or an alkaline earth metal is preferable, specifically, lithium, calcium or barium is preferred. Note that in the case of using a composite oxide as an inorganic compound, another metal alkoxide may be added. In other words, in a case that a composite oxide including an aluminum oxide skeleton, for example, is used, an aluminum alkoxide such as aluminum triisopropoxide may additionally be added.

A sol is prepared by adding water and a chelating agent such as β-diketon as a stabilizer, into a solution in which a metal alkoxide is dissolved in a proper solvent. As the solvent, for example, tetrahydrofuran (THF), acetonitrile, dichloromethane, dichloroethane, or a mixed solvent of these can be used, as well as lower alcohol such as methanol, ethanol, n-propanol, i-propanol, n-butanol, and sec-butanol. However, the present invention is not limited to them.

As the compound which can be used as a stabilizer, β-diketones such as acetylacetone, ethyl acetoacetate, benzoylacetone are given, for example. However, the stabilizer is provided to prevent precipitation inside a sol; however, it is not necessarily provided. In addition, water is not necessarily required, since it is added to control the progress of a reaction of the alkoxide.

Subsequently, an organic compound (or a solution of an organic compound) is mixed with the prepared sol, and stirred to obtain a first solution including the metal alkoxide and the organic compound. After that, by coating and baking the solution, a composite material generating electrons, of the present invention, can be formed as a film. As a method of applying a solution, wet methods such as a solution cast method, a dip coating method, a spin coating method, a roll coating method, a blade coating method, a wire bar coat method, a spray coating method, an ink-jet method, a screen printing method, and a gravure printing method can be adopted. However, the present invention is not limited to the methods.

It should be noted that a binder substance may be added, in advance, to the first solution, in the case of adding the binder substance. Substances described in Embodiment Mode 1 may be used as the binder substance.

### Embodiment Mode 3

Embodiment Mode 3 will describe a method of forming a composite material generating electrons, as a film, by another method, which is different from that in Embodiment Mode 2.

A metal alkoxide is used as a component for forming an inorganic compound. As described in Embodiment Mode 1, an oxide including an alkali metal or an alkaline earth metal is preferably used. As the metal, an alkali metal or an alkaline earth metal is preferable, specifically, lithium, calcium or barium is preferred. Note that in a case of using a composite oxide as an inorganic compound, another metal alkoxide may be added. In other words, in a case that a composite oxide including an aluminum oxide skeleton, for example, is used, an aluminum alkoxide such as aluminum triisopropoxide may additionally be added.

A first solution including a metal alkoxide and an organic compound is obtained by dissolving the metal alkoxide and the organic compound in a proper solvent, and stirring it. As the solvent, for example, THF, acetonitrile, dichloromethane, dichloroethane, or a mixed solvent of these can be used, as well as lower alcohol such as methanol, ethanol, n-propanol, i-propanol, n-butanol, and sec-butanol. However, the present invention is not limited to them.

After that, by coating, exposing to water vapor and baking, a composite material of the present invention, can be formed as a film. As a method of applying a solution, wet methods such as a solution cast method, a dip coating method, a spin coating method, a roll coating method, a blade coating method, a wire bar coat method, a spray coating method, an ink-jet method, a screen printing method, and a gravure printing method can be adopted. However, the present invention is not limited to the methods.

As a result of exposing the solution to water vapor after applying it, a hydrolysis reaction of the metal alkoxide occurs. Then, it is baked, so that polymerization or cross-linking reaction progresses. Alternatively, irradiation of a microwave may be conducted, instead of baking, so that polymerization or cross-linking reaction can progress. Further, baking and irradiation of a microwave may be conducted together, so that polymerization or cross-linking reaction can progress.

It should be noted that a binder substance may be added, in advance, to the first solution, in a case of adding the binder substance. Substances described in Embodiment Mode 1 may be used as the binder substance.

In this embodiment mode, a stabilizer such as the β-diketone as described in Embodiment Mode 2 may be added into the first solution including a metal alkoxide and an organic compound. By adding a stabilizer, multinuclear precipitation of a metal hydroxide due to moisture in the air or the like, can be suppressed. A stabilizer is not necessarily needed, if the manufacturing process is done in an environment without moisture, before being exposed to water vapor.

### Embodiment Mode 4

Embodiment Mode 4 will describe a light-emitting element manufactured using a composite material of the present invention.

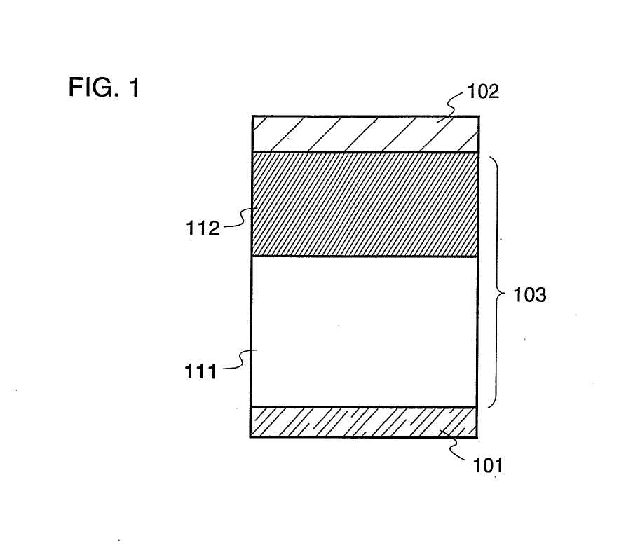

FIG. 1 shows a light-emitting element of the present invention. A layer including a luminescent substance 103 is sandwiched between a first electrode 101 and a second electrode 102. The layer including a luminescent substance has a structure in which a first layer 111 and a second layer 112 are stacked. This embodiment mode describes a case that the first electrode 101 serves as an anode and the second electrode 102 serves as a cathode.

The second layer 112 is described. The second layer 112 is a layer which transports electrons to the first layer 111, and is preferably formed with a composite material generating electrons, which is shown in Embodiment Mode 1. The composite material generating electrons contains an organic compound and an inorganic compound showing an electron donating property to the organic compound. Electron transfer occurs between the organic compound and the inorganic compound, thereby generating a large number of electrons as carriers. Thus, excellent electron injecting property and electron transporting property are shown. Therefore, driving voltage of a light-emitting element can be decreased by using a composite material generating electrons of the present invention. It should be noted that, since the second layer 112 including such a composite material generating electrons has excellent electron injecting property and electron transporting property, the second layer 112 is preferably formed in a position closer to a cathode than a light-emitting layer. This embodiment mode will describe a case that the second layer 112 is provided to be in contact with the second electrode 102 serving as a cathode.

A composite material of the present invention has high conductivity. Thus, the second layer 112 can be made thicker without causing a rise of driving voltage, and short-circuiting of an element caused by dusts or the like can be prevented.

Since the above composite material includes an inorganic compound, heat-resistance of the light-emitting element can be increased.

The first layer 111 is a layer having a light-emitting function. The first layer 111 may have a single layer or a multilayer. For example, functional layers such as an electron injecting layer, an electron transporting layer, a hole blocking layer, a hole transporting layer, and a hole injecting layer may be freely combined, in addition to the light-emitting layer. In addition, a known material can be used for the first layer 111, and a low molecular weight material and a high molecular weight material can be used. It should be noted that, as a material for forming the first layer 111, organic compound materials containing an inorganic compound as a part can be used, as well as materials of only an organic compound. An advantageous effect that heat resistance is more enhanced, can be provided, since the first layer 111 also contains an inorganic compound.

In this embodiment mode, since the second layer 112 serves as an electron injecting layer, an electron injecting layer is not required to be provided in the first layer 111.

A known material can be used as a hole injecting material for forming a hole injecting layer. Specifically, metal oxides such as molybdenum oxide, vanadium oxide, ruthenium oxide, and aluminum oxide are preferable. Alternatively, in a case of using an organic compound, a porphyrin based compound is effective, phthalocyanine (H₂-PC), copper phthalocyanine (CuPc) or the like can be used. In addition, a chemically doped polymer conductive compound can be used, for example, polyethylene dioxythiophene (PEDOT) which is doped with polystyrene sulfonic acid (PSS), or polyaniline (PAni) etc., can be used. A composite material may be used, in which an organic compound having an aromatic amine skeleton, such as 4,4′,4″-tris(N,N-diphenyl-amino)-triphenylamine (TDATA); 4,4′,4″-tris[N-(3-methylphenyl)-N-phenylamino]triphenylamine (MTDATA); 1,3,5-tris[N,N-bis(3-methylphenyl)amino]benzene (m-MTDAB); N,N′-diphenyl -N,N′-bis(3-methylphenyl)-1,1′-biphenyl-4,4′-diamine (TPD); 4,4′-bis[N-(1-naphthyl)-N-phenylamino]biphenyl (NPB); 4,4′-bis{N-(4-[N,N-bis(3-methylphenyl amino]phenyl)-N-phenylamino}biphenyl (DNTPD); 4,4′,4″-tris (N-carbazolyl)triphenylamine (TCTA); or poly(4-vinyl triphenylamine) (PVTPA), and a compound showing an electron accepting property to the organic compound, are mixed. At this time, as the compound having an electron accepting property, an oxide including a transition metal such as molybdenum oxide, vanadium oxide, rhenium oxide, tungsten oxide, or ruthenium oxide is preferred.

A known material can be used as a hole transporting material for forming a hole transporting layer. As a preferable material, an aromatic amine compound (i.e., a compound having a bond of benzene ring—nitrogen). As a widely used material, a star burst aromatic amine compound such as 4,4′-bis[N-(3-methylphenyl)-N-phenyl-amino]-biphenyl (TPD); or derivatives thereof, e.g., 4,4′-bis[N-(1-naphthyl)-N-phenyl-amino]-biphenyl (NPB); 4,4′,4″-tris(N,N-diphenyl-amino)-triphenylamine (TDATA); 4,4′,4″-tris[N-(3-methylphenyl)-N-phenyl-amino]-triphenylamine (MTDATA) can be given.

The light-emitting layer contains a luminescent substance. The luminescent substance is herein a substance that has an excellent light emitting efficiency and can emit light with a predetermined wavelength. Although the light-emitting layer is not especially limited, the light-emitting layer is preferably one in that a luminescent substance is dispersed in a layer formed using a substance having a larger energy gap than that of the substance with the light emitting property. This layer can prevent light emitted from the substance with the light emitting property from quenching due to the concentration of the substance with the light emitting property. Further, the energy gap indicates an energy gap between the LUMO level and the HOMO level.

The substance with the light emitting property used for forming a light-emitting layer is not especially limited. A substance having an excellent light emitting efficiency that can emit light with a predetermined emission wavelength may be used. In order to emit red light, for example, the following substances exhibiting emission spectrum with peaks at 600 to 680 nm can be employed: 4-dicyanomethylene-2-isopropyl-6-[2-(1,1,7,7-tetramethyljulolidine-9-yl)ethenyl]-4H-p yran (DCJTI); 4-dicyanomethylene-2-methyl-6-[2-(1,1,7,7-tetramethyljulolidine-9-yl)ethenyl]-4H-pyr an (DCJT); 4-dicyanomethylene-2-tert-butyl-6-[2-(1,1,7,7-tetramethyljulolidine-9-yl)ethenyl]-4H-p yran (DCJTB); periflanthene; 2,5-dicyano-1,4-bis[2-(10-methoxy-1,1,7,7-tetramethyljulolidine-9-yl)ethenyl]benzene; and the like. In order to obtain green light emission, substances exhibiting emission spectrum with peaks at 500 to 550 nm such as N,N′-dimethylquinacridon (DMQd), coumarin 6, coumarin 545T, and tris(8-quinolinolato) aluminum (Alq₃) can be employed. In order to obtain blue light emission, the following substances exhibiting emission spectrum with peaks at 420 to 500 nm can be employed: 9,10-bis(2-naphthyl)-tert-butylanthracene (t-BuDNA); 9,9′-bianthryl; 9,10-diphenylanthracene (DPA); 9,10-bis(2-naphthyl) anthracene (DNA); bis(2-methyl-8-quinolinolato)-4-phenylphenolato-gallium (BGaq); bis(2-methyl-8-quinolinolato)(4-phenylphenolato)aluminium (BAlq); and the like. In addition to the above mentioned fluorescent substances, the following phosphorescent substances can be used as substances with the light emitting properties: bis[2-(3,5-bis(trifluoromethyl)phenyl)pyridinato-N,C²′]iridium(III) picolinate (Ir(CF₃ppy)₂(Pic)); bis[2-(4,6-difluorophenyl)pyridinato-N,C²′]iridium(III) acetylacetonate (FIr(acac)); bis[2-(4,6-difluorophenyl)pyridinato-N,C²′]iridium(III) picolinate (FIr(pic)); tris(2-phenylpyridinato-N,C²′) iridium (Ir(ppy)₃); and the like.

A substance used for dispersing a luminescent substance is not especially limited. For example, an anthracene derivative such as 9,10-di(2-naphthyl)-2-tert-butylanthracene (t-BuDNA); a carbazole derivative such as 4,4′-bis(N-carbazolyl) biphenyl (CBP); a metal complex such as bis[2-(2-hydroxyphenyl)pyridinato]zinc (ZnpP₂); and bis[2-(2-hydroxyphenyl)benzoxazolato]zinc (ZnBOX); and the like can be used.

As a material with an electron transporting property that is used for forming an electron transporting layer, a known material can be used. Specifically, a typical metal complex such as tris(8-quinolinolato) aluminum (Alq₃); tris(4-methyl-8-quinolinolato) aluminum (Almq₃); bis(10-hydroxybenzo[h]-quinolinato) beryllium (BeBq₂); bis(2-methyl-8-quinolinolato)(4-phenylphenolato)aluminium (BAlq); bis[2-(2-hydroxyphenyl)-benzoxazolate]zinc (Zn(BOX)₂); and bis[2-(2-hydroxyphenyl)-benzothiazolate]zinc (Zn(BTZ)₂) can be given. In addition, a hydrocarbon compound such as 9,10-diphenylanthracene and 4,4′-bis(2,2-diphenylethenyl) biphenyl is preferably employed. Additionally, a triazole derivative such as 3-(4-tert-butylphenyl)-4-(4-ethylphenyl)-5-(4-biphenylyl)-1,2,4-triazole; a phenanthroline derivative such as bathophenanthroline and bathocuproin may be used.

As a material with an electron injecting property that is used for forming an electron injecting layer, a known material can be used. Specifically, alkali metal salt and alkaline earth metal salt such as calcium fluoride, lithium fluoride, lithium oxide and lithium chloride are preferable. Alternatively, a layer of a material with an electron transporting property to which a donor compound such as lithium is added, for example, tris(8-quinolinolato) aluminum (Alq₃) and bathocuproin (BCP) and the like, can be employed.

In this embodiment mode, a dopant that contributes to light emission is added only to the light-emitting layer and light emitted from the dopant is only observed. However, a dopant exhibiting different light emission may be added to, for example, an electron transporting layer or a hole transporting layer. When a color of light emitted from the light-emitting layer and a color of light emitted from the dopant added to the other layer are complementary to each other, white light emission can be obtained.

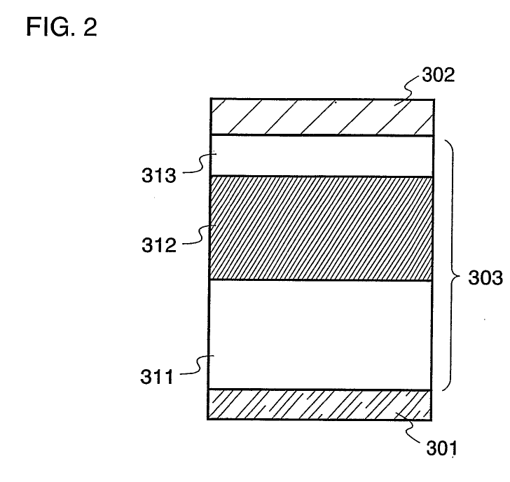

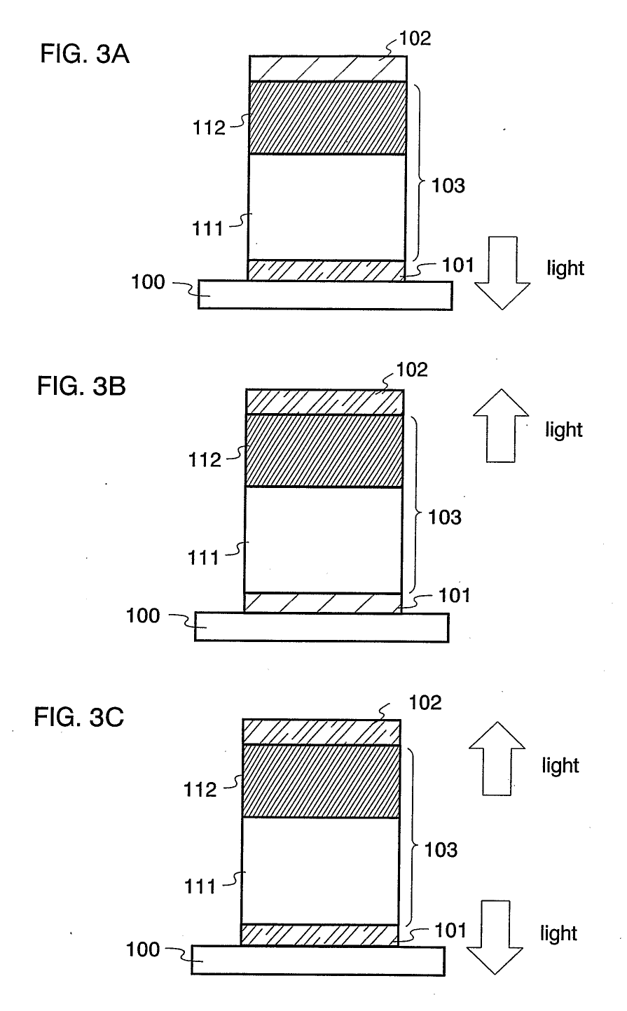

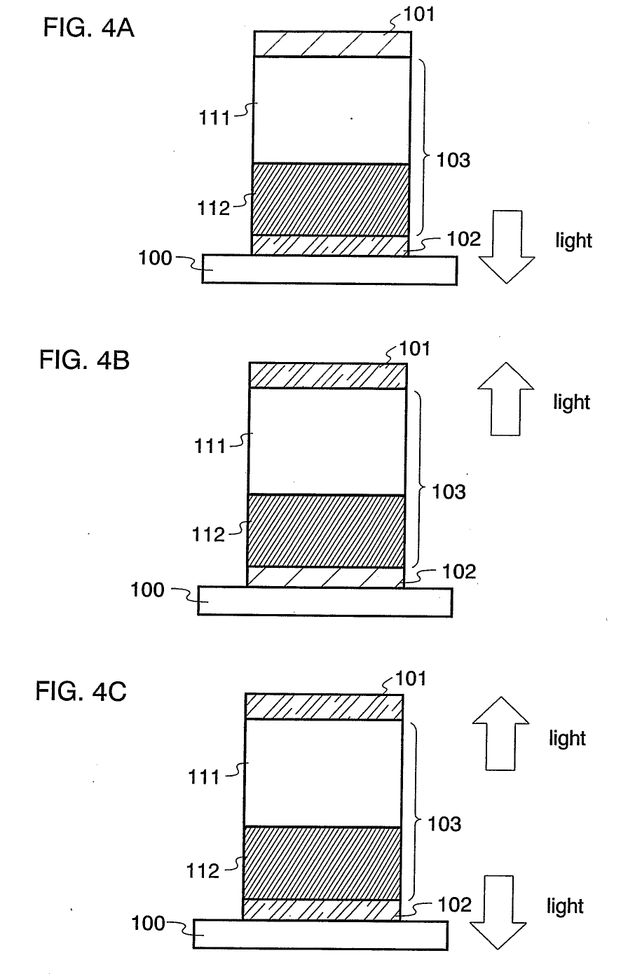

By changing the kinds of the first electrode 101 and the second electrode 102, there are different variations in the light emitting element of this embodiment mode. Schematic views of the variations are shown in FIGS. 3A to 3C and FIGS. 4A to 4C. Further, the reference numerals used in FIG. 1 are also used in FIGS. 3A to 3C and FIGS. 4A to 4C. Moreover, reference numeral 100 represents a substrate for supporting a light emitting element of the present invention.

FIGS. 3A to 3C each show an example in which the first layer 111 and the second layer 112 included in the layer including a luminescent substance 103 are stacked in this order over the substrate 100. In this case, when the first electrode 101 is formed using a material having a light transmitting property and the second electrode 102 is formed using a material having a light-shielding property (in particular, light reflecting property), light can be emitted through the substrate 100 as shown in FIG. 3A. Also, when the first electrode 101 is formed using a material with a light-shielding property (in particular, light reflecting property) and the second electrode 102 is formed using a material having a light transmitting property, light can be emitted through the side opposite the substrate 100 as shown in FIG. 3B. Further, when the first electrode 101 and the second electrode 102 are both formed using a material having a light transmitting property, light can be emitted toward both the substrate 100 and the side opposite the substrate as shown in FIG. 3C.

FIGS. 4A to 4C each show an example in which the second layer 112 and the first layer 111 included in the layer including a luminescent substance 103 are stacked in this order over the substrate 100. In this case, when the first electrode 101 is formed using a material having a light-shielding property (in particular, light reflecting property) and the second electrode 102 is formed using a material having a light transmitting property, light can be emitted through the substrate 100 as shown in FIG. 4A. When the first electrode 101 is formed using a material having a light transmitting property and the second electrode 102 is formed using a material having a light-shielding property (in particular, light reflecting property), light can be emitted through the side opposite the substrate 100 as shown in FIG. 4B. Further, when the first electrode 101 and the second electrode 102 are both formed using a material having a light transmitting property, light can be emitted toward both the substrate 100 and the side opposite the substrate 100 as shown in FIG. 4C.

In the light emitting element of this embodiment mode, since the second layer 112 includes an organic compound and an inorganic compound showing an electron donating property to the organic compound, the second layer 112 exhibits extremely excellent electron injecting and transporting properties. Therefore, the increase in driving voltage can be suppressed even when the thickness of the second layer 112 is increased. As a consequence, short-circuiting of the light emitting element can be prevented while suppressing the increase in driving voltage. Moreover, in order to improve the color purity by an optical design, the thickness of the second layer 112 can be freely set.

Furthermore, as shown in FIGS. 3A to 3C, in the case where the first layer 111 and the second layer 112 are sequentially formed over the first electrode 101, which has been formed first, and then the second electrode 102 is formed thereover by sputtering, it is possible to avoid damage to the first layer 111 in which the luminescent substance exists.

### Embodiment Mode 5

Although Embodiment Mode 4 has described the case that the layer including an organic compound and an inorganic compound showing an electron donating property to the organic compound, is in contact with the cathode, Embodiment Mode 5 will describe a case that the layer including an organic compound and an inorganic compound showing an electron donating property to the organic compound, exists between the cathode and a light-emitting layer, and is not in contact with the cathode.

An example of a structure of a light emitting element of the present invention will be shown in FIG. 2. A layer including a luminescent substance 303 is sandwiched between a first electrode 301 and a second electrode 302. The layer containing the luminescent substance 303 includes a structure in which a first layer 311, a second layer 312 and a third layer 313 are stacked in this order. This embodiment mode describes a case that the first electrode 301 serves as an anode, and the second electrode 302 serves as a cathode.

The first layer 311 has a function of emitting light. The same structure as that of the first layer 111, which has been described in Embodiment Mode 4, can be applied for the first layer 311.

The second layer 312 is a layer including an organic compound and an inorganic compound showing an electron donating property to the organic compound. The second layer 312 can have the same structure as the second layer 112 shown in Embodiment Mode 4.

The third layer 313 is a layer having a function of injecting electrons. A known material can be formed as an electron injecting material for forming an electron injecting layer. Specifically, the electron injecting materials shown in Embodiment Mode 4 can be used.

By adopting the above described structure, an increase of driving voltage can be suppressed, even when the second layer 312 becomes thick. Thus, the increase of driving voltage can be suppressed, short-circuiting of an element can be prevented, and the color purity by optical design can be realized.

### Embodiment Mode 6

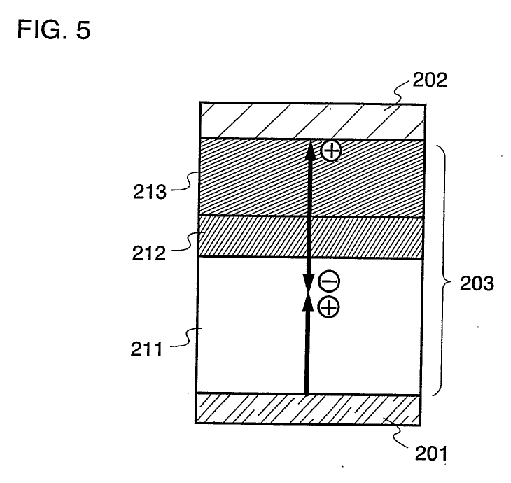

Embodiment Mode 6 will describe a light-emitting element having a structure different from those shown in Embodiment Modes 4 and 5 with reference to FIG. 5.

FIG. 5 shows a structure of a light-emitting element of the present invention as one example. A layer including a luminescent substance 203 is sandwiched between a first electrode 201 and a second electrode 202. The layer containing the luminescent substance 203 includes a structure in that a first layer 211, a second layer 212 and a third layer 213 are stacked in this order. This embodiment mode describes a case that the first electrode 201 serves as an anode, and the second electrode 202 serves as a cathode.

The light-emitting element of this embodiment mode is operated as follows. When voltage is applied such that a potential of the first electrode 201 is higher than that of the second electrode 202, holes are injected into the second electrode 202 from the third layer 213 while electrons are injected into the first layer 211 from the second layer 212. Also, holes are injected into the first layer 211 from the first electrode 201. The holes injected from the first electrode 201 and the electrons injected from the second layer 212 are recombined in the first layer 211, so that a luminescent substance is excited. The luminescent substance emits light when returning to a ground state from the excited state.

The first electrode 201, the second electrode 202, the first layer 211 and the second layer 212 can have the same structures as the first electrode 101, the second electrode 102, the first layer 111 and the second layer 112 in Embodiment Mode 1, respectively. In other words, the first electrode can be formed using a known material, the first layer 211 includes a luminescent substance, and the second layer 212 includes an organic compound and an inorganic compound showing an electron donating property to the organic compound.

The third layer 213 is a layer generating holes. As the layer generating holes, for example, a layer containing an aromatic amine compound and a substance that shows an electron accepting property to the aromatic amine compound is preferably used. Here, the aromatic amine compound is a substance having an aryl amine skeleton. Among such aromatic amine compounds, particularly, a substance including triphenylamine in its skeleton and having a molecular weight of 400 or more is preferable. In addition, among the aromatic amine compounds including triphenylamine in their skeleton, an aromatic amine including a fused aromatic ring such as a naphthyl group in its skeleton is preferable particularly. By using an aromatic amine compound including triphenylamine and fused aromatic ring in its skeleton, heat resistance of a light-emitting element is increased. For example, an aromatic amine compound such as 4,4′-bis[N-(1-naphthyl)-N-phenylamino]biphenyl (α-NPD); 4,4′-bis[N-(3-methylphenyl)]-N-phenylamino]biphenyl (TPD); 4,4′,4″-tris(N,N-diphenylamino)triphenylamine (TDATA); 4,4′,4″-tris[N-(3-methylphenyl)-N-phenylamino]triphenylamine (MTDATA); and 4,4′-bis{N-[4-(N,N-di-m-tolylamino)phenyl]-N-phenylaminobiphenyll(DNTPD); 1,3,5-tris[N,N-di(m-tolyl)amino]benzene (m-MTDAB); 4,4′,4″-tris (N-carbazolyl)-triphenylamine (TCTA); 2,3-bis(4-diphenylaminophenyl)quinoxaline (TTPAQn); 2,2′,3,3′-tetrakis(4-diphenylaminophenyl)-6,6′-bisquinoxaline (D-TriPhAQn); 2,3-bis{4-[N-(1-naphthyl)-N-phenylamino]phenyl}-dibenzo[f,h]quinoxaline (NPADiBzQn); and the like can be given. Also, the substance having the electron accepting property to the aromatic amine compound is not especially limited. For example, titanium oxide, molybdenum oxide, vanadium oxide, tungsten oxide, rhenium oxide, ruthenium oxide, chromium oxide, zirconium oxide, hafnium oxide, tantalum oxide, silver oxide, 7,7,8,8-tetracyanoquinodimethane (TCNQ), 2,3,5,6-tetrafluoro-7,7,8,8-tetracyanoquinodimethane (F4-TCNQ), and the like can be used. The third layer 213 preferably includes the substance that shows the electron accepting property to the aromatic amine compound so that the value of a molar ratio (i.e., the substance showing the electron accepting property to the aromatic amine compound/the aromatic amine compound) is in the range of 0.5 to 2.

By utilizing the above mentioned structure, when the voltage is applied to the light emitting element, the electrons are transported in the vicinity of an interface between the second layer 212 and the third layer 213 so that electrons and holes are generated, as shown in FIG. 5. The second layer 212 transports the electrons to the first layer 211, and at the same time, the third layer 213 transports the holes to the second electrode 202. That is, a combination of the second layer 212 and the third layer 213 serves as a carrier generating layer. Also, it can be said that the third layer 213 has a function of transporting holes to the second electrode 202. Further, when another first layer and another second layer are also stacked between the third layer 213 and the second electrode 202, a multiphoton light emitting element can be formed.

Furthermore, since the second layer 212 includes an organic compound and an inorganic compound showing an electron donating property to the organic compound, the second layer 212 exhibits extremely strong electron injecting and transporting properties. Therefore, the increase in driving voltage can be suppressed even when the thickness of the second layer 212 is increased. Thus, in the light-emitting element of this embodiment mode, since the thickness of the second layer 212 can be increased, the short-circuiting of the light emitting element can be effectively prevented. Moreover, in order to improve the color purity by an optical design, the thickness of the second layer 212 can be freely set.

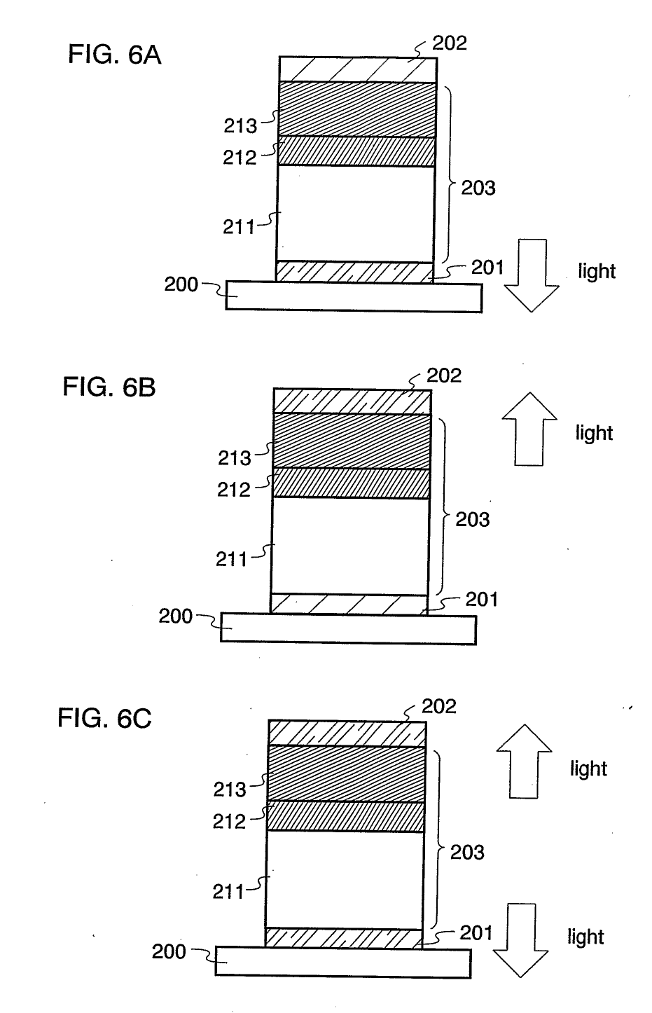

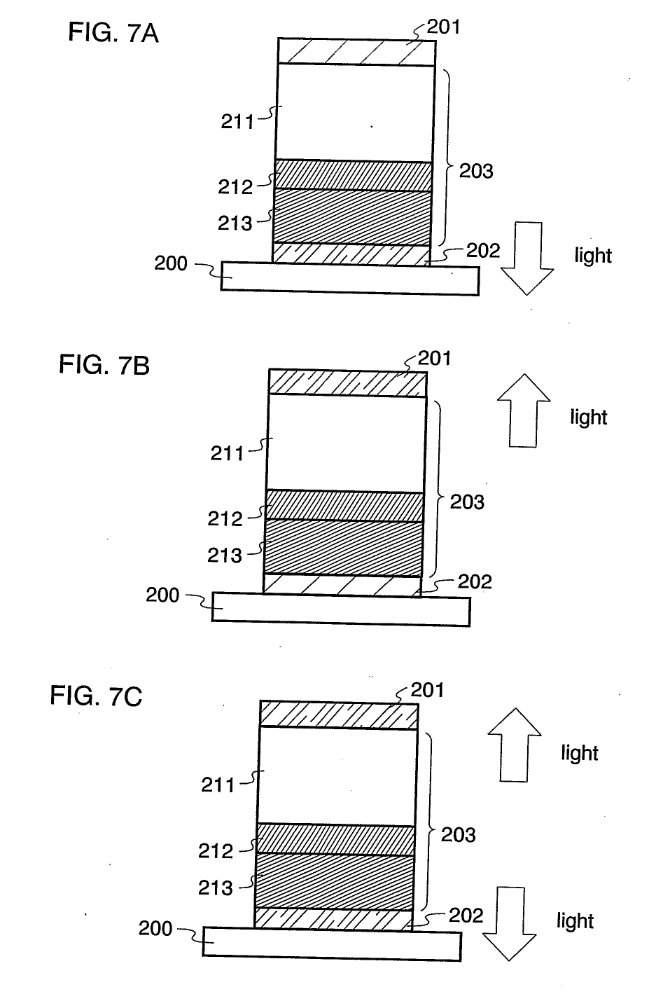

Further, in the light-emitting element of this embodiment mode, by changing the kinds of the first electrode 201 and the second electrode 202, there are many variations in the light emitting element. Schematic views of the variations are shown in FIGS. 6A to 6C and FIGS. 7A to 7C. The reference numerals used in FIG. 5 are also used in FIGS. 6A to 6C and FIGS. 7A to 7C. Reference numeral 200 represents a substrate for supporting a light emitting element of the present invention.

FIGS. 6A to 6C each show an example in which a layer including a luminescent substance 203 includes a first layer 211, a second layer 212, and a third layer 213, which are stacked in this order over the substrate 200. In this case, when the first electrode 201 is formed using a material with a light transmitting property and the second electrode 202 is formed using a material with a light-shielding property (in particular, light reflecting property), light can be emitted through the substrate 200 as shown in FIG. 6A. When the first electrode 201 is formed using a material with a light-shielding property (in particular, light reflecting property) and the second electrode 202 is formed using a material with a light transmitting property, light can be emitted through the side opposite the substrate 200 as shown in FIG. 6B. Further, when the first electrode 201 and the second electrode 202 are both formed using a material having a light transmitting property, light can be emitted through both the substrate 200 and the side opposite the substrate, as shown in FIG. 6C.

FIGS. 7A to 7C each show an example in which a layer including a luminescent substance 203 includes a third layer 213, a second layer 212 and a first layer 211, which are stacked in this order over the substrate 200. In this case, when the first electrode 201 is formed using a material with a light-shielding property (in particular, light reflecting property) and the second electrode 202 is formed using a substance with a light transmitting property, light can be emitted through the substrate 200 as shown in FIG. 7A. When the first electrode 201 is formed using a material with a light transmitting property and the second electrode 202 is formed using a material with a light-shielding property (in particular, light reflecting property), light can be emitted through the side opposite the substrate 200 as shown in FIG. 7B. Further, when the first electrode 201 and the second electrode 202 are both formed using a material with a light transmitting property, light can be emitted through both the substrate 200 and the side opposite the substrate 200, as shown in FIG. 7C.

### Embodiment Mode 7

Embodiment Mode 7 will describe a manufacturing method of the light-emitting element shown in Embodiment Mode 4.

The first electrode 101 is formed first. The first electrode 101 can be formed using a known material by a known method.

Next, the first layer 111 is formed. The first layer 111 can be formed using a known material by a known method. In a case of-employing a wet method which can respond to the increase in a substrate size, all layers included in the layer including a luminescent substance 103 can be formed by a wet method, and thus, a wet method is suitable for mass production. For example, a luminescent substance such as poly (2,5-dihexoxy-1,4-phenylenevinylene) (MEH-PPV) can be formed by a wet method.

Then, the second layer 112 is formed. The second layer 112 can be formed by any method shown in Embodiment Modes 2 and 3. The methods shown in Embodiment Modes 2 and 3 are each a wet method, and thus the methods are suitable for the increase in substrate size.

The second electrode 102 can be formed using a known material by a known method.

In accordance with the above method, a light-emitting element of the present invention can be manufactured. Since the manufacturing method of a light-emitting element of the present invention which is employed for forming the second layer 112, is a wet method, the method can respond to the increase in a substrate size and is suitable for mass production. In particular, when the first layer 111 is also formed by a wet method using a known polymer light-emitting material or the like, all layers included in the layer including a luminescent substance 103 can be formed by a wet method. Thus, the present invention can easily respond to the increase in a substrate size, and is suitable for mass production.

It should be noted that this embodiment mode has described the method of forming the light-emitting element from the first electrode 101 side (over the first electrode). However, the light-emitting element may be formed by stacking layers from the second electrode 102 side (over the second electrode).

### Embodiment Mode 8

Embodiment Mode 8 will describe a light-emitting element of the present invention. The light-emitting element of the present invention includes a luminescent substance and a composite material between a pair of electrodes. Note that the composite material is a material including an organic compound and an inorganic compound in combination.

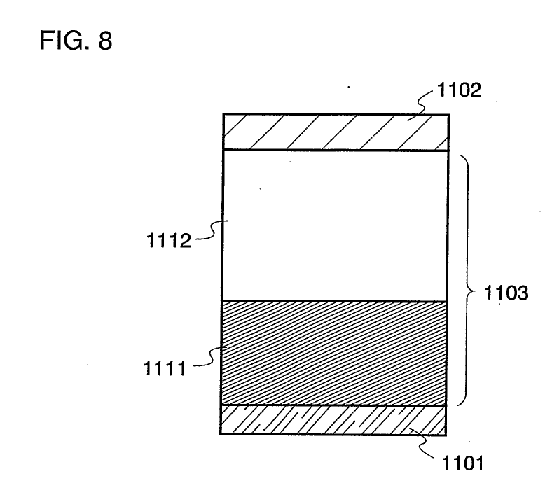

FIG. 8 shows an example of a structure of the light-emitting element of the present invention. A layer including a luminescent substance 1103 is sandwiched between a first electrode 1101 and a second electrode 1102. This embodiment mode describes a case that the first electrode 1101 serves as an anode and the second electrode 1102 serves as a cathode.

The layer including a luminescent substance 1103 has a structure in which a first layer 1111 and a second layer 1112 are stacked.

The first layer 1111 is a layer which transports holes to the second layer 1112, and includes a composite material generating holes. The composite material generating holes contains an organic compound and an inorganic compound showing an electron accepting property to the organic compound in combination. Electron transfer occurs between the organic compound and the inorganic compound, thereby generating a large number of holes. Thus, excellent hole injecting property and hole transporting property are exhibited. Therefore, driving voltage of a light-emitting element can be decreased by using a composite material generating holes. It should be noted that, since the first layer 1111 including such a composite material generating holes has excellent hole injecting property and hole transporting property, the first layer 1111 is preferably formed in a position closer to an anode than a light-emitting layer. This embodiment mode will describe a case that the first layer 1111 is provided to be in contact with the first electrode 1101 serving as an anode.

As the organic compound included in the composite material generating holes, a compound having an excellent property of transporting generated holes is preferable, specifically, an organic compound having an aryl amine compound is preferable. More specifically, such as 4,4′,4″-tris(N,N-diphenylamino)triphenylamine (TDATA); 4,4′,4″-tris[N-(3-methylphenyl)-N-phenylamino]triphenylamine (MTDATA); 1,3,5-tris[N,N-bis(3-methylphenyl)amino]benzene (m-MTDAB); N,N′-diphenyl-N,N′-bis-(3-methylphenyl)-1,1′-biphenyl-4,4′-diamine (TPD); 4,4′-bis[N-(1-naphthyl)-N-phenylamino]biphenyl (NPB); 4,4′-bis{N-(4-[N,N-bis(3-methylphenyl amino]phenyl)-N-phenylamino}biphenyl (DNTPD); 4,4′,4″-tris (N-carbazolyl)triphenylamine (TCTA); or poly(4-vinyl triphenylamine) (PVTPA); poly (N-vinylcarbazole) (PVK); and the like are given. However, the present invention is not limited to these materials.

As the inorganic compound included in the composite material generating holes, an oxide including a transition metal is preferably used. Specifically, one or plural of titanium oxide, molybdenum oxide, vanadium oxide, rhenium oxide, tungsten oxide, or ruthenium oxide is/are preferred. In addition, a composite oxide including a skeleton of the oxides described above may be used. The oxide including a transition metal may have a hydroxyl group.

By using a oxide including a transition metal, electron transfer between the oxide including a transition metal and nitrogen in an arylamine skeleton is conducted, thereby generating holes. Holes exist internally, and thus high conductivity can be obtained when being applied with an electric field.

The above composite material has high conductivity and thus, the increase in driving voltage can be suppressed when the film thickness is increased. Therefore, since the first layer 1111 can be made thick without causing the increase in driving voltage, short-circuiting of an element due to dusts or the like can be suppressed.

In addition, the above composite material includes an inorganic compound, and thus, heat resistance of a light-emitting element can be increased.

The first layer 1111 may take form in a variety of states, such as a state in which the organic compound becomes a matrix and the inorganic compound is dispersed therein, a state in which the inorganic compound becomes a matrix and the organic compound is dispersed therein, or a state in which the organic compound and the inorganic compound are contained in nearly equal amounts and bound to each other. In any state, since electron transfer is conducted between an organic compound and an inorganic compound, superior hole injecting property, hole transporting property and high conductivity can be obtained.

When a film is formed using a composite material generating holes, a material serving as a binder (a binder substance) may be added to enhance the film quality. In particular, in the case of using a low molecular weight compound (specifically, a compound having a molecular weight of 500 or less) is used as the organic compound, a binder substance is needed in consideration of film quality. Needless to say, a binder substance may be added when a high molecular weight compound is used. As binder substances, polyvinyl alcohol (PVA), polymethylmethacrylate (PMMA), polycarbonate (PC), a phenol resin or the like can be given.

The second layer 1112 is a layer having a light-emitting function. The second layer 1112 may have a single layer or a multilayer. For example, functional layers such as an electron injecting layer, an electron transporting layer, a hole blocking layer, a hole transporting layer, and a hole injecting layer may be freely combined, in addition to the light-emitting layer. In addition, a known material can be used for the second layer 1112, and a low molecular weight compound and a high molecular weight compound can be used. It should be noted that, as a material for forming the second layer 1112, organic compound materials containing an inorganic compound as a part can be used, as well as materials including only an organic compound material. An advantageous effect that heat resistance can be more enhanced, can be provided by making the second layer 1112 contain an inorganic compound.

In this embodiment mode, since the first layer 1111 serves as a hole injecting layer, a hole injecting layer is not required to be provided in the second layer 1112.

A known material can be used as a hole injecting material for forming a hole injecting layer. Specifically, metal oxides such as molybdenum oxide, vanadium oxide, ruthenium oxide, and aluminum oxide are preferable. Alternatively, in a case of using an organic compound, a porphyrin based compound is effective, phthalocyanine (H₂-Pc), copper phthalocyanine (CuPc) or the like can be used. In addition, a chemically doped polymer conductive compound can be used, for example, polyethylene dioxythiophene (PEDOT) which is doped with polystyrene sulfonic acid (PSS), polyaniline (PAni), and the like can be used.

Known materials can be used as a hole transporting material for forming a hole transporting layer. As a preferable material, an aromatic amine compound (a compound having a bond of a benzene ring and nitrogen) is given. As a widely used material, a star busrt type aromatic amine compound is given, for example, 4,4′-bis[N-(3-methylphenyl)-N-phenyl-amino]-biphenyl (TPD); a derivative thereof such as 4,4′-bis[N-(1-naphthyl)-N-phenyl-amino]biphenyl (NPB), 4,4′,4″-tris(N,N-diphenyl-amino)-triphenylamine (TDATA); and 4,4′,4″-tris[N-(3-methylphenyl)-N-phenyl-amino]-triphenylamine (MTDATA).

The light-emitting layer contains a luminescent substance. The luminescent substance is herein a substance that has an excellent light emitting efficiency and can emit light with a predetermined wavelength. Although the light-emitting layer is not especially limited, the light-emitting layer is preferably one in that a luminescent substance is dispersed in a layer formed using a substance having a larger energy gap than that of the substance with the light emitting property. This layer can prevent light emitted from the substance with the light emitting property from quenching due to the concentration of the substance with the light emitting property. Further, the energy gap indicates an energy gap between the LUMO level and the HOMO level.

The substance with the light emitting property used for forming a light-emitting layer is not especially limited. A substance having an excellent light emitting efficiency that can emit light with a predetermined emission wavelength may be used. In order to emit red light, for example, the following substances exhibiting emission spectrum with peaks at 600 to 680 nm can be employed: 4-dicyanomethylene-2-isopropyl-6-[2-(1,1,7,7-tetramethyljulolidine-9-yl)ethenyl]-4H-p yran (DCJTI); 4-dicyanomethylene-2-methyl-6-[2-(1,1,7,7-tetramethyljulolidine-9-yl)ethenyl]-4H-pyr an (DCJT); 4-dicyanomethylene-2-tert-butyl-6-[2-(1,1,7,7-tetramethyljulolidine-9-yl)ethenyl]-4H-p yran (DCJTB); periflanthene; 2,5-dicyano-1,4-bis[2-(10-methoxy-1,1,7,7-tetramethyljulolidine-9-yl)ethenyl]benzene; and the like. In order to obtain green light emission, substances exhibiting emission spectrum with peaks at 500 to 550 nm such as N,N′-dimethylquinacridon (DMQd), coumarin 6, coumarin 545T, and tris(8-quinolinolato) aluminum (Alq₃) can be employed. In order to obtain blue light emission, the following substances exhibiting emission spectrum with peaks at 420 to 500 nm can be employed: 9,10-bis(2-naphthyl)-tert-butylanthracene (t-BuDNA); 9,9′-bianthryl; 9,10-diphenylanthracene (DPA); 9,10-bis(2-naphthyl)anthracene (DNA); bis(2-methyl-8-quinolinolato)-4-phenylphenolate-gallium (BGaq); bis(2-methyl-8-quinolinolato)(4-phenylphenolato)aluminium (BAlq); and the like. In addition to the above mentioned fluorescent substances, the following phosphorescent substances can be used as substances with the light emitting properties: bis[2-(3,5-bis(trifluoromethyl)phenyl)pyridinato-N,C²′]iridium(III) picolinate (Ir(CF₃ppy)2(pic)); bis[2-(4,6-difluorophenyl)pyridinato-N,C²′]iridium(III) acetylacetonate (FIr(acac)); bis[2-(4,6-difluorophenyl)pyridinato-N,C²′]iridiumn(III) picolinate (FIr(pic)); tris(2-phenylpyridinato-N,C²′) iridium (Ir(ppy)3); and the like.

A substance used for dispersing a luminescent substance is not especially limited. For example, an anthracene derivative such as 9,10-di(2-naphthyl)-2-tert-butylanthracene (t-BuDNA); a carbazole derivative such as 4,4′-bis(N-carbazolyl) biphenyl (CBP); a metal complex such as bis[2-(2-hydroxyphenyl)pyridinato]zinc (Znpp₂); and bis[2-(2-hydroxyphenyl)benzoxazolato]zinc (ZnBOX); and the like can be used.

As a material with an electron transporting property that is used for forming an electron transporting layer, a known material can be used. Specifically, a typical metal complex such as tris(8-quinolinolato) aluminum (Alq₃); tris(4-methyl-8-quinolinolato) aluminum (Almq₃); bis(10-hydroxybenzo[h]-quinolinato)beryllium (BeBq₂); bis(2-methyl-8-quinolinolato)(4-phenylphenolato)aluminium (BAlq); bis[2-(2-hydroxyphenyl)-benzoxazolate]zinc (Zn(BOX)₂); and bis[2-(2-hydroxyphenyl)-benzothiazolate]zinc (Zn(BTZ)₂) can be given. In addition, a hydrocarbon compound such as 9,10-diphenylanthracene or 4,4′-bis(2,2-diphenylethenyl) biphenyl is also preferable. Additionally, a triazole derivative such as 3-(4-tert-butylphenyl)-4-(4-ethylphenyl)-5-(4-biphenyl)-1,2,4-triazole; a phenanthroline derivative such as bathophenanthroline or bathocuproin may be used.

As a material with an electron injecting property that is used for forming an electron injecting layer, a known material can be used. Specifically, alkali metal salt and alkaline earth metal salt such as calcium fluoride, lithium fluoride, lithium oxide and lithium chloride are preferable. Alternatively, a layer of a material with an electron transporting property such as tris(8-quinolinolato)aluminum (Alq₃) or bathocuproin (BCP), to which a donor compound such as lithium is added, can be employed.

In this embodiment mode, a dopant that contributes to light emission is added only to the light-emitting layer, and light emitted from the dopant is only observed. However, a dopant exhibiting different light emission may be added to, for example, an electron transporting layer or a hole transporting layer. When a color of light emitted from the light-emitting layer and a color of light emitted from the dopant added to another layer are complementary to each other, white light emission can be obtained.

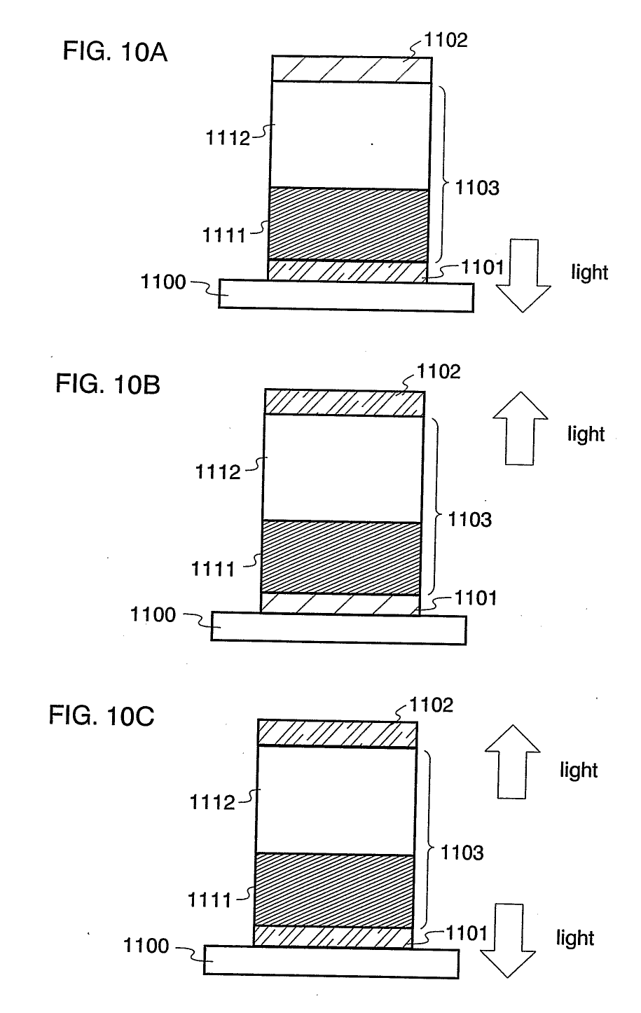

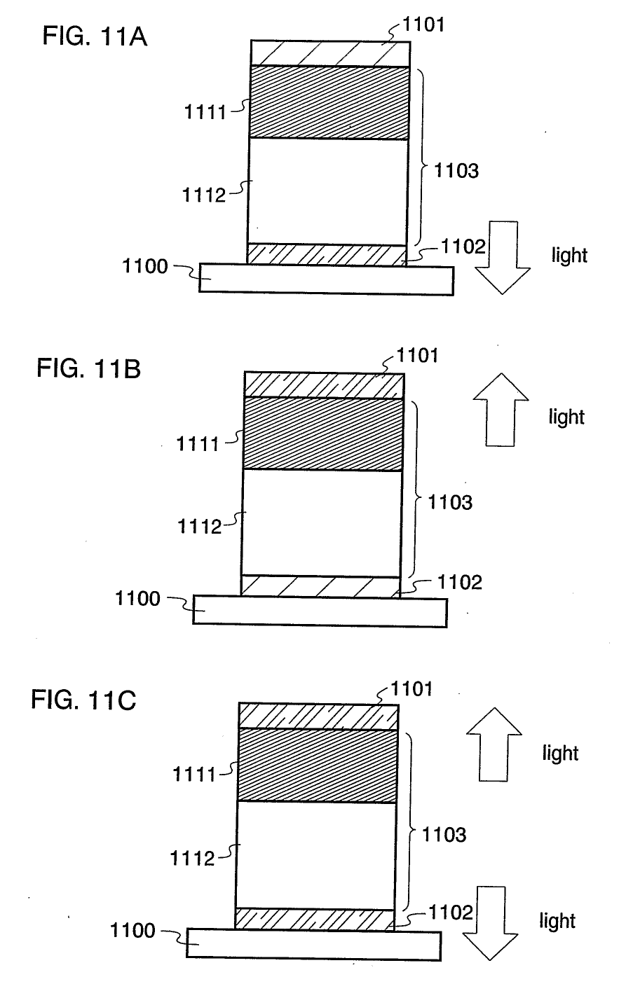

By changing the kinds of the first electrode 1101 and the second electrode 1102, there are different variations in the light emitting element of this embodiment mode. Schematic views of the variations are shown in FIGS. 10A to 10C and FIGS. 11A to 11C. Further, the reference numerals used in FIG. 8 are also used in FIGS. 10A to 10C and FIGS. 11A to 11C. Moreover, reference numeral 1100 represents a substrate for supporting a light emitting element of the present invention.

FIGS. 10A to 10C each show an example in which the first layer 1111 and the second layer 1112 included in the layer including a luminescent substance 1103 are stacked in this order over the substrate 1100. In this case, when the first electrode 1101 is formed using a material having a light transmitting property and the second electrode 1102 is formed using a material having a light-shielding property (in particular, light reflecting property), light can be emitted through the substrate 1100 as shown in FIG. 10A. Also, when the first electrode 1101 is formed using a material with a light-shielding property (in particular, light reflecting property) and the second electrode 1102 is formed using a material having a light transmitting property, light can be emitted through the side opposite the substrate 1100 as shown in FIG. 10B. Further, when the first electrode 1101 and the second electrode 1102 are both formed using a material having a light transmitting property, light can be emitted toward both the substrate 1100 and the side opposite the substrate 1100 as shown in FIG. 10C.

FIGS. 11A to 11C each show an example in which the second layer 1112 and the first layer 1111 included in the layer including a luminescent substance 1103 are stacked in this order over the substrate 1100. In this case, when the first electrode 1101 is formed using a material having a light-shielding property (in particular, light reflecting property) and the second electrode 1102 is formed using a material having a light transmitting property, light can be emitted through the substrate 1100 as shown in FIG. 11A. When the first electrode 1101 is formed using a material having a light transmitting property and the second electrode 1102 is formed using a material having a light-shielding property (in particular, light reflecting property), light can be emitted through the side opposite the substrate 1100 as shown in FIG. 11B. Further, when the first electrode 1101 and the second electrode 1102 are both formed using a material having a light transmitting property, light can be emitted toward both the substrate 1100 and the side opposite the substrate 1100 as shown in FIG 11C.

In the light emitting element of this embodiment mode, since the first layer 1111 includes an organic compound and an inorganic compound showing an electron accepting property to the organic compound, the first layer 1111 exhibits extremely excellent hole injecting and transporting properties. Therefore, the increase in driving voltage can be suppressed even when the thickness of the first layer 1111 is increased. As a consequence, short-circuiting of the light emitting element can be prevented while suppressing the increase in driving voltage. Moreover, in order to improve the color purity by an optical design, the thickness of the first layer 1111 can be freely set.

Furthermore, as shown in FIGS. 11A to 11C, in the case where the second layer 1112 and the first layer 1111 are sequentially formed over the second electrode 1102, which has been formed first, and then the first electrode 1101 is formed thereover by sputtering, it is possible to avoid damage to the second layer 1112 including the luminescent substance.

Since a light-emitting element of the present invention employs a material that is less corrosive and harmful, effects on the environment and on the human body are low.

### Embodiment Mode 9

Embodiment Mode 9 will describe a method for forming a film of a composite material generating holes, which is shown in Embodiment Mode 8.

A metal alkoxide is used as a component for forming an inorganic compound. As described in Embodiment Mode 8, an oxide including a transition metal is preferably used as the inorganic compound. As the metal, a transition metal is preferable, specifically, titanium, vanadium, molybdenum, tungsten, rhenium, and ruthenium are preferred. Note that in the case of using a composite oxide as the inorganic compound, another metal alkoxide may be added. In other words, in a case that a composite oxide including an aluminum oxide skeleton, for example, is used, an aluminum alkoxide such as aluminum triisopropoxide may be additionally added.

A sol is prepared by adding water and a chelating agent such as β-diketon as a stabilizer, into a solution in which a metal alkoxide is dissolved in a proper solvent. As the solvent, for example, THF, acetonitrile, dichloromethane, dichloroethane, or a mixed solvent of these can be used, as well as lower alcohol such as methanol, ethanol, n-propanol, i-propanol, n-butanol, and sec-butanol. However, the present invention is not limited to them.

As the compound which can be used as a stabilizer, β-diketones such as acetylacetone, ethyl acetoacetate, and benzoylacetone are given, for example. However, the stabilizer is provided to prevent precipitation inside a sol; however, it is not necessarily provided.

The amount of water to be added is preferably with 2 or more and 6 or less equivalent weights with respect to a metal alkoxide, since the metal alkoxide generally has divalent to hexavalent. However, water is not necessarily required, since water is used to control the progress of a reaction of a metal alkoxide.

Subsequently, a solution of an organic compound is mixed with the prepared sol, and stirred to obtain a solution including the metal alkoxide and the organic compound. After that, by coating and baking the solution, a composite material of the present invention can be formed as a film. As a method of applying a solution, wet methods such as a solution cast method, a dip coating method, a spin coating method, a roll coating method, a blade coating method, a wire bar coat method, a spray coating method, an ink-jet method, a screen printing method, and a gravure printing method can be adopted. However, the present invention is not limited to the methods.

It should be noted that a binder substance may be added, in advance, to the first solution, in a case of adding the binder substance. Substances described in Embodiment Mode 8 may be used as the binder substance.

### Embodiment Mode 10

Embodiment Mode 10 will describe a method of forming a composite material generating holes, as a film, by another method, which is different from that in Embodiment Mode 9.

A metal alkoxide is used as a component for forming an inorganic compound. As described in Embodiment Mode 8, an oxide including a transition metal is preferably used as an inorganic compound. As the metal, a transition metal is preferable, specifically, titanium, vanadium, molybdenum, tungsten, rhenium, and ruthenium are preferred. Note that in a case of using a composite oxide as the inorganic compound, another metal alkoxide may be further added. In other words, in the case that a composite oxide including an aluminum oxide skeleton, for example, is used, an aluminum alkoxide such as aluminum triisopropoxide may be additionally added.

By dissolving a metal alkoxide and an organic compound in a proper solvent, and stirring it, a first solution including the metal alkoxide and the organic compound is obtained. As the solvent, for example; THF, acetonitrile, dichloromethane, dichloroethane, or a mixed solvent of these can be used, as well as lower alcohols such as methanol, ethanol, n-propanol, i-propanol, n-butanol, and sec-butanol. However, the present invention is not limited to them.

After that, by applying the solution, exposing it to water vapor and baking it, a composite material of the present invention, can be obtained. As a method of applying a solution, wet methods such as a solution cast method, a dip coating method, a spin coating method, a roll coating method, a blade coating method, a wire bar coat method, a spray coating method, an ink-jet method, a screen printing method, and a gravure printing method can be adopted. However, the present invention is not limited to the methods.

As a result of exposing the solution to water vapor after being applied, a hydrolysis reaction of the metal alkoxide occurs. Then, it is baked, so that polymerization or cross-linking reaction progresses. Alternatively, irradiation of a microwave may be conducted, instead of baking, so that polymerization or cross-linking reaction can progress. Further, baking and irradiation of a microwave may be conducted together, so that polymerization or cross-linking reaction can progress.

It should be noted that a binder substance may be added, in advance, to the solution, in the case of adding the binder substance. Substances described in Embodiment Mode 8 may be used as the binder substance.

In this embodiment mode, a stabilizer such as the β-diketone as described in Embodiment Mode 9 may be added into the solution including a metal alkoxide and an organic compound. By adding a stabilizer, multinuclear precipitation of the metal hydroxide due to moisture in the air or the like, can be suppressed. A stabilizer is not necessarily needed, if the manufacturing process is done in an environment without moisture, before being exposed to water vapor.

### Embodiment Mode 11

Embodiment Mode 11 will describe a method of forming a composite material generating holes, as a film, by another method, which is different from those in Embodiment Modes 9 and 10.

As a component for forming an inorganic compound, an ammonia water is dropped into a water solution of acid salt including a metal to obtain multinuclear precipitation of a metal hydroxide. Note that, in a case of applying a composite oxide as an inorganic compound, another metal salt may additionally be added. In other words, when a composite oxide including a skeleton of an aluminum oxide is applied, aluminum salt such as aluminum chloride may additionally be added.

Acid such as acetic acid is added into the obtained precipitation to be refluxed, and it is deflocculated to obtain a sol. A solution of an organic compound (or an organic compound) is added into the obtained sol and was stirred. Thus, a first solution including the sol obtained by deflocculating a metal hydroxide, and the organic compound can be obtained. After that, by coating and baking the solution, a first composite material of the present invention can be formed as a film. As a method of applying a solution, wet methods such as a solution cast method, a dip coating method, a spin coating method, a roll coating method, a blade coating method, a wire bar coat method, a spray coating method, an ink-jet method, a screen printing method, and a gravure printing method can be adopted. However, the present invention is not limited to the methods.

It should be noted that a binder substance may be added, in advance, to the solution, in a case of adding the binder substance. Substances described in Embodiment Mode 8 may be used as the binder substance.

### Embodiment Mode 12

Embodiment Mode 12 will describe a manufacturing method of the light-emitting element shown in Embodiment Mode 8.

The first electrode 1101 is formed first. The first electrode 1101 can be formed using a known material by a known method. Specifically, a metal compound such as indium tin oxide (ITO), indium tin oxide including silicon (ITSO), indium oxide including zinc oxide of 2 to 20wt % (IZO),or a titanium nitride; a metal such as Cr, W, Zn, Pt, Al, or Ag ; or an alloy thereof, etc, is preferably used. For example, indium oxide-zinc oxide (IZO) can be formed by a sputtering method using indium oxide into which zinc oxide of 1 to 20 wt % is added, as a target. In addition, indium oxide-zinc oxide including tungsten oxide and zinc oxide (IWZO) can be formed by a sputtering method using indium oxide into which tungsten oxide of 0.5 to 5 wt % and zinc oxide of 0.1 to 1 wt % are added, as a target.

Next, the first layer 1111 is formed. The first layer 1111 can be formed by any one of the methods shown in Embodiment Modes 9 to 11. The methods shown in Embodiment Modes 9 to 11 are each a wet method, and thus, can respond to the increase in a substrate size.

Then, the second layer 1112 is formed. The second layer 1112 can be formed using a known material by a known method. When the second layer 1112 is formed by a wet method, all layers included in the layer including a luminescent substance 1103 can be formed by a wet method, and thus, it can respond to the increase in a substrate size. Thus, the manufacturing method using a wet method is suitable for mass production. For example, a luminescent substance such as poly (2,5-dihexoxy-1,4-phenylenevinylene) (MEH-PPV) can be formed by a wet method.

The second electrode 1102 can be formed using a known material by a known method. Specifically, the materials mentioned when the first electrode 1101 is described above can be used. One or both of the first electrode 1101 and the second electrode 1102 may have a light-transmitting property.

In accordance with the above method, a light-emitting element of the present invention can be manufactured. Since the manufacturing method of a light-emitting element of the present invention can form the first layer 1111 by a wet method, it can respond to the increase in a substrate size and is suitable for mass production. In particular, when the second layer 1112 is also formed using a known polymer light-emitting material or the like by a wet method, all layers included in the layer including a luminescent substance 1103 can be formed by a wet method, and thus, it can respond to the increase in a substrate size. Thus, the manufacturing method using a wet method is suitable for mass production.

This embodiment mode has described a method for forming an element from the first electrode 1101 side (over the first electrode 1101). However, a light-emitting element may be formed by forming layers sequentially from the second electrode 1102 side (over the second electrode 1102).

### Embodiment Mode 13

Although Embodiment Mode 8 has described the case that the layer including an organic compound and an inorganic compound showing an electron accepting property to the organic compound, is in contact with the anode, Embodiment Mode 13 will describe a case that the layer including an organic compound and an inorganic compound showing an electron accepting property to the organic compound, exists between the anode and a light-emitting layer, and is not in contact with the anode.

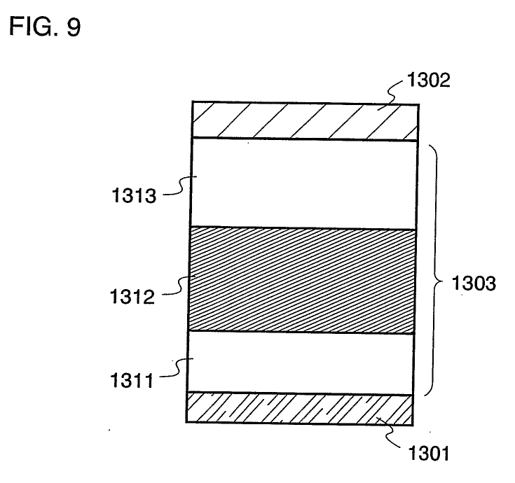

An example of a structure of a light emitting element of the present invention will be shown in FIG. 9. A layer including a luminescent substance 1303 is sandwiched between a first electrode 1301 and a second electrode 1302. The layer containing the luminescent substance 1303 includes a structure in which a first layer 1311, a second layer 1312 and a third layer 1313 are stacked in this order. This embodiment mode describes a case that the first electrode 1301 serves as an anode, and the second electrode 1302 serves as a cathode.

The first layer 1311 is a layer having a function of injecting holes. A known material can be formed as a hole injecting material for forming a hole injecting layer. Specifically, the hole injecting materials shown in Embodiment Mode 8 can be used.

The second layer 1312 is a layer including an organic compound and an inorganic compound showing an electron accepting property to the organic compound. The second layer 1312 can have the same structure as the first layer 1111 shown in Embodiment Mode 8.

The third layer 1313 has a function of emitting light. The same structure as that of the second layer 1112, which has been described in Embodiment Mode 8, can be applied for the third layer 1313.

By adopting the above described structure, an increase of driving voltage can be suppressed, even when the second layer 1312 becomes thick. Thus, the increase of driving voltage can be suppressed, short-circuiting of an element can be prevented, and the color purity by optical design can be realized.

### Embodiment Mode 14

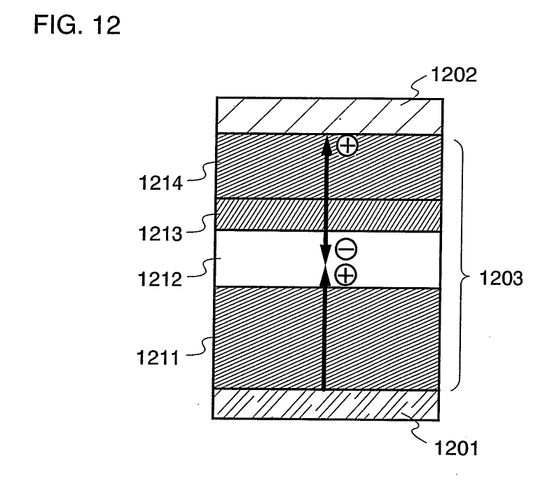

FIG. 12 shows an example of a structure of a light-emitting element having a structure different from that shown in Embodiment Mode 8, with reference to FIG. 12.

FIG. 12 shows a structure of a light-emitting element of the present invention as one example. A layer including a luminescent substance 1203 is sandwiched between a first electrode 1201 and a second electrode 1202. The layer containing the luminescent substance 1203 includes a structure in which a first layer 1211, a second layer 1212, a third layer 1213, and a fourth layer 1214 are stacked in this order. This embodiment mode describes a case that the first electrode 1201 serves as an anode, and the second electrode 1202 serves as a cathode.

The light-emitting element of this embodiment mode is operated as follows. When voltage is applied such that a potential of the first electrode 1201 is higher than that of the second electrode 1202, holes are injected into the second electrode 1202 from the fourth layer 1214 while electrons are injected into the second layer 1212 from the third layer 1213. Also, holes are injected into the first layer 1211 from the first electrode 1201, and then, injected into the second layer 1212 from the first layer 1211. The holes injected from the first layer 1211 and the electrons injected from the third layer 1213 are recombined in the second layer 1212, so that a luminescent substance is excited. The luminescent substance emits light when returning to a ground state from the excited state.

The first electrode 1201, the second electrode 1202, the first layer 1211 and the second layer 1212 can have the same structures as the first electrode 1101, the second electrode 1102, the first layer 1111 and the second layer 1112 in Embodiment Mode 8, respectively. In other words, the first electrode can be formed using a known material, the first layer 1211 includes an organic compound and an inorganic compound showing an electron accepting property to the organic compound, and the second layer 1212 includes a luminescent substance.

The third layer 1213 includes a material having a donor level for generating electrons. As such a layer, a layer including an electron transporting substance and a substance showing an electron donating property to the substance, is given. Herein, the electron transporting substance is a substance which has a property of transporting electrons rather than holes. The electron transporting substance is not especially limited, and for example, 2-(4-biphenylyl)-5-(4-tert-butylphenyl)-1,3,4-oxadiazole (PBD); 1,3-bis[5-(p-tert-butylphenyl)-1,3,4-oxadiazol-2-yl]benzene (OXD-7); 3-(4-tert-butylphenyl)-4-phenyl-5-(4-biphenylyl)-1,2,4-triazole (TAZ); and 3-(4-tert-butylphenyl)-4-(4-ethylphenyl)-5-(4-biphenylil)-1,2,4-triazole (p-EtTAZ); bathophenanthroline (BPhen), bathocuproin (BCP); and the like can be used, as well as metal complexes such as tris(8-quinolinolato) aluminum (Alq₃); tris(4-methyl-8-quinolinolato) aluminum (Almq₃); bis(10-hydroxybenzo[h]-quinolinato)beryllium (BeBq₂); bis(2-methyl-8-quinolinolato)(4-phenylphenolato)aluminium (BAlq); bis [2-(2-hydroxyphenyl)-benzoxazolate]zinc (Zn(BOX)₂); and bis[2-(2-hydroxyphenyl)-benzothiazolato]zinc (Zn(BTZ)₂). In addition, the substance showing an electron donating property to the electron transporting substance is not especially limited, and for example, alkali metals such as lithium and cesium, alkaline earth metals such as magnesium and calcium, rare-earth metal such as erbium and ytterbium, and the like can be used. Further, a substance selected from alkali metal oxides or alkaline earth metal oxides, such as lithium oxides (Li₂O), calcium oxides (CaO), sodium oxide (Na₂O), potassium oxide (K₂O), and magnesium oxide (MgO), may be used as the substance showing an electron donating property to an electron transporting substance. Note that alkali metal oxides, alkaline earth metal oxides, and the like are easy to treat, since they are less reactive. In addition, the second layer 312 may be a layer formed of an n-type semiconductor such as zinc oxide, zinc sulphide, zinc selenide, tin oxide or titanium oxide.

The fourth layer 1214 includes an organic compound and an inorganic compound showing an electron accepting property to the organic compound. Therefore, the inorganic compounds described in Embodiment Mode 8 can be used as the inorganic compound included in the fourth layer. However, the inorganic compound included in the fourth layer 1214 may be the same as the one included in the first layer 1211, or different from the one included in the first layer 1211.

By adopting such a structure, as shown in FIG. 12, electron transfer is conducted in the vicinity of an interface between the third layer 1213 and the fourth layer 1214 by applying a voltage, and electrons and holes are generated. Then, the third layer 1213 transports electrons into the second layer 1112, and at the same time, the fourth layer 1214 transports holes into the second electrode 1102. In other words, a combination of the third layer 1213 and the fourth layer 1214 serves as a carrier generating layer. In addition, it can be said that the fourth layer 1214 has a function of transporting holes to the second electrode 1102. It should be noted that a multiphoton type light-emitting element can also be obtained by further stacking another second layer and another third layer between the fourth layer 1214 and the second electrode 1202.

Since the first layer 1211 or the fourth layer 1214 includes an organic compound and an inorganic compound showing an electron accepting property to the organic compound, the first layer 1211 or the fourth layer 1214 exhibits extremely excellent hole injecting and transporting properties. Therefore, the increase in driving voltage can be suppressed even when the thickness of the first layer 1211 is increased. Thus, in the light-emitting element of the present invention, it is possible that the opposites sides of the second layer 1212 having a light-emitting function, i.e., the first electrode side and the second electrode side of the second layer 1212, can be made extremely thicker. In other words, the distance between the first electrode and the second electrode can be made large. As a consequence, short-circuiting of the light emitting element can be prevented. Moreover, in order to improve the color purity by an optical design, the thicknesses in the both sides of the first electrode side and the second electrode side of the second layer 1212 can be freely set. Furthermore, in the case where, after forming the layer including a luminescent layer 1203, the first electrode 1201 or the second electrode 1202 is formed by sputtering, it is possible to avoid damage to the second layer 1212 including the luminescent substance. Further, by forming the first layer 1211 and the fourth layer 1214 using the same material, the layers formed with the same material are located at the opposite sides of the layer including a luminescent substance 1203, i.e., the first electrode side and the second electrode side thereof. Thus, it can be expected that stress strain can be suppressed.

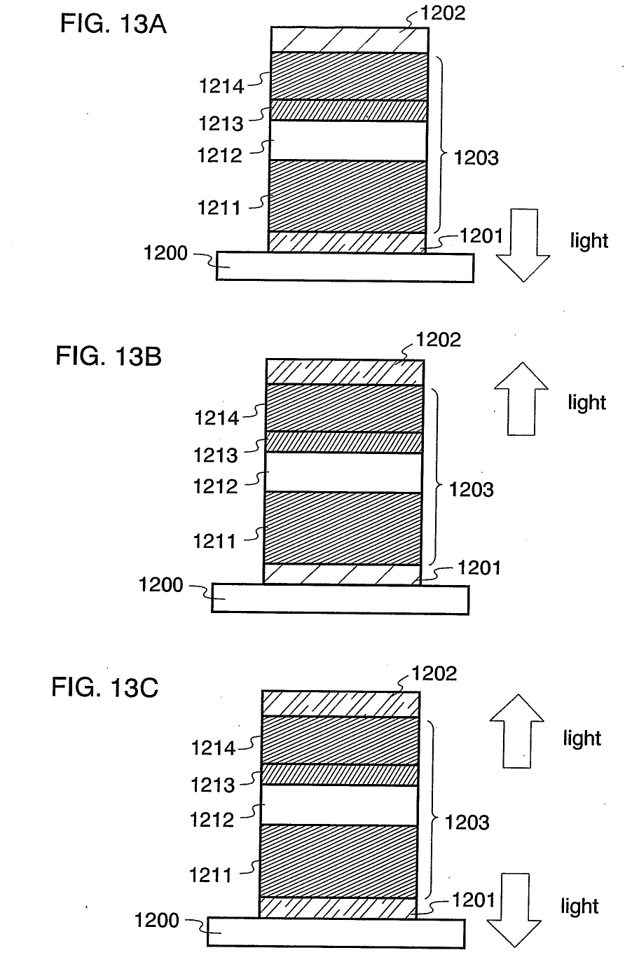

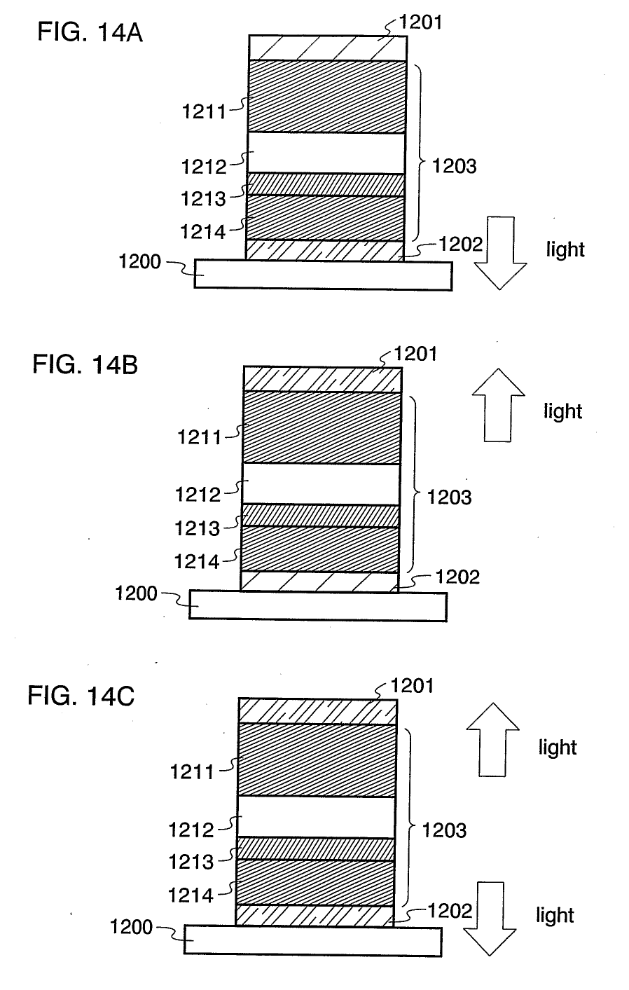

Further, in the light-emitting element of this embodiment mode, by changing the kinds of the first electrode 1201 and the second electrode 1202, there are many variations in the light emitting element. Schematic views of the variations are shown in FIGS. 13A to 13C and FIGS. 14A to 14C. The reference numerals used in FIG. 12 are also used in FIGS. 13A to 13C and FIGS. 14A to 14C. Reference numeral 1200 represents a substrate for supporting a light emitting element of the present invention.

FIGS. 13A to 13C each show an example in which a layer including a luminescent substance 1203 includes a first layer 1211, a second layer 1212, a third layer 1213, and a fourth layer 1214, which are stacked in this order over the substrate 1200. In this case, when the first electrode 1201 is formed using a material with a light transmitting property and the second electrode 1202 is formed using a material with a light-shielding property (in particular, light reflecting property), light can be emitted through the substrate 1200 as shown in FIG. 13A. When the first electrode 1201 is formed using a material with a light-shielding property (in particular, light reflecting property) and the second electrode 1202 is formed using a material with a light transmitting property, light can be emitted through the side opposite the substrate 1200 as shown in FIG. 13B. Further, when the first electrode 1201 and the second electrode 1202 are both formed using a material having a light transmitting property, light can be emitted through both the substrate 1200 and the side opposite the substrate, as shown in FIG. 13C.

FIGS. 14A to 14C each show an example in which a layer including a luminescent substance 1203 includes a fourth layer 1214, a third layer 1213, a second layer 1212 and a first layer 1211, which are stacked in this order over the substrate 1200. In this case, when the first electrode 1201 is formed using a material with a light-shielding property (in particular, light reflecting property) and the second electrode 1202 is formed using a substance with a light transmitting property, light can be emitted through the substrate 1200 as shown in FIG. 14A. When the first electrode 1201 is formed using a material with a light transmitting property and the second electrode 1202 is formed using a material with a light-shielding property (in particular, light reflecting property), light can be emitted through the side opposite side the substrate 1200 as shown in FIG. 14B. Further, when the first electrode 1201 and the second electrode 1202 are both formed using a material with a light transmitting property, light can be emitted through both the substrate 1200 and the side opposite the substrate 1200, as shown in FIG. 14C.

When the light-emitting element in this embodiment mode is formed, it can be formed in accordance with the method described in Embodiment Mode 12. In other words, the first electrode 1201, the second electrode 1202, the second layer 1212 and the third layer 1213 can be formed by a known method, and the first layer 1211, and the fourth layer 1214 each can be formed by appropriately adopting any one of the methods described in Embodiment Modes 9 to 12. The fourth layer 1214 may be formed by another method, for example, an evaporation method.

Further, when the fourth layer 1214 is formed using a composite material of the present invention by a wet method, the first layer 1211 may be formed by a known method such as an evaporation method. In addition, in the case of forming the fourth layer 1214 by a wet method, the first layer 1211 is not necessarily required.

After forming the first electrode 1201, the first layer 1211, the second layer 1212, the third layer 1213, and the fourth layer 1214 may be sequentially formed, and then, the second electrode 1202 may be formed. Alternatively, after forming the second electrode 1202 first, the fourth layer 1214, the third layer 1213, the second layer 1212, and the first layer 1211 may be sequentially formed, and then, the first electrode may be formed.

In addition, it is possible that the first layer 1211 includes a material having a donor level for generating electrons, the third layer 1213 includes an organic compound and an inorganic compound showing an electron accepting property to the organic compound, and the fourth layer 1214 includes a material having a donor level for generating electrons. In this case, since the third layer 1213 includes an organic compound and an inorganic compound showing an electron accepting property to the organic compound, it has an excellent hole transporting property. Therefore, the driving voltage of the light-emitting element can be reduced. In addition, the third layer 1213 can be freely set for the sake of enhancement in color purity by an optical design.

### Embodiment Mode 15

Embodiment Mode 15 will describe, in detail, an organic compound included in a composite material generating holes of the present invention.

As the organic compound included in a composite material generating holes of the present invention, any of low molecular weight compounds, middle molecular weight compounds, and high molecular weight compounds can be used, as long as they are each an organic compound having an arylamine skeleton. In this embodiment mode, a high molecular weight compound, which is-an organic compound included in a composite material generating holes of the present invention, is described.

As the high molecular weight compound, high molecular weight compounds with vinyl monomer, which are represented by the following general formulas or structural formulas (11) to (15).

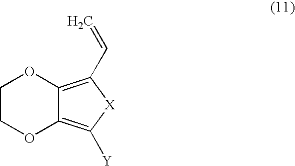

wherein X represents an oxygen atom (O) or a sulfur atom (S). Y represents any a hydrogen atom, an alkyl group, an aryl group, or a silyl group having an alkyl group or an aryl group as a substituent.

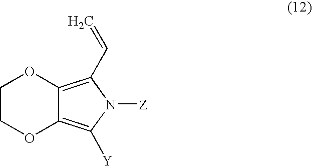

wherein Y represents a hydrogen atom, an alkyl group, an aryl group, or a silyl group having an alkyl group or an aryl group as a substituent. Z represents one of a hydrogen atom, an alkyl group, and a substituted or unsubstituted aryl group.

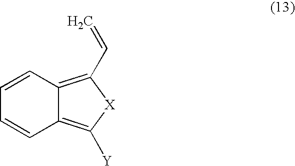

wherein X represents an oxygen atom (O) or a sulfur atom (S). Y represents a hydrogen atom, an alkyl group, an aryl group, or a silyl group having an alkyl group or an aryl group as a substituent.

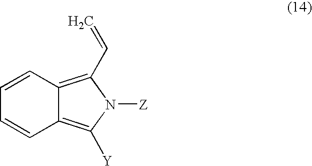

wherein Y represents a hydrogen atom, an alkyl group, an aryl group, or a silyl group having an alkyl group or an aryl group as a substituent. Z represents a hydrogen atom, an alkyl group, or a substituted or unsubstituted aryl group.

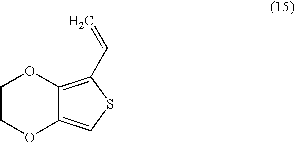

Specifically, high molecular weight compounds which are polymers represented by the following general formulas or structural formulas (1) to (5), can be used.

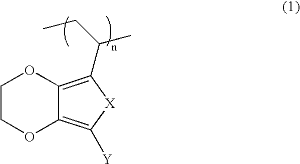

wherein X represents an oxygen atom (O) or a sulfur atom (S). Y represents a hydrogen atom, an alkyl group, an aryl group, or a silyl group having an alkyl group or an aryl group as a substituent. n is an integer of 2 or more.

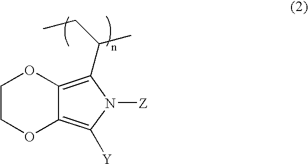

wherein Y represents a hydrogen atom, an alkyl group, an aryl group, or a silyl group having an alkyl group or an aryl group as a substituent. Z represents one of a hydrogen atom, an alkyl group, and a substituted or unsubstituted aryl group. n is an integer of 2 or more.

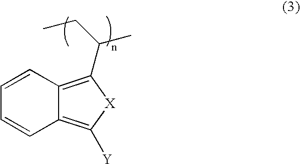

wherein X represents an oxygen atom (O) or a sulfur atom (S). Y represents a hydrogen atom, an alkyl group, an aryl group, or a silyl group having an alkyl group or an aryl group as a substituent. n is an integer of 2 or more.

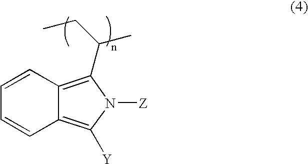

wherein Y represents a hydrogen atom, an alkyl group, an aryl group, or a silyl group having an alkyl group or an aryl group as a substituent. Z represents one of a hydrogen atom, an alkyl group, and a substituted or unsubstituted aryl group. n is an integer of 2 or more.

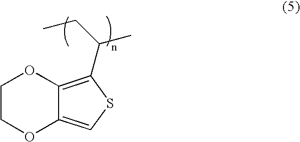

wherein n is an integer of 2 or more.

Further, high molecular weight compounds which are copolymers represented by the following general formulas or structural formulas (6) to (10), can be used.

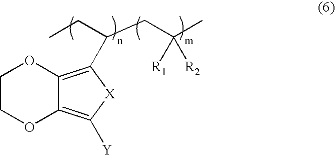

wherein X represents an oxygen atom (O) or a sulfur atom (S). Y represents a hydrogen atom, an alkyl group, an aryl group, or a silyl group having an alkyl group or an aryl group as a substituent. R₁ represents a hydrogen atom or an alkyl group. R₂ represents a substituted or unsubstituted aryl group, an ester group, a cyano group, an amide group, an alkoxy group, an oxycarbonyl alkyl group, or a diaryl amino group. n and m are individually an integer of 1 or more.

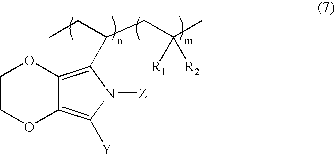

wherein Y represents a hydrogen atom, an alkyl group, an aryl group, or a silyl group having an alkyl group or an aryl group as a substituent. Z represents one of a hydrogen atom, an alkyl group, and a substituted or unsubstituted aryl group. R₁ represents a hydrogen atom or an alkyl group. R₂ represents a substituted or unsubstituted aryl group, an ester group, a cyano group, an amide group, an alkoxy group, an oxycarbonyl alkyl group, or a diaryl amino group. n and m are individually an integer of 1 or more.

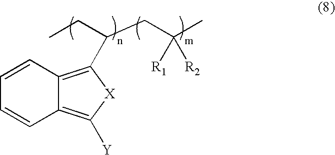

wherein X represents an oxygen atom (O) or a sulfur atom (S). Y represents a hydrogen atom, an alkyl group, an aryl group, or a silyl group having an alkyl group or an aryl group as a substituent. R₁ represents a hydrogen atom or an alkyl group. R₂ represents a substituted or unsubstituted aryl group, an ester group, a cyano group, an amide group, an alkoxy group, an oxycarbonyl alkyl group, or a diaryl amino group. n and m are individually an integer of 1 or more.

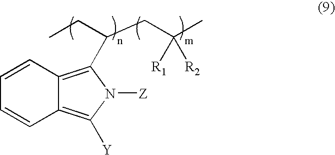

wherein Y represents a hydrogen atom, an alkyl group, an aryl group, or a silyl group having an alkyl group or an aryl group as a substituent. Z represents a hydrogen atom, an alkyl group, or a substituted or unsubstituted aryl group. R₁ represents a hydrogen atom or an alkyl group. R₂ represents a substituted or unsubstituted aryl group, an ester group, a cyano group, an amide group, an alkoxy group, an oxycarbonyl alkyl group, or a diaryl amino group. n and m are individually an integer of 1 or more.

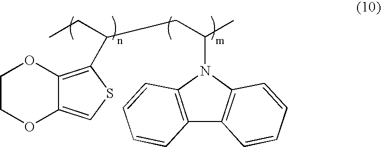

wherein n and m are individually an integer of 1 or more.

In the vinyl monomers represented by the above general formulas or structural formulas (11) to (15), vinyl groups contributing polymerization, which are conjugated with an aromatic substituent such as thiophene or a furan skeleton, are active in polymerization. In addition, since a thiophene ring, a furan skeleton, and a pyrrole ring are hetero aromatic rings that have excess electrons, the vinyl groups have an improved electron density. Therefore, the vinyl monomers represented by the above general formulas or structural formulas (11) to (15) easily give polymers by radical polymerization or cation polymerization. Additionally, in the vinyl monomers represented by the above general formulas (11) to (14), the solubility is increased by making Y in the formula a substituent other than a hydrogen atom, for example, an alkyl group, an aryl group, or a silyl group having an alkyl group or an aryl group as a substituent.

In addition, in the polymers represented by the general formulas or structural formulas (1) to (5), n is preferably an integer of 10 or more from the viewpoint of improvement in heat resistance. Further, in the copolymers represented by the general formulas or structural formulas (6) to (10), the sum of n and m is preferably an integer of 10 or more (however, n is an integer of 1 or more) from the viewpoint of improvement in heat resistance.

In the copolymer represented by the structural formula (10), a material that has aryl amine as a side chain can be used, other than vinyl carbazole. For example, it is possible to cite a copolymer represented by the general formula (8), wherein a material in which R₁ is a hydrogen atom, and R₂ is a substance represented by any one of the following structural formulas (16), (17), (18), and (19).

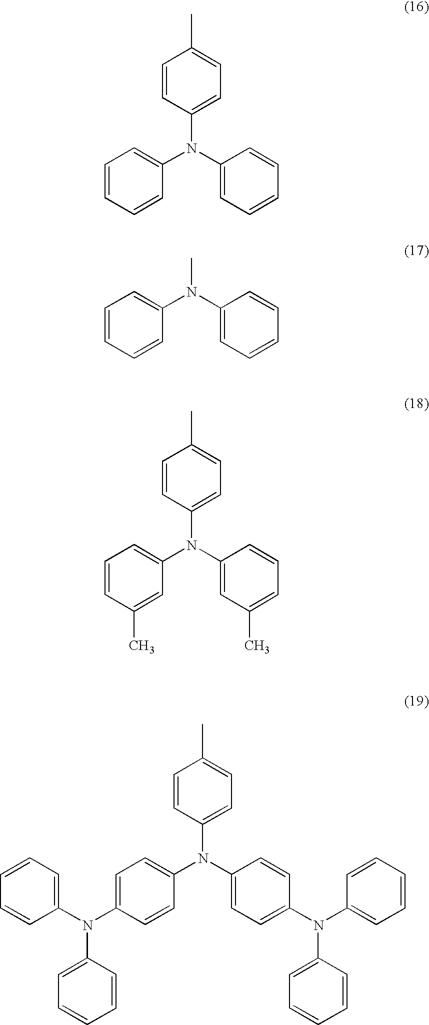

### Embodiment Mode 16

A light-emitting element of the present invention will be explained. The light emitting-element of the present invention includes a luminescent substance and a composite material between a pair of electrodes. A composite material is a material made by combining an organic compound and an inorganic compound.

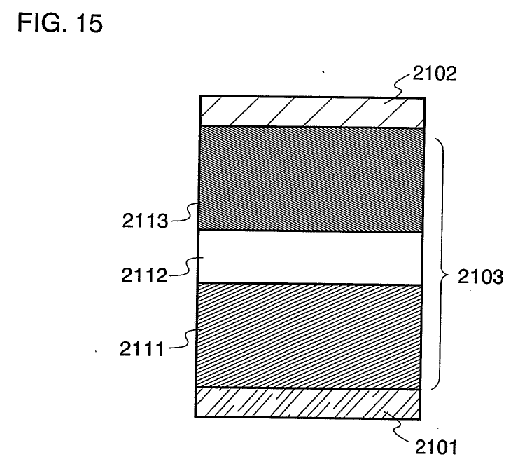

FIG. 15 shows a structure of a light-emitting element of the present invention as an example. In the light-emitting element, a layer including a luminescent substance 2103 is interposed between a first electrode 2101 and a second electrode 2102. The structure of the layer including a luminescent substance 2103 is a stacked structure of a first layer 2111, a second layer 2112, and a third layer 2113. This embodiment mode explains a case when the first electrode 2101 functions as an anode and the second electrode 2102 functions as a cathode.

The first layer 2111 takes on a function of transporting holes to the second layer 2112, and contains a hole-generating first composite material. This hole-generating first composite material is made by combining a first organic compound, and a first inorganic compound showing an electron-accepting property to the first organic compound. By the transfer of electrons between the first organic compound and the first inorganic compound, a large number of holes are generated. For this reason, excellent hole-injecting property and hole-transporting property are exhibited. Therefore, by using the hole-generating first composite material, the driving voltage of a light-emitting element can be reduced.

As the first organic compound included in the hole-generating first composite material, it is desirable to use a compound having an excellent property of transporting the generated holes, and the use of an organic compound having an arylamine skeleton is preferred. More specifically, organic compounds such as 4,4′4″-tris(N,N-diphenylamino)triphenylamine (TDATA); 4,4′,4″-tris[N-(3-methylphenyl)-N-phenylamino]triphenylamine (MTDATA); 1,3,5-tris[N,N-bis(3-methylphenyl)amino]benzene (m-MTDAB); N,N′-diphenyl-N,N′-bis(3-methylphenyl)-1,1′-biphenyl-4,4′-diamine (TPD); 4,4′-bis[N-(1-naphthyl)-N-phenylamino]biphenyl (NPB); 4,4′-bis(N-{4-[N,N-bis(3-methylphenyl)amino]phenyl}-N-phenylamono)biphenyl (DNTPD); 4,4′,4″-tris(N-carbazolyl)triphenylamine (TCTA); poly(4-vinyltriphenylamine) (PVTPA); and poly(N-vinylcarbazole) (PVK) may be given, but is not limited to these organic compounds.

As the first inorganic compound included in the hole-generating first composite material, it is preferable to use an oxide containing a transition metal. Specifically, it is preferable to use one or plural of titanium oxide, vanadium oxide, molybdenum oxide, tungsten oxide, rhenium oxide, or ruthenium oxide. It also may be a composite oxide including a skeleton of these oxides. Further, the oxide containing a transition metal may have a hydroxyl group.

By using an oxide containing a transition metal, electron transfer is carried out between the oxide containing a transition metal and nitrogen of an arylamine skeleton, and holes can be generated. Since holes are generated internally, high conductivity can be obtained when an electric field is applied.

Also, since the first composite material has high conductivity, increase in driving voltage can be supressed even when the thickness increases. Therefore, since the thickness of the first layer 2111 can be increased without increasing the driving voltage, short-circuiting of the light-emitting element caused by unwanted particles, dusts or the like, can be suppressed.

Further, because the first composite material contains an inorganic compound, heat resistance of the light-emitting element can be improved.

Incidentally, the first layer 2111 may take form in a variety of states, such as a state in which the first organic compound becomes a matrix and the first inorganic compound is dispersed therein, a state in which the first inorganic compound becomes a matrix and the first organic compound is dispersed therein, or a state in which the first organic compound and the first inorganic compound are contained in nearly equal amounts and bound to each other. Regardless of the state, however, electrons will be transferred between the first organic compound and the first inorganic compound, and excellent hole-injecting and hole-tranporting properties, as well as high conductivity can be obtained.

Further, when the hole-generating first compound material is used to form a film, a material that serves as a binder (a binder substance) may be added in order to improve the quality of the film. Especially, when a compound with a low molecular weight (specifically, a compound having a molecule weight of 500 or less) is used as the first organic compound, a binder substance becomes necessary for the sake of film quality. Needless to say, a binder substance may also be added when using a high molecular weight compound. As a binder substance, polyvinyl alcohol (PVA), polymethyl methacrylate (PMMA), polycarbonate (PC), a phenol resin, and the like can be given.

Here, the third layer 2113 will be explained. The third layer 2113 takes on a function of transporting electrons to the second layer 2112, and includes an electron-generating second composite material. The electron-generating second composite material is made by combining a second organic compound, and a second inorganic compound showing an electron-donating property to the second organic compound. By the transfer of electrons between the second organic compound and the second inorganic compound, a large number of electrons are generated. For this reason, excellent electron-injecting property and electron-transporting property are exhibited. Therefore, by using the electron-generating second composite material, the driving voltage of a light-emitting element can be reduced.

As the second organic compound included in the electron-generating second composite material, it is desirable that it be a material having an excellent property of transporting the generated electrons, and it is preferable to use an organic compound having a pyridine skeleton, an imidazole skeleton, a triazole skeleton, an oxadiazole skeleton, an oxazole skeleton, or a thiazole skeleton. More specifically, organic compounds such as tris(8-quinolinolato)aluminum (Alq₃); tris(4-methyl-8-quinolinolato)aluminum (Almq₃); bis(10-hydroxybenzo [h]quinolinato)beryllium (BeBq₂); bis(2-methyl-8-quinolinolato)(4-phenylphenolato)aluminum (BAlq); bis[2-(2′-hydroxyphenyl)benzoxazolato]zinc (Zn(BOX)₂); bis[2-(2′-hydroxyphenyl)benzothiazolatolzinc (Zn(BTZ)₂); bathophenanthroline (BPhen);bathocuproin (BCP); 2-(4-biphenylyl)-5-(4-tert-butylphenyl)-1,3,4-oxadiazole (PBD); 1,3-bis[5-(4-tert-butylphenyl)-1,3,4-oxadiazol-2-yl]benzene (OXD-7); 2,2′,2″-(1,3,5-benzenetriyl)-tris(1-phenyl-1H-benzimidazole) (TPBI); 3-(4-biphenylyl)-4-phenyl-5-(4-tert-butylphenyl)-1,2,4-triazole (TAZ); 3-(4-biphenylyl)-4-(4-ethylphenyl)-5-(4-tert-butylphenyl)-1,2,4-triazole (p-EtTAZ); and poly(4-vinylpyridine) (PVPy) may be given, but is not limited to these organic compounds.

As the second inorganic compound contained in the electron-generating second composite material, it is preferable to use an oxide containing an alkali metal or an alkaline earth metal. Specifically, it is preferable to use one or plural of lithium oxide, calcium oxide, and barium oxide. Also a composite oxide including a skeleton of these oxides may be used. Further, the oxide containing an alkali metal or an alkaline earth metal may have a hydroxyl group.

By using an oxide containing an alkali metal or an alkaline earth metal, electron transfer is carried out between the oxide containing an alkali metal or an alkaline earth metal, and a pyridine skeleton or the like, and electrons can be generated. Since electrons are generated internally, high conductivity can be obtained when an electric field is applied.

Also, since the second composite material has high conductivity, increase in driving voltage can be supressed even when the thickness increases. Therefore, since the thickness of the third layer 2113 can be increased without increasing the driving voltage, short-circuiting of the light-emitting element caused by unwanted particles, dust and the like, can be suppressed.

Further, because the second composite material contains an inorganic compound, heat resistance of the light-emitting element can be improved.

Incidentally, the third layer 2113 may take form in a variety of states, such as a state in which the second organic compound becomes a matrix and the second inorganic compound is dispersed therein, a state in which the second inorganic compound becomes a matrix and the second organic compound is dispersed therein, or a state in which the second organic compound and the second inorganic compound are contained in nearly equal amounts and bound to each other. Regardless of the state, however, electrons will be transferred between the second organic compound and the second inorganic compound, and excellent electron-injecting and electron-transporting properties as well as high conductivity can be obtained.

Further, when the electron-generating second compound material is used to form a film, a material that serves as a binder (a binder substance) may be added in order to improve the quality of the film. When a compound with a low molecular weight (specifically, a compound having a molecule weight of 500 or less) is used as the second organic compound, a binder substance becomes necessary for the sake of film quality. Needless to say, a binder substance may also be added when using a high molecular weight compound for the second organic compound. As the binder substance, polyvinyl alcohol (PVA), polymethyl methacrylate (PMMA), polycarbonate (PC), a phenol resin, and the like can be given.

The second layer 2112 takes on a light-emitting function, and it is acceptable as long as the layer contains at least a luminescent substance. As for the luminescent substance, a known material can be used. Further, besides a luminescent substance, another material may be included in the second layer 2112. For example, in the same way as the first layer 2111 or third layer 2113, it may include an inorganic compound as well as an organic compound having a light-emitting property. By the second layer also having a structure containing an inorganic compound, an effect of improving heat resistance can be obtained.

In the light-emitting element explained in this embodiment mode, the first layer 2111 or the third layer 2113 exhibits extremely strong carrier-injecting and carrier-transporting properties. It also has high conductivity. Consequently, the light-emitting element of this embodiment mode can suppress the increase in driving voltage, and a layer between the second layer having a light-emitting function and the first electrode, and a layer between the second layer having a light-emitting function and the second electrode, can be made thick. In other words, it becomes possible to make the distance between the first electrode and the second electrode wide, and can prevent short-circuiting in the light-emitting element.

In a case of forming the first electrode 2101 or the second electrode 2102 by sputtering after forming the layer including a luminescent substance 2103, damage to the second layer 2112, which includes the luminescent substance, can be reduced.

Since the increase in driving voltage can be suppressed even if the film thickness of the first layer 2111 or the third layer 2113 is increased, the film thickness of the first layer 2111 and the third layer 2113 can be freely set, and the light extraction efficiency from the second layer 2112 can be improved. Also, film thicknesses of the first layer 2111 and the third layer 2113 can be set to improve the color purity of light emission from the second layer 2112.

Further, because the light-emitting element of the present invention has materials with low toxicity and harmful effects, effects on the environment and the human body can be reduced.

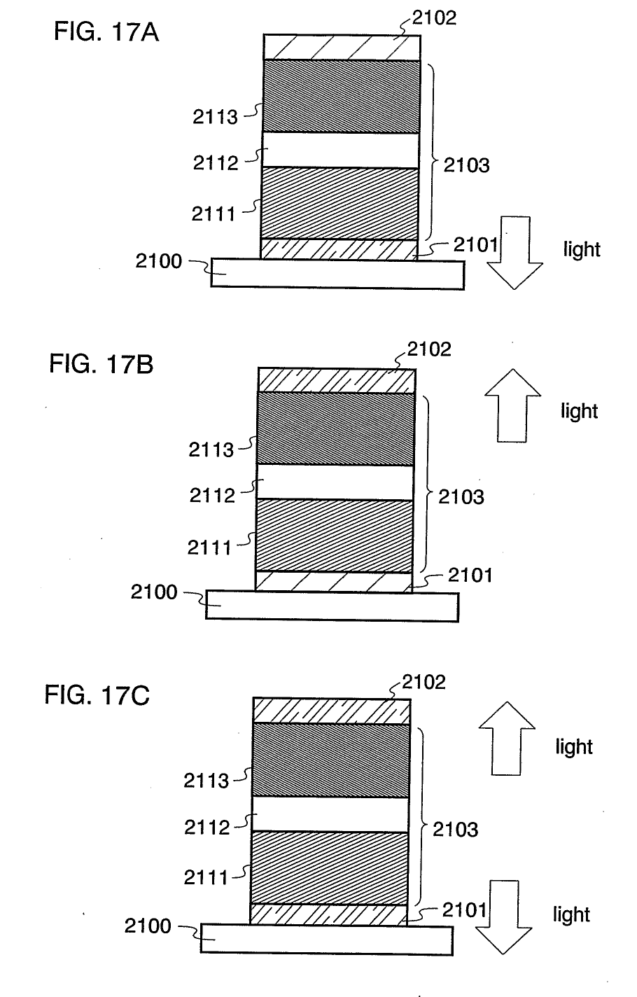

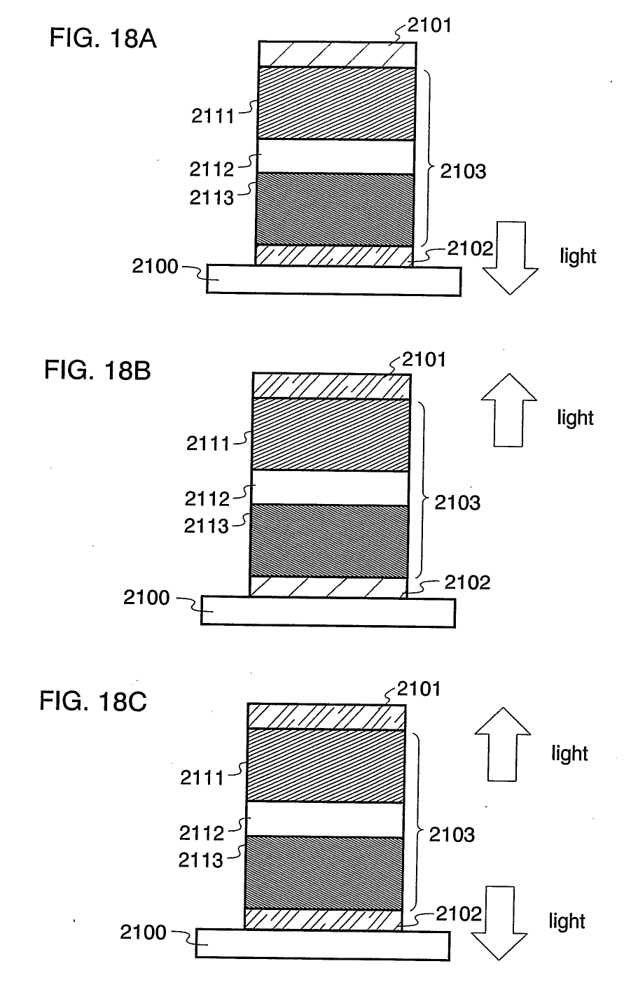

There are many variations in the light-emitting element of this embodiment mode, by changing the types of the first electrode 2101 or the second electrode 2102. These variations are shown in the schematic views of FIGS. 17A to 17C and 18A to 18C. The reference numerals use in FIG. 15 are also used in FIGS. 17A to 17C and 18A to 18C. Also, reference numeral 2100 represents a substrate supporting the light-emitting element of the present invention.

FIGS. 17A to 17C are examples of a case in which the layer including a luminescent substance 2103 has a structure in which the first layer 2111, the second layer 2112, and the third layer 2113 are sequentially formed over the substrate 2100. By the first electrode 2101 having a light-transmitting property, and by the second electrode 2102 having a light-shielding property (specifically a light-reflecting property), light is emitted through the substrate 2100, as in FIG. 17A. Also, by the first electrode 2101 having a light-shielding property (especially a light-reflecting property), and by the second electrode 2102 having a light-transmitting property, light is emitted from the side opposite the substrate 2100, as in FIG. 17B. Further, by the first electrode 2101 and the second electrode 2102 both having light-transmitting properties, light is emitted from the opposite sides of the light-emitting element, i.e., both the side of the substrate 2100 and the opposite side the substrate 2100, as shown in FIG. 17C.

FIGS. 18A to 18C are examples of a case in which the layer including a luminescent substance 2103 has a structure in which the third layer 2113, the second layer 2112, and the first layer 2111 are formed in this order over the substrate 2100. When the first electrode 2101 has a light-shielding property (especially a light-reflecting. property), and when the second electrode 2102 has a light-transmitting property, light is extracted from the substrate 2100 side, as shown in FIG. 18A. Also, when the first electrode 2101 has a light-transmitting property, and when the second electrode 2102 has a light-shielding property (especially a light-reflecting property), light is extracted from the side opposite the substrate 2100, as shown in FIG. 18B. Furthermore, when both the first electrode 2101 and second electrode 2102 have light-transmitting properties, light can be emitted from the opposite sides of the light-emitting element, i.e., the substrate 2100 side and the side opposite the substrate 2100 as shown in FIG. 18C.

### Embodiment Mode 17

Embodiment Mode 17 will describe a manufacturing method of the light-emitting element shown in Embodiment Mode 16.

The first electrode 2101 is formed first. The first electrode 2101 can be formed using a known material by a known method. Specifically, a metal compound such as indium tin oxide (ITO), indium tin oxide including silicon (ITSO), indium oxide including zinc oxide of 2 to 20 wt % (IZO), titanium nitride; a metal such as Cr, W, Zn, Pt, Al, or Ag; or an alloy thereof, etc, is preferably used. For example, indium oxide-zinc oxide (IZO) can be formed by a sputtering method using indium oxide into which zinc oxide of 1 to 20 wt % is added, as a target. In addition, indium oxide-tin oxide including tungsten oxide and zinc oxide (IWZO) can be formed by a sputtering method using indium oxide into which tungsten oxide of 0.5 to 5 wt % and zinc oxide of 0.1 to 1 wt % are added, as a target.

Next, the first layer 2111 is formed. The first layer 2111 can be formed by any one of the methods shown in Embodiment Modes 9 to 11. The methods shown in Embodiment Modes 9 to 11 are each a wet method, and thus, can respond to the increase in a substrate size.

Then, the second layer 2112 is formed. The second layer 2112 can be formed using a known material by a known method. When the second layer 2112 is formed by a wet method, which can respond to the increase in a substrate size, all layers included in the layer including a luminescent substance 2103 can be formed by a wet method. Thus, the manufacturing method using a wet method is suitable for mass production. For example, a luminescent substance such as poly (2,5-dihexoxy-1,4-phenylenevinylene) (MEH-PPV) can be formed by a wet method.

Subsequently, the third layer 2113 is formed. The third layer 2113 can be formed by any of the methods shown in Embodiment Modes 2 and 3. Since the methods shown in Embodiment Modes 2 and 3 are each a wet method, they can respond to the increase in a substrate size.

The second electrode 2102 can be formed using a known material by a known method. Specifically, the materials mentioned when the first electrode 2101 is described above can be used. One or both of the first electrode 2101 and the second electrode 2102 may have a light-transmitting property.

In accordance with the above method, a light-emitting element of the present invention can be manufactured. Since the manufacturing method of a light-emitting element of the present invention can form the first layer 2111 and the third layer 2113 by a wet method, it can respond to the increase in a substrate size and is suitable for mass production. Specifically, when the second layer 2112 is also formed using a known polymer light-emitting material or the like by a wet method, all layers in the layer including a luminescent substance 2103 can be formed by a wet method, and thus, it can respond to the increase in a substrate size. Thus, the present invention is suitable for mass production.

In this embodiment mode, a method for forming layers from the first electrode 2101 side (over the first electrode 2101) has been described. However, a light-emitting element may be formed by forming layers sequentially from the second electrode 2102 side (over the second electrode 2102). That is, it is possible to form the light-emitting element of the present invention by forming the second electrode 2102 first, forming the third layer 2113, the second layer 2112, and the first layer 2111 sequentially and then forming the first electrode 2101.

### Embodiment Mode 18

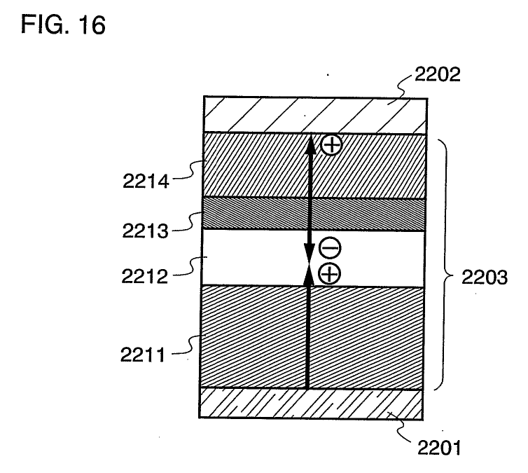

Embodiment Mode 18 will describe a light-emitting element having a structure different from that shown in Embodiment Mode 16 with reference to FIG. 16.

FIG. 16 shows an example of the structure of the light-emitting element of the present invention. A layer including a luminescent substance 2203 is sandwiched between a first electrode 2201 and a second electrode 2202. The layer including a luminescent substance 2203 has a structure in which a first layer 2211, a second layer 2212, a third layer 2213 and a fourth layer 2214 are sequentially stacked. In this embodiment mode, the first electrode 2201 serves as an anode, and the second electrode 2202 serves as a cathode.

The first electrode 2201, the second electrode 2202, the first layer 2211, the second layer 2212, and the third layer 2213 can have the same structures as the respective layers in Embodiment Mode 16 (i.e., FIG. 15). In other words, the first electrode can be formed using a known material, the first layer 2211 includes a composite material having a first organic compound and a first inorganic compound showing an electron accepting property to the first organic compound, the second layer 2212 includes a luminescent substance, and the third layer 2213 includes a composite material having a second organic compound and a second inorganic compound showing an electron donating property to the second organic compound. The difference between the light-emitting element in this embodiment mode and that in Embodiment Mode 16 is that the fourth layer 2214 is formed between the third layer 2213 and the second electrode 2202.

The fourth layer 2214 includes at least a third composite material having a third organic compound and a third inorganic compound showing an electron accepting property to the third organic compound. Thus, the first organic compounds described in Embodiment Mode 1 can be used as the third organic compound, and the first inorganic compounds described in Embodiment Mode 1 can be used as the third inorganic compound. However, the third organic compound may be the same as or different from the first organic compound, and the third inorganic compound may be the same as or different from the first inorganic compound.

By adopting such a structure, as shown in FIG. 16, electron transfer is conducted in the vicinity of an interface between the third layer 2213 and the fourth layer 2214 by applying a voltage, and electrons and holes are generated. Then, the third layer 2213 transports electrons into the second layer 2112, and at the same time, the fourth layer 2214 transports holes into the second electrode 2102. In other words, a combination of the third layer 2213 and the fourth layer 2214 serves as a carrier generating layer. In addition, it can be said that the fourth layer 2214 has a function of transporting holes to the second electrode 2102. It should be noted that a multiphoton type light-emitting element can also obtained by stacking another second layer and another third layer between the fourth layer 2214 and the second electrode 2202.

Since the first layer 2211 or the fourth layer 2214 exhibits extremely excellent hole injecting and transporting properties. Thus, in the light-emitting element of this embodiment mode, it is possible that the opposites sides of the second layer having a light-emitting function, i.e., the first electrode side and the second electrode side of the second layer, can be made extremely thicker. In other words, the distance between the first electrode and the second electrode can be made large. As a consequence, short-circuiting of the light emitting element can be prevented. Furthermore, like an example shown in FIG. 16, in a case where the second electrode 2202 is formed by sputtering, it is possible to avoid damage to the second layer 2212 including the luminescent substance. Further, by forming the first layer 2211 and the fourth layer 2214 using the same material, the layers formed with the same material are located at the opposite sides of the layer including a luminescent substance 2203, i.e., the first electrode side and the second electrode side thereof. Thus, it can be expected that stress strain can be suppressed.

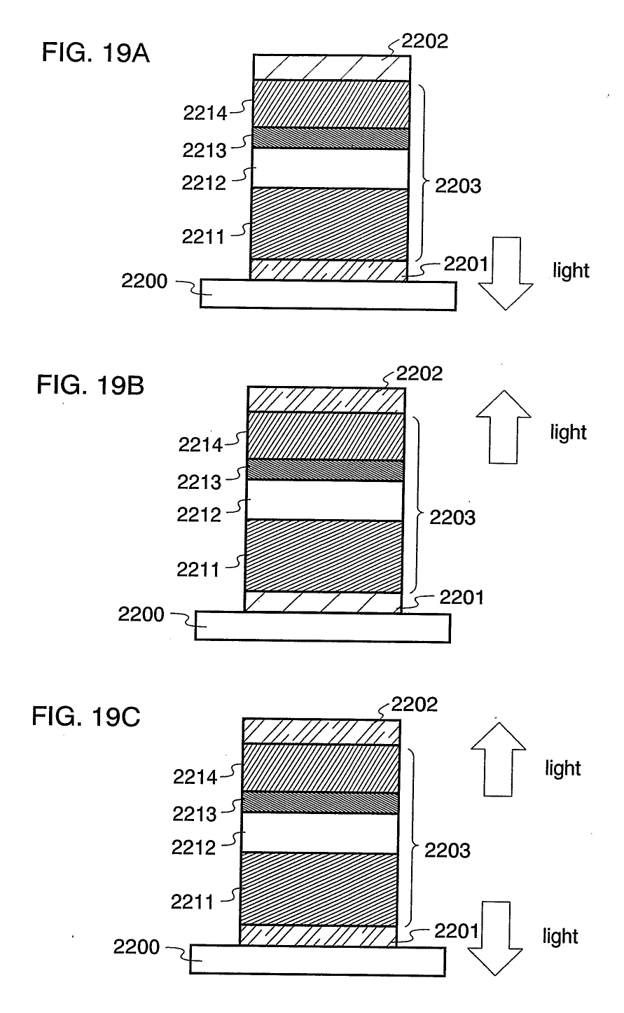

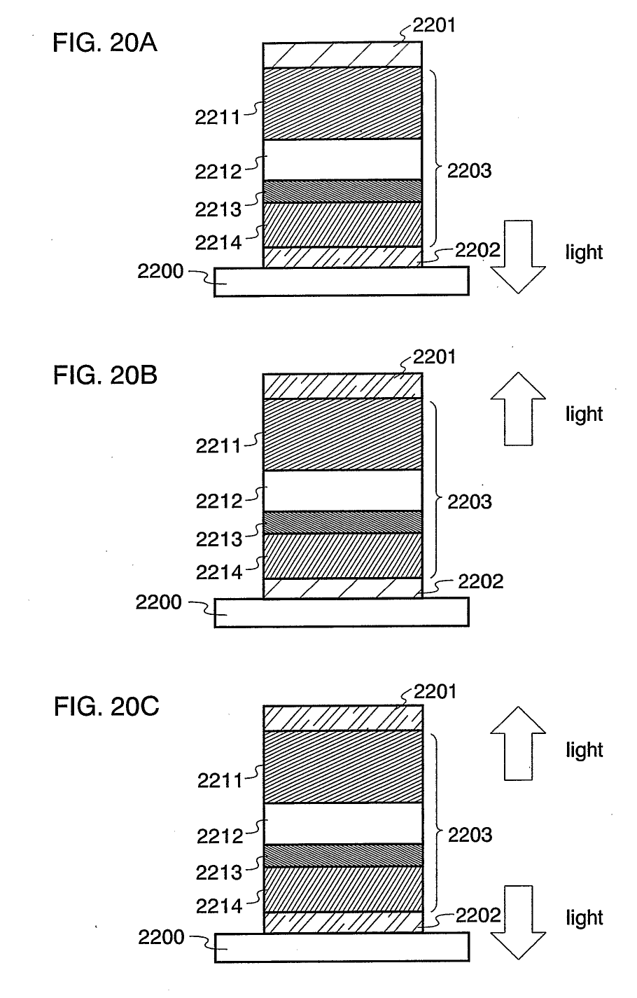

Further, in the light-emitting element of this embodiment mode, by changing the kinds of the first electrode 2201 and the second electrode 2202, there are many variations in the light-emitting element. Schematic views of the variations are shown in FIGS. 19A to 19C and FIGS. 20A to 20C. The reference numerals used in FIG. 16 are also used in FIGS. 19A to 19C and FIGS. 20A to 20C. Reference numeral 2200 represents a substrate for supporting a light-emitting element of the present invention.

FIGS. 19A to 19C each show an example in which a layer including a luminescent substance 2203 includes a first layer 2211, a second layer 2212, a third layer 2213, and a fourth layer 2214, which are stacked in this order over the substrate 2200. In this case, when the first electrode 2201 is formed using a material with a light transmitting property and the second electrode 2202 is formed using a material with a light-shielding property (in particular, light reflecting property), light can be emitted through the substrate 2200 as shown in FIG. 19A. When the first electrode 2201 is formed using a material with a light-shielding property (in particular, light-reflecting property) and the second electrode 2202 is formed using a material with a light transmitting property, light can be emitted through the side opposite the substrate 2200 as shown in FIG. 19B. Further, when the first electrode 2201 and the second electrode 2202 are both formed using a material having a light transmitting property, light can be emitted through both the substrate 2200 and the side opposite the substrate, as shown in FIG. 19C.

FIGS. 20A to 20C each show an example in which a layer including a luminescent substance 2203 includes a fourth layer 2214, a third layer 2213, a second layer 2212 and a first layer 2211, which are stacked in this order over the substrate 2200. In this case, when the first electrode 2201 is formed using a material with a light-shielding property (in particular, light reflecting property) and the second electrode 2202 is formed using a substance with a light transmitting property, light can be emitted through the substrate 2200 as shown in FIG. 20A. When the first electrode 2201 is formed using a material with a light transmitting property and the second electrode 2,202 is formed using a material with a light-shielding property (in particular, light reflecting property), light can be emitted through the side opposite the substrate 2200 as shown in FIG. 20B. Further, when the first electrode 2201 and the second electrode 2202 are both formed using a material with a light transmitting property, light can be emitted through both the substrate 2200 and the side opposite the substrate 2200, as shown in FIG. 20C.

When the first layer 2211 includes a composite material of the second organic compound and the second inorganic compound showing an electron donating property to the second organic compound, the second layer 2212 includes a luminescent substance, the third layer 2213 includes a composite material of the first organic compound and the first inorganic compound showing an electron accepting property to the first organic compound, and the fourth layer 2214 includes the composite material of the second organic compound and the second inorganic compound showing an electron donating property to the second organic compound, the same effect can be obtained. In this case, the first layer 2211 or the fourth layer 2214 shows an extremely strong electron injecting property and an extremely high electron transporting property. Thus, a layer between the first electrode and the second layer having a light-emitting function, and a layer between the second electrode and the second layer having a light-emitting function, can be made much thicker, thereby preventing short-circuiting of the light-emitting element. Further, damages to the second layer can be reduced. In addition, stress strain can be suppressed.

When the light-emitting element in this embodiment mode is formed, it can be formed in accordance with the method described in Embodiment Mode 7. In other words, the first electrode 2201, the second electrode 2202, and the second layer 2212 can be formed by a known method, and the first layer 2211, the third layer 2213, and the fourth layer 2214 can each formed by appropriately adopting any one of the methods described in Embodiment Modes 2, 3 and 9 to 11. The fourth layer 2214 may be formed by another method, for example, an evaporation method.

After forming the first electrode 2201, the first layer 2211, the second layer 2212, the third layer 2213, and the fourth layer 2214 may be sequentially formed, and then, the second electrode 2202 may be formed. Alternatively, after forming the second electrode 2202, the fourth layer 2214, the third layer 2213, the second layer 2212, and the first layer 2211 may be sequentially formed, and then, the first electrode may be formed.

### Embodiment Mode 19

Embodiment Mode 19 will describe a light-emitting device having a light-emitting element of the present invention.

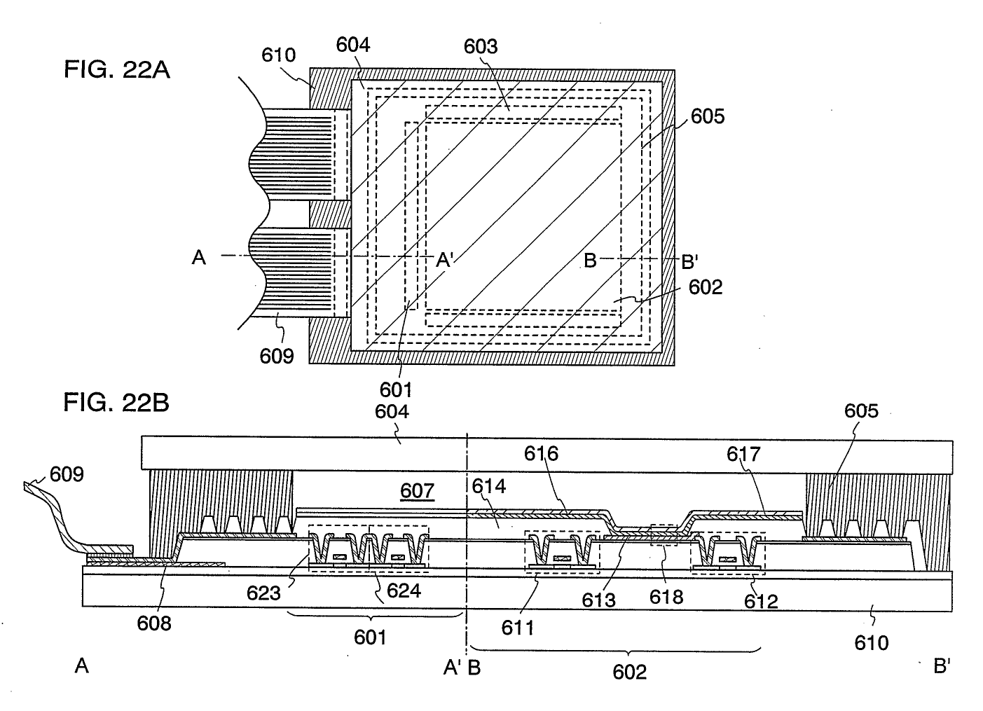

This embodiment mode describes a light-emitting device having a light-emitting element of the present invention in its pixel portion with reference to FIGS. 22A and 22B. FIG. 22A is a top view of the light-emitting device, while FIG. 22B is a cross-sectional view taken along A-A′ and B-B′ in FIG. 22A. Reference numeral 601 shown by a dotted line denotes a driver circuit portion (source side driver circuit); 602, a pixel portion; 603, a driver circuit portion (gate side driver circuit); 604, a sealing substrate; 605, a sealing material; and 607, a space surrounded by the sealing material 605.

Reference numeral 608 denotes a wiring for transmitting signals to be inputted into the source side driver circuit portion 601 and the gate side driver circuit portion 603 and receiving signals such as a video signal, a clock signal, a start signal, and a reset signal from an FPC (flexible printed circuit) 609 serving as an external input terminal. Although only the FPC is illustrated here, a print wiring board (PWB) may be attached to this FPC, and the light-emitting device in this specification may include not only the light-emitting device itself but also the light-emitting device with the FPC and/or the PWB attached thereto.

Next, the cross-sectional structure is described with reference to FIG. 22B. The driver circuit portion and the pixel portion are formed over an element substrate 610. In this embodiment mode, the source side driver circuit portion 601, which is the driver circuit portion, and one pixel of the pixel portion 602 are shown.

In the source side driver circuit portion 601, a CMOS circuit is formed in which an n-channel TFT 623 and a p-channel TFT 624 are combined. Further, the TFT forming the driver circuit may be formed with a known CMOS circuit, PMOS circuit, or NMOS circuit using TFTs. Although this embodiment mode shows an example of forming the pixel portion and the driver circuit formed over the same substrate, the present invention is not limited to this, and the driver circuit can also be formed outside, not over the same substrate as the pixel portion.

The pixel portion 602 is formed with a plurality of pixels including a switching TFT 611, a current controlling TFT 612, and a first electrode 613 connected electrically with a drain of the current controlling TFT. An insulator 614 is formed to cover the end portions of the first electrode 613. Here, a positive photosensitive acrylic resin film is used.

In order to improve the coverage, the insulator 614 is formed to have a curved surface with curvature at its upper or lower end portion. For example, in the case of using positive photosensitive acrylic for the insulator 614, only the upper end portion of the insulator 614 preferably has a curved surface with a radius of curvature of 0.2 to 3 μm. The insulator 614 may be formed with either a negative type, which becomes insoluble to the etchant by the irradiation of light, or a positive type, which becomes soluble to the etchant by the irradiation of light.

A layer including a luminescent substance 616 and a second electrode 617 are formed over the first electrode 613. The first electrode 613 serving as an anode is preferably formed with a material having a high work function. For example, a single layer of an indium tin oxide (ITO) film, an indium tin oxide film containing silicon, an indium oxide film containing zinc oxide (ZnO) of 2 to 20 wt %, a titanium nitride film, a chromium film, a tungsten film, a Zn film, a Pt film, a stacked layer of a titanium nitride film and a film mainly containing aluminum, a three-layer stacked structure of a titanium nitride film, a film mainly containing aluminum and a titanium nitride film, and the like can be used. Note that, when a stacked structure is employed, resistance of a wiring is low and a favorable ohmic contact is obtained.

The layer including a luminescent substance 616 includes a composite material generating carriers shown in Embodiment Mode 8. Specifically, the first composite material including the first organic compound and the first inorganic compound showing an electron accepting property to the first organic compound, and the second composite material including the second organic compound and the second inorganic compound showing an electron donating property to the second organic compound are included in the layer including a luminescent substance 616. These composite materials generating carriers can be formed by the methods shown in Embodiment Modes 2, 3 and 9 to 11. Since the methods are each a wet method, they can respond to the increase in a substrate size. When other layers included in the layer including a luminescent substance 616 than the layer of the composite material generating carriers, are formed by a wet method, all layers included in the layer including a luminescent substance 616 can be formed by a wet method. Thus, it is suitable for mass production.

In addition, a known material can be used, as a material which can be combined with the composite material generating carriers, and a low molecular weight compound, a middle molecular weight (including oligomer or dendrimer), or a high molecular weight compound may be used.

The composite material generating carriers shown in Embodiment Mode 1 has an excellent carrier injecting property and an excellent carrier transporting property, because electron transfer is conducted between the organic compound and the inorganic compound. Thus, the driving voltage of a light-emitting element can be reduced.

As the material for the second electrode (cathode) 617 formed over the layer including a luminescent material 616, a material having a low work function is preferable. For example, Al, Mg, Li, Ca, an alloy or compound such as MgAg, MgIn, LiF, AlLi, CaF₂ or calcium nitride or the like can preferably be used. When light generated in the layer including a luminescent material 616 passes through the second electrode 617, a stacked layer of a thin metal film having a thin thickness, and a transparent conductive film (such as ITO, indium oxide including zinc oxide of 2 to 20 wt %, indium tin oxide including silicon, zinc oxide (ZnO) or the like) can be used as the second electrode (cathode) 617.

Further, a light-emitting element 618 is provided in the space 607 surrounded with the element substrate 610, the sealing substrate 604, and the sealing material 605 by pasting the sealing substrate 604 and the element substrate 610 using the sealing material 605. The space 607 may be filled with an inert gas (such as nitrogen or argon), or the sealing material 605.

An epoxy based resin is preferably used for the sealing material 605. It is preferable that these materials do not transmit oxygen or moisture as much as possible. As the material for the sealing substrate 604, a glass substrate, a quartz substrate, a plastic substrate made of FRP (Fiberglass-Reinforced Plastics), PVF (polyvinyl fluoride), mylar, polyester, acrylic, or the like can be used.

As thus described, a light-emitting device having a light-emitting element of the present invention can be obtained.

Since a light-emitting element of the present invention uses an organic compound, and an inorganic compound which can transfer electrons with the organic compound, the conductivity is high and the driving voltage can be reduced. Therefore, power consumption can be reduced.

In addition, since the conductivity of the composite material included in a light-emitting element of the present invention is high, the thickness of the layer including a luminescent substance 616 can be made thicker without increasing the driving voltage. Thus, short-circuiting of an element, to be caused by dusts or the like can be suppressed. Therefore, a light-emitting device with fewer defects can be provided.

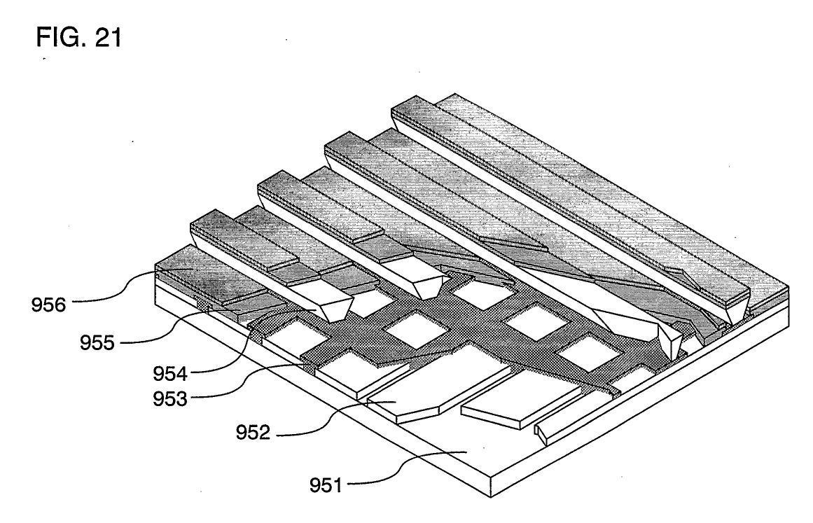

As set forth above, an active light-emitting device which controls the driving of the light-emitting element using a transistor has been described in this embodiment mode. In addition, a passive light-emitting device which drives a light-emitting element without providing a driving element such as a transistor may be employed. FIG. 21 shows a perspective view of a passive light-emitting device which is manufactured in accordance with the present invention. In FIG. 21, a layer including a luminescent substance 955 is provided between an electrode 952 and an electrode 956 over a substrate 951. An edge portion of the electrode 952 is covered with an insulating layer 953. A partition layer 954 is provided over the insulating layer 953. The sidewalls of the partition layer 954 are aslope such that the distance between both sidewalls is gradually narrowed toward the surface of the substrate. That is, a cross section in a short side of the partition layer 954 is a trapezoidal shape, and a lower side (the side is in contact with the insulating layer 953) is shorter than an upper side (the side is not in contact with the insulating layer 953). By providing the partition layer 954 in this manner, defects of the light-emitting element due to static charge and the like can be prevented. In addition, by utilizing the light-emitting element of the present invention, which operates at low driving voltage, for a passive light-emitting device, the passive light-emitting device can be driven at lower power consumption.

### Embodiment Mode 20

Embodiment mode 20 will describe various electronic devices each including a light-emitting device formed using a light-emitting element of the present invention as a part thereof.

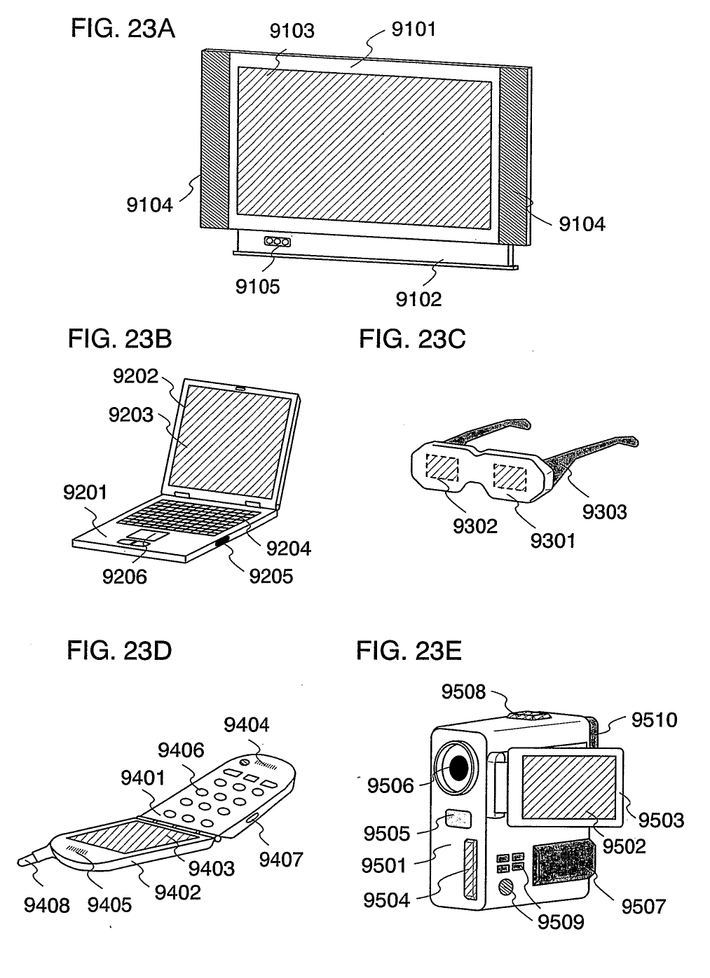

Electronic devices manufactured using a light-emitting device having a light-emitting element of the present invention are, for example, cameras such as video cameras or digital cameras, goggle type displays, navigation systems, sound reproduction devices (such a car audios or audio components), computers, game machines, mobile information terminals (such as mobile computers, cell phones, portable game machines, or electronic books), image reproduction devices utilizing a recording medium (such as devices which can reproduce a recording medium such as a digital versatile disk (DVD) and is equipped with a display device capable of displaying the image) and the like. These electronic devices are specifically shown in FIGS. 23A to 23E.

FIG. 23A shows a television receiving machine including a casing 9101, a supporting stand 9102, a display portion 9103, speaker portions 9104, a video input terminal 9105, and the like. The television receiving machine of the present invention is manufactured by using a light-emitting device having a light-emitting element of the present invention for the display portion 9103. By using the light-emitting device of the present invention, a television receiving machine with low power consumption and having a display portion with few defects can be provided. It is to be noted that the television receiving machine includes all types of information display devices, e.g., a display device for a computer, one for TV broadcast reception, one for advertisement display, and so on.

FIG. 23B shows a computer including a main body 9201, a casing 9202, a display portion 9203, a keyboard 9204, an external connection port 9205, a pointing mouse 9206, and the like. The computer of the present invention is manufactured by using a light-emitting device having a light-emitting element of the present invention for the display portion 9203. By using the light-emitting device of the present invention, a computer with low power consumption and having a display portion with few defects can be provided.

FIG. 23C shows a goggle-type display including a main body 9301, display portions 9302, arm portions 9303, and the like. The goggle-type display of the present invention is manufactured by using a light-emitting device having a light-emitting element of the present invention for the display portion 9302. By using the light-emitting device of the present invention, a goggle-type display with low power consumption and having a display portion with few defects can be provided.

FIG. 23D shows a cell phone including a main body 9401, a casing 9402, a display portion 9403, an audio input portion 9404, an audio output portion 9405, operation keys 9406, an external connection port 9407, an antenna 9408, and the like. The cell phone of the present invention is manufactured by using a light-emitting device having a light-emitting element of the present invention for the display portion 9403. By using the light-emitting device of the present invention, a cell phone with low power consumption and having a display portion with few defects can be provided. In addition, the power consumption can be suppressed by displaying white characters against black in the display portion 9403.

FIG. 23E shows a camera including a main body 9501, a display portion 9502, a casing 9503, an external connection port 9504, a remote control receiving portion 9505, an image receiving portion 9506, a battery 9507, an audio input portion 9508, operation keys 9509, an eyepiece portion 9510, and the like. The camera of the present invention is manufactured by using a light-emitting device having a light-emitting element of the present invention for the display portion 9502. By using the light-emitting device of the present invention, a camera with low power consumption and having a display portion with few defects can be provided.

As thus described, a light-emitting device having a light-emitting element according to the present invention can be applied in an extremely wide range, and the light-emitting device can be applied to electronic devices of every field. By using a light-emitting device having a light-emitting element of the present invention, electronic devices with low power consumption and few defects can be provided.

### EXAMPLE 1

### Synthesis Example 1

In the present synthesis example, synthesis of a compound shown by the structural formula (15), 2-ethenyl-3,4-ethylenedioxythiophene, will be described. The synthesis scheme (a) is shown as follows.

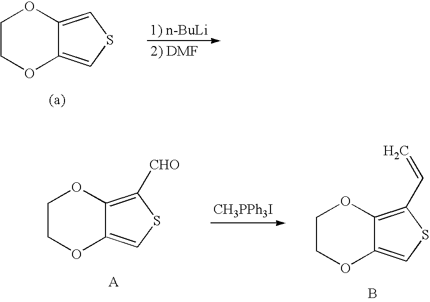

Under a nitrogen atmosphere, a 1.58 N hexane solution of n-butyllithium (158 mL, 0.1 mol) was dropped, at −78° C., into a dried tetrahydrofran (130 mL) solution of 3, 4-ethylenedioxythiophene (13.8 g, 0.1 mol). After the dropping, stirring: was performed at −78° C. for 45 minutes. After adding dried DMF (7.3 g, 0.1 mol) to this suspension, the reaction mixture was heated at 45° C. for 2 hours. About 100 mL of 1 N HCl was added to the reaction mixture, and stirring was continued further for 10 minutes. The reaction solution was extracted with ether, and the ether was removed. By recrystallizing the residue with hexane, 2-formyl-3,4-ethylenedioxythiophene (a compound A in the synthesis scheme (a), 13.21 g, yield: 84%) was obtained.

Under a nitrogen atmosphere, a 1.58 N hexane solution of n-butyllithium (49 mL, 78 mmol) was dropped, at −40° C., into a dried THF solution of a methyltriphenylphosphonium iodide salt (78 mmol). After the dropping, and then cooling to −78° C., a dried THF solution (70 mL) of 2-formyl-3,4-ethylenedioxythiophene (the compound A in the synthesis scheme (a)) was added to this reaction mixture. After that, the reaction mixture was brought back to a room temperature, and stirred for 24 hours. The reaction solution was extracted with ether, and the ether was removed. By purifying the residue by silica-gel chromatography (developing solvent: hexane/ethyl acetate), 2-ethenyl-3,4-ethylenedioxythiophene represented by the structural formula (5) (a compound B in the synthesis scheme (a), 6.93 g, yield: 58%) was obtained. Here is NMR data of the compound B. ¹H NMR (300 MHz, CDCl₃) δ 6.70 (dd, J=11, 18 Hz, 1H), 6.18 (s, 1H), 5.48 (q, J=18 Hz, 1H), 5.06 (d, J=11 Hz ,1H), 4.18-4.25 (m, 4H).

### Synthesis Example 2

In the present synthesis example, an example of homopolymerization of 2-ethenyl-3,4-ethylenedioxythiophene represented by the structural formula (15) will be described. The synthesis scheme (b) is shown below.

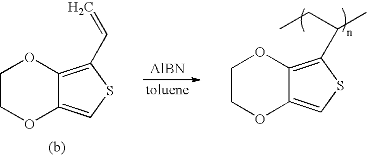

Under nitrogen, 2-ethenyl-3,4-ethylenedioxythiophene (1.3 g) was dissolved in 1 mL of toluene, and azobisisobutyronitrile (32.8 mg) dissolved in 1 mL of toluene was added thereto. The reaction solution was left at 60° C. for 24 hours. By putting the reaction solution in excess ethanol, and filtering and drying generated precipitation, a corresponding polymer, poly(2-ethenyl-3,4-ethylenedioxythiophene), was obtained. Yield: 50 mg (yield: 36%). The decomposition temperature and glass transition temperature of this compound under a nitrogen atmosphere were 340° C. and 158° C., respectively. The ionization potential was 5.60 eV.

### Synthesis Example 3

In the present synthesis example, an example of copolymerization of 2-ethenyl-3,4-ethylenedioxythiophene represented by the structural formula (15) and N-vinylcarbazole in a solution will be described. The synthesis scheme (c) is shown below.

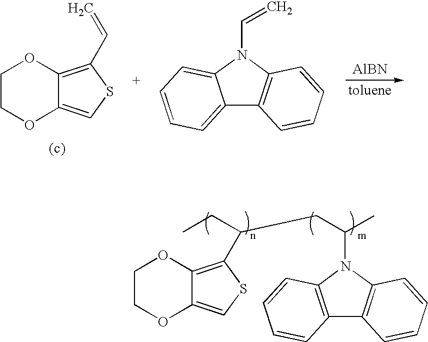

Under nitrogen, 2-ethenyl-3,4-ethylenedioxythiophene (0.4 mmol) and N-vinylcarbazole (3.6 mmol) were dissolved in 1 mL of toluene, and azobisisobutyronitrile (0.2 mmol) dissolved in 1 mL of toluene was added thereto. The reaction solution was left at 60° C. for 24 hours. By putting the reaction solution in excess methanol, and filtering and drying generated precipitation, a polymer shown by the general formula (10), poly(2-ethenyl-3,4-ethylenedioxythiophene-co-N-vinylcarbazole), was obtained. Yield: 79 mg (yield: 32%). The 5% weight loss temperature of this copolymer under a nitrogen atmosphere was 190° C. In addition, in a differential scanning calorimetry measurement (DSC measurement), no grass transition temperature was shown at this temperature or less.

### Synthesis Example 4

In the present synthesis example, an example of bulk copolymerization of 2-ethenyl-3,4-ethylenedioxythiophene represented by the structural formula (15) and N-vinylcarbazole will be described. The synthesis scheme (d) is shown below.

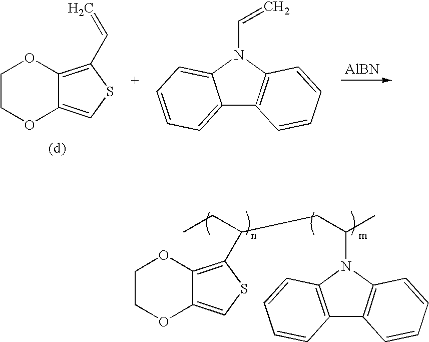

Under nitrogen, azobisisobutyronitrile (0.29 mmol) was added to 2-ethenyl-3, 4-ethylenedioxythiophene (0.57 mmol) and N-vinylcarbazole (5.24 mmol) to react at 80° C. for 48 hours. By reprecipitating a generated polymer with methanol, a copolymer shown by the general formula (10) was isolated. Yield: 230 mg (yield: 21%).

### EXAMPLE 2

Example 2 will concretely describe a light-emitting element of the present invention. An element structure is described with reference to FIG. 8.

A glass substrate over which indium tin oxide including silicon was formed to have a thickness of 110 nm, was prepared. The formed indium tin oxide including silicon serves as a first electrode 1101 in this example.

A solution in which PVK of 0.125 g, TPD of 0.125 g, and titanium (IV) tetra isopropoxide of 0.02 g are dissolved in 25 mL of toluene, was prepared. This solution was dropped onto the prepared substrate. The substrate was spin-coated with this solution at 800 rpm for 5 seconds and then, at 1200 rpm for 60 seconds. Further, it was baked at 50° C. in the air, and then, at 50° C. for 30 minutes under vacuum to form a composite material. Thus, the first layer 1111 was obtained.

The second layer 1112 was formed. The second layer 1112 was formed with a hole transporting layer, a light-emitting layer, an electron transporting layer and an electron injecting layer.

As described above, the substrate provided with the first layer 1111 was fixed on a substrate holder in a vacuum evaporation apparatus in such a way that the surface provided with the first layer is on the downside. Then, NPB was deposited with a thickness of 10 nm by a vacuum evaporation method using resistance heating to form a hole transporting layer. Next, a light-emitting layer in which coumarin 6 was added into Alq₃, was formed. At this time, a co-evaporation method in which Alq₃ and coumarin 6 were evaporated by resistance heating at the same time, was employed to adjust so that the mass ratio of Alq₃ and coumarin 6 was 1: 0.003. The film thickness was made to be 37.5 nm. Further, an Alq₃ film was formed as an electron transporting layer with a thickness of 37.5 nm, and a CaF₂ film was formed as an electron injecting layer with a thickness of 1 nm. Both films were formed by a vacuum evaporation method using resistance heating.

As described above, after forming the second layer 1112, Al was deposited to have a thickness of 200 nm as the second electrode 1102. In this manner, a light-emitting element of the present invention was obtained.

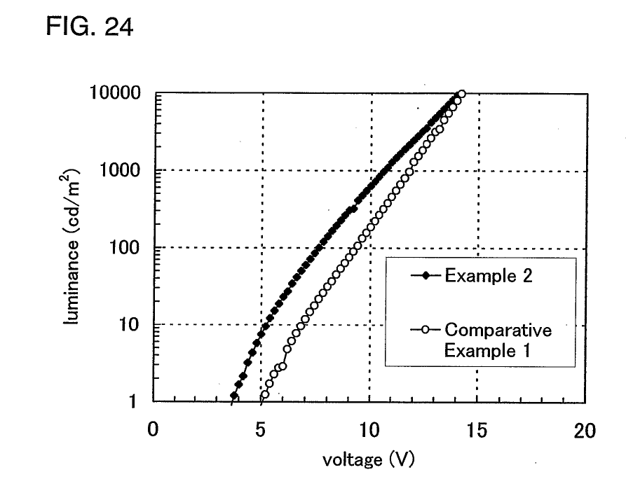

FIG. 24 shows a voltage-luminance characteristic of a light-emitting element of the present invention. As shown in FIG. 24, the voltage needed to obtain luminance of 1000 cd/m² was 10.6 V. In addition, the current efficiency at this time was 13.0 cd/A.

### COMPARATIVE EXAMPLE 1

A comparative example is shown concretely, in which a conventional hole injecting layer was used instead of the first layer 1111 in the above light-emitting element. The hole injecting layer in the comparative example 1 was obtained by preparing a solution in which titanium (IV) tetra isopropoxide was removed from the solution shown in Example 2, and applying and baking the solution in the same way. In addition, the first electrode 1101, the second electrode 1102 and the second layer 1112 were the same as those in Example 2.

FIG. 24 also shows a voltage-luminance characteristic of a light-emitting element as the comparative example 1. As shown in FIG. 24, the voltage needed to obtain luminance of 1000 cd/m² was 11.8 V. The voltage was higher than that of Example 2 by 1V. It should be noted that the current efficiency at this time was 13.6 cd/A, and the current efficiency was almost the same. Therefore, it could be understood that, by applying the present invention, the driving voltage can be decreased without changing the current efficiency.

### EXAMPLE 3

Example 3 shows a measurement example of electric characteristics of a composite material generating holes, in which 4,4′-bis[N-(1-naphthyl)-N-phenylamino]biphenyl (NPB) was used as an organic compound having an excellent hole transporting property; poly(methyl methacrylate) (PMMA) was used as a binder substance; and titanium oxide (TiOₓ) was used as an inorganic compound showing an electron accepting property to the organic compound. Moreover, as a comparative example, an example in which electric characteristics of a material which does not include TiOₓ was measured, is also shown.

A solution for coating was prepared in which PMMA (Mw=996000) of 0.125 g, NPB of 0.125 g (0.21 mmol), and titanium (IV) tetra isopropoxide, which is a raw material of TiOₓ, of 0.060 g (0.21 mmol) were dissolved in 25 mL of a mixed solvent in which chloroform and toluene were dissolved in the ratio of 1:1.

In addition, a substrate in which a transparent electrode (indium tin silicon oxide, ITSO) having a 2-mm square was formed, was prepared, and rinsed with ultrasonic wave using acetone, pure water, and ethanol in this order. Thereafter, it was rinsed by boiled ethanol, and was finally exposed to UV ozone treatment for 370 seconds.

Then, the solution which had been prepared was made to pass through a 0.45 μm filter and was dropped onto a substrate. The substrate was spin-coated with the solution at 1000 rpm for 60 seconds. The spin-coated substrate and a beaker filled with pure water were put in an electric heating furnace, and were heated at 40° C. for 2 hours to conduct hydrolysis with water vapor. Further, after the beaker filled with pure water was taken out of the furnace, the substrate was baked at 120° C. for 1.5 hours while evacuating air from the furnace by a rotary pump. In this way, a composite material generating holes which were formed with NPB, PMMA and titanium oxide was obtained. The film thickness was 100 nm.

Lastly, an electrode of Al was formed to have a thickness of 100 nm over the formed composite material by a vacuum evaporation method. A single layer element for measurement of electric characteristics, having an element structure shown below, was manufactured.

In other words, a transparent electrode (ITSO) was formed, a composite material generating holes (100 nm), which was formed from NPB, PMMA and titanium oxide, was formed, and then, Al (100 nm) was formed to manufacture a light-emitting element of the present example.

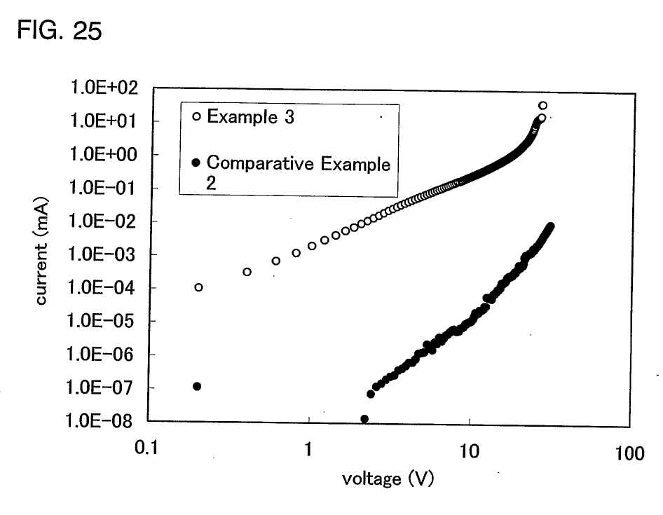

A measurement of a voltage-current characteristic was conducted to the element manufactured as described above by forwardly biasing to the ITSO. FIG. 25 shows a measurement result. In FIG. 25, the horizontal axis represents voltage (unit: V) and the vertical axis represents current (unit: mA). As shown in FIG. 25, the composite material generating holes of the present invention exhibits an excellent voltage-current characteristic. Specifically, current of 0.1 mA (i.e., current density of 2.5 mA/cm²) flows at 5.8 V, and sufficient current for driving a light-emitting element flows.

### COMPARATIVE EXAMPLE 2

For comparison, a material in which an inorganic compound (titanium oxide) was removed from the material of Example 3, or a material which was formed with an organic compound (NPB) and a binder substance (PMMA) only, was formed over the same substrate as that in Example 3. In this way, a comparative element was manufactured.

A manufacturing method of a comparative element is described below. A solution for coating was prepared in which PMMA (Mw=996000) of 0.125 g and NPB of 0.125 g (0.21 mmol) were dissolved in 25 mL of a mixed solvent in which chloroform and toluene were dissolved in the ratio of 1:1.

Then, the prepared solution passed through a 0.45 μm filter and was dropped onto the same substrate as that in Example 3. The substrate was spin-coated with the solution at 620 rpm for 60 seconds. The spin-coated substrate was put in an electric heating furnace, and was heated at 120° C. for 1.5 hours while evacuating air from the furnace by a rotary pump. The film thickness was 100 nm.

Lastly, Al was deposited as an electrode to have a thickness of 100 nm by a vacuum evaporation method, and a comparative element having an element structure shown below was manufactured.

In other words, a transparent electrode (ITSO) was formed, a material (100 nm), which was formed from NPB and PMMA was formed, and then, Al (100 nm) was formed to manufacture a comparative element.

A measurement of a voltage-current characteristic was conducted to the comparative element by forwardly biasing to the ITSO. FIG. 25 shows the measurement result of the comparative example 2. As shown in FIG. 25, in the comparative element of the comparative example 2, almost no current flow until the voltage becomes 2.4 V, and the same electric characteristic is shown as that of a conventional organic compound which exhibits the rise of the voltage-current characteristic at 2.4 V or more. In addition, the amount of current flowing in the comparative element when a certain voltage was applied, was inferior by 3 to 5 digits to the element manufactured in Example 3, although the thickness of the comparative element was almost the same as that of the element manufactured in Example 3.

### EXAMPLE 4

Example 4 shows a measurement example of electric characteristics of a composite material generating holes, in which 4,4′-bis[N-(1-naphthyl)-N-phenylamino]biphenyl (NPB) was used as an organic compound having an excellent hole transporting property; poly(methyl methacrylate) (PMMA) was used as a binder substance; and vanadium oxide (VOₓ) was used as an inorganic compound showing an electron accepting property to the organic compound.

A solution was prepared in which PMMA (Mw=996000) of 0.25 g and NPB of 0.243 g (0.41 mmol) were dissolved in 50 mL of a mixed solvent in which 25 mL of chloroform and 25 mL of toluene were mixed. The solution was divided equally into two solutions of 25 mL Vanadium (V) triisopropoxide of 0.051 g (0.21 mmol), Which is a raw material of VOₓ, and ethyl acetoacetate of 0.025 g (0.19 mmol) as a stabilizer, were mixed into one solution of them, to obtain a solution I. It should be noted that the other solution of 25 mL is a solution II (the solution II was used in Example 5.)

In addition, a substrate in which a transparent electrode (indium tin silicon oxide, ITSO) having a 2-mm square was formed was prepared, and rinsed with ultrasonic wave using acetone, pure water, and ethanol in this order. Thereafter, it was rinsed by boiled ethanol, and was exposed to UV ozone treatment finally for 370 seconds.

Next, the prepared solution I passed through a 0.45 μm filter and was dropped onto the substrate. The substrate was spin-coated with the solution at 1100 rpm for 60 seconds, while rotating the substrate. The spin-coated substrate and a beaker filled with pure water were put in an electric heating furnace, and were heated at 40° C. for 2 hours to conduct hydrolysis with water vapor. Further, after the beaker filled with pure water was taken out of the furnace, the substrate was baked at 120° C. for 1.5 hours while evacuating air from the furnace by a rotary pump. In this way, a composite material generating holes which were formed with NPB, PMMA and vanadium oxide was obtained. The film thickness was 100 nm.

Lastly, an electrode of Al was formed to have a thickness of 100 nm over the formed composite material by a vacuum evaporation method. A single layer element for measurement of electric characteristics, having an element structure shown below, was manufactured.

In other words, a transparent electrode (ITSO) was formed, a composite material generating holes (100 nm), which was formed from NPB, PMMA and vanadium oxide, was formed, and then, Al (100 nm) was formed to manufacture a light-emitting element of the present example.

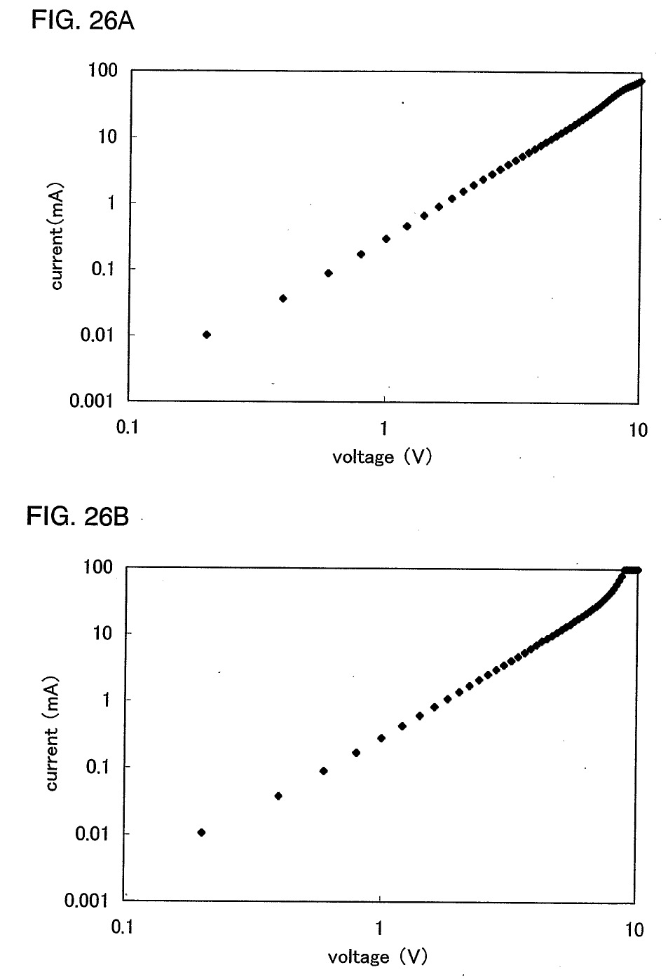

A measurement of a voltage-current characteristic was conducted to the element manufactured as described above. FIG. 26A shows a voltage-current characteristic in a case that a forward bias is applied to the ITSO, in other words, a voltage is applied so that the ITSO become a positive bias, while FIG. 26B shows a voltage-current characteristic in a case that a reverse bias is applied to the ITSO, in other words, a voltage is applied so that the ITSO become a negative bias. In FIGS. 26A and 26B, the horizontal axis represents voltage (unit: V) and the vertical axis represents current (unit: mA). As shown in FIGS. 26A and 26B, the composite material generating holes of the present example exhibits an excellent voltage-current characteristic. Specifically, current of 0.1 mA (i.e., current density of 2.5 mA/cm²) flows at as small as 0.6 V in the forward bias, and sufficient current for driving a light-emitting element flows.

In addition, in both cases of forward bias and reverse bias, almost the same voltage-current characteristics were exhibited. This means that the composite material generating holes of the present invention can have an ohmic contact with both ITSO and Al.

### EXAMPLE 5

In order to examine the factor that the composite material formed in the above example 4 (a composite material including NPB, PMMA and vanadium oxide) has an extremely excellent electric characteristic, the absorption spectrum was measured in Example 5. In addition, for comparison, the absorption spectrum of a material which does not include vanadium oxide (i.e., a material formed with NPB and PMMA) was also measured.

The solution I prepared in Example 4 passed through a filter of 0.45 μm, and was dropped onto a quartz substrate. The quartz substrate was spin-coated with the solution at 200 rpm for 2 seconds then, at 2000 rpm for 60 seconds, and at 3000 rpm for 10 seconds while rotating the substrate. The spin-coated substrate and a beaker filled with pure water were put in an electric heating furnace, and were heated at 40° C. for 2 hours to conduct hydrolysis with water vapor. Further, after the beaker filled with pure water was taken out of the furnace, the substrate was baked at 120° C. for 1.5 hours while evacuating air from the furnace by a rotary pump. In this way, a composite material generating holes which were formed with NPB, PMMA and vanadium oxide was obtained on the quartz substrate.

### COMPARATIVE EXAMPLE 3

The solution II prepared in Example 4 passed through a filter of 0.45 μm, and was dropped onto a quartz substrate. The quartz substrate was spin-coated with the solution at 200 rpm for 2 seconds, at 2000 rpm for 60 seconds, and at 3000 rpm for 10 seconds while rotating the substrate. The spin-coated substrate was put in an electric heating furnace, and was heated 120° C. for 1.5 hours while evacuating air from the furnace by a rotary pump. In this way, a material which was formed with NPB, and PMMA was obtained on the quartz substrate.

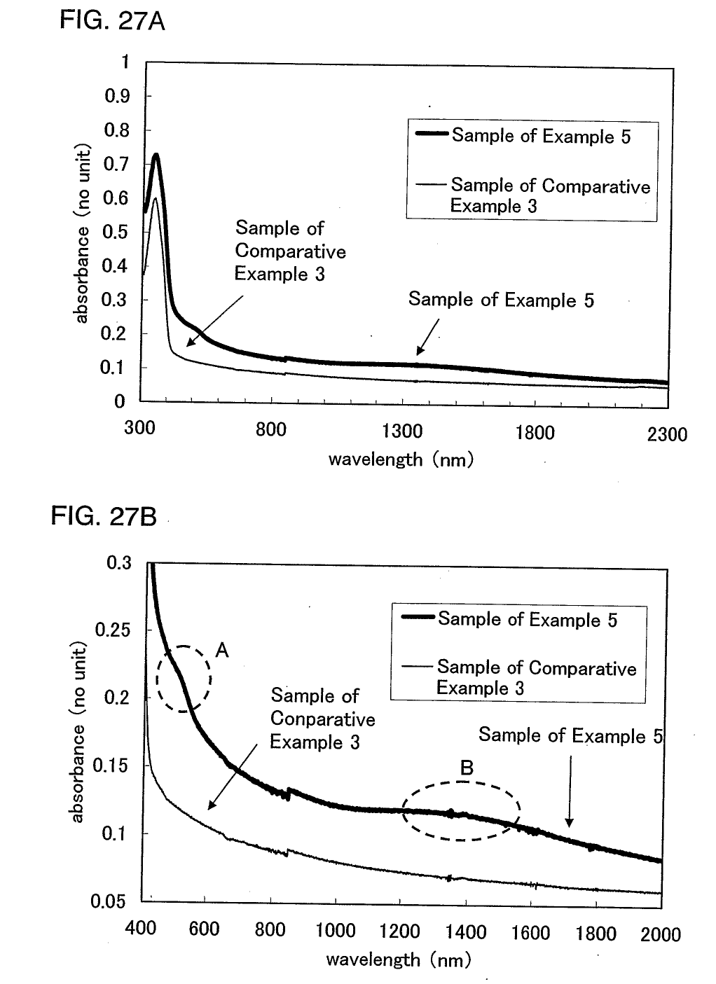

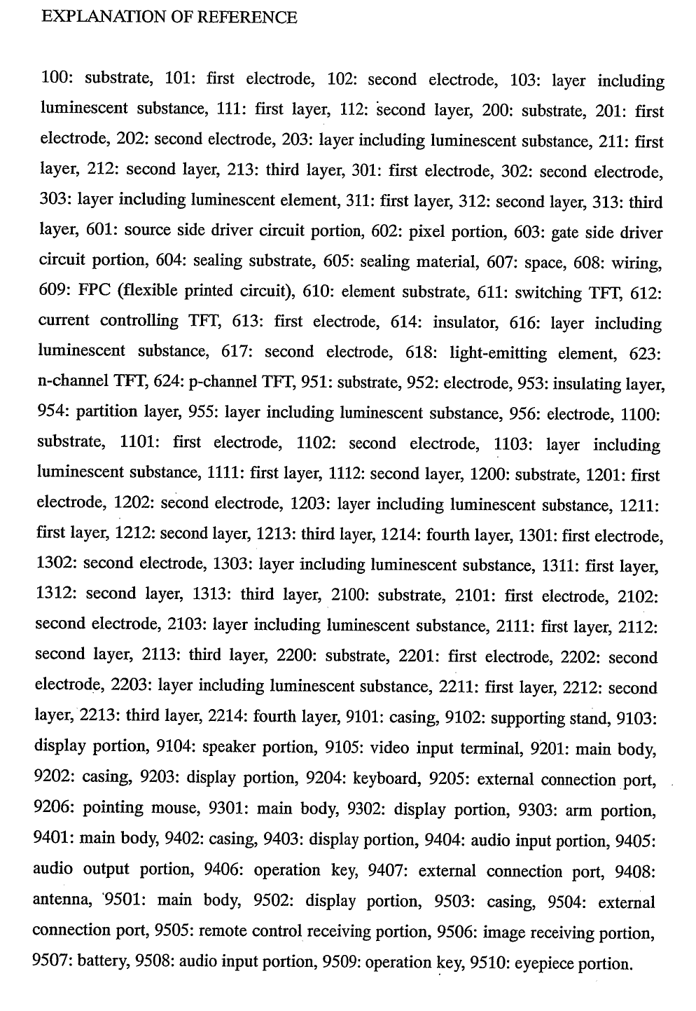

The absorption spectra of the sample formed in Example 5 as described above and the sample formed in the comparative example 3 were measured. The obtained results are shown in FIG. 27A. In addition, an enlarged view of FIG. 27A is shown in FIG. 27B. As shown in FIG. 27B, it can be understood that the composite material generating holes of the present invention has new notable absorption peaks in the vicinity of 500 nm (the circle shown by a dashed line A) and 1400 nm (the circle shown by a dashed line B), as compared with the comparative sample. This suggests that vanadium oxide draws electrons from NPB, and thus, a kind of charge transfer complex is made in the composite material generating holes of the present invention. In other words, it can be considered that holes are generated in NPB and this contributes to high conductivity of the composite material.

This application is based on Japanese Patent Application serial no. 2004-353452 filed in Japan Patent Office on Dec. 6, 2004, Japanese Patent Application serial no. 2004-353449 filed in Japan Patent Office on Dec. 6, 2004 and Japanese Patent Application serial no. 2004-353450 filed in Japan Patent Office on Dec. 6, 2004, the entire contents of which are hereby incorporated by reference.

1. A composite material comprising:
an organic compound;
a binder substance; and
an inorganic compound showing an electron donating property to the organic compound.

2. A composite material comprising:
an organic compound of a high molecular weight compound; and
an inorganic compound showing an electron donating property to the organic compound.

3. The composite material according to claim 1, wherein the binder substance is polyvinyl alcohol, polymethyl methacrylate, polycarbonate, or phenol resin.

4. The composite material according to claim 1 or 2, wherein the organic compound has one or plural of a pyridine skeleton, an imidazole skeleton, a triazole skeleton, an oxadiazole skeleton, a thiadiazole skeleton, an oxazole skeleton, and a thiazole skeleton.

5. The composite material according to claim 1 or 2, wherein the inorganic compound is an oxide including an alkali metal or an alkali earth metal.

6. The composite material according to claim 1 or 2, wherein the inorganic compound is one or plural of lithium oxide, calcium oxide, and barium oxide.

7. A light-emitting element comprising:
a first layer and a second layer between a pair of electrodes,
wherein the first layer comprises a luminescent substrate, and
wherein the second layer comprises an organic compound, a binder substance and an inorganic compound showing an electron donating property to the organic compound.

8. A light-emitting element comprising:
a first layer, a second layer and a third layer, which are each stacked sequentially, between a pair of electrodes,
wherein the first layer comprises a luminescent substance,
wherein the second layer comprises an organic compound, a binder substance and an inorganic compound showing an electron donating property to the organic compound, and
wherein the third layer comprises a material generating holes.

9. A light-emitting element comprising:
a first layer and a second layer between a pair of electrodes,
wherein the first layer comprises a luminescent substrate, and
wherein the second layer comprises an organic compound of a high molecular weight compound, and an inorganic compound showing an electron donating property to the organic compound.

10. A light-emitting element comprising:
a first layer, a second layer and a third layer, which are each stacked sequentially, between a pair of electrodes,
wherein the first layer includes a luminescent substance;
wherein the second layer includes an organic compound of a high molecular weight compound, and an inorganic compound showing an electron donating property to the organic compound; and
wherein the third layer includes a material generating holes.

11. The light-emitting element according to claim 7, wherein the second layer is in contact with one electrode of the pair of electrodes.

12. The light-emitting element according to claim 9, wherein the second layer is in contact with one electrode of the pair of electrodes.

13. The light-emitting element according to claim 7 or 8, wherein the binder substance is polyvinyl alcohol, polymethyl methacrylate, polycarbonate, or phenol resin.

14. The light-emitting element according to any one of claims 7 to 10, wherein the organic compound has one or plural of a pyridine skeleton, an imidazole skeleton, a triazole skeleton, an oxadiazole skeleton, a thiadiazole skeleton, an oxazole skeleton, and a thiazole skeleton.

15. The light-emitting element according to any one of claims 7 to 10, wherein the inorganic compound is an oxide including an alkali metal or an alkali earth metal.

16. The light-emitting element according to any one of claims 7 to 10, wherein the inorganic compound is one kind or plural kinds of lithium oxide, calcium oxide, and barium oxide.

17. A light-emitting element comprising:
a first layer and a second layer between a pair of electrodes,
wherein the first layer comprises a luminescent substance, and
wherein the second layer comprises an organic compound, a binder substance and an inorganic compound showing an electron accepting property to the organic compound.

18. A light-emitting element comprising:
a first layer, a second layer, a third layer and a fourth layer, which are each stacked sequentially, between a pair of electrodes,
wherein the first layer comprises a composite material having an organic compound, a binder substance, and an inorganic compound showing an electron accepting property to the organic compound,
wherein the second layer comprises a luminescent substance,
wherein the third layer comprises a material generating electrons, and
wherein the fourth layer comprises a material generating holes.

19. A light-emitting element comprising:
a first layer, a second layer, a third layer and a fourth layer, which are each stacked sequentially, between a pair of electrodes,
wherein the first layer comprises a material generating holes,
wherein the second layer comprises a luminescent substance,
wherein the third layer comprises a material generating electrons, and
wherein the fourth layer comprises a composite material having an organic compound, a binder substance, and an inorganic compound showing an electron accepting property to the organic compound.

20. A light-emitting element comprising:
a first layer and a second layer between a pair of electrodes,
wherein the first layer comprises a luminescent substance, and
wherein the second layer comprises an organic compound of a high molecular weight compound, and an inorganic compound showing an electron accepting property to the organic compound.

21. A light-emitting element comprising:
a first layer, a second layer, a third layer and a fourth layer, which are each stacked sequentially, between a pair of electrodes;
wherein the first layer comprises a composite material having an organic compound of a high molecular weight compound, and an inorganic compound showing an electron accepting property to the organic compound,
wherein the second layer comprises a luminescent substance,
wherein the third layer comprises a material generating electrons, and
wherein the fourth layer comprises a material generating holes.

22. A light-emitting element comprising:
a first layer, a second layer, a third layer and a fourth layer, which are each stacked sequentially, between a pair of electrodes;
wherein the first layer comprises a material generating holes,
wherein the second layer comprises a luminescent substance,
wherein the third layer comprises a material generating electrons, and
wherein the fourth layer comprises a composite material having an organic compound of a high molecular weight compound, and an inorganic compound showing an electron accepting property to the organic compound.

23. The light-emitting element according to claim 17, wherein the second layer is in contact with one electrode of the pair of electrodes.

24. The light-emitting element according to claim 20, wherein the second layer is in contact with one electrode of the pair of electrodes.

25. The light-emitting element according to any one of claims 17 to 19, wherein the binder substance is polyvinyl alcohol, polymethyl methacrylate, polycarbonate, or phenol resin.

26. The light-emitting element according to any one of claims 17 to 22, wherein the organic compound includes an arylamine skeleton.

27. The light-emitting element according to any one of claims 20 to 22, wherein the organic compound is a high molecular weight compound represented by a general formula (1) 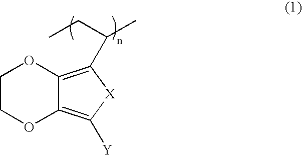
wherein X represents an oxygen atom (O) or a sulfur atom (S). Y represents a hydrogen atom, an alkyl group, an aryl group, or a silyl group having an alkyl group or an aryl group as a substituent. n is an integer of 2 or more.

28. The light-emitting element according to any one of claims 20 to 22, wherein the organic compound is a high molecular weight compound represented by a general formula (2) 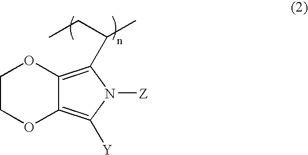
wherein Y represents a hydrogen atom, an alkyl group, an aryl group, or a silyl group having an alkyl group or an aryl group as a substituent. Z represents a hydrogen atom, an alkyl group, or a substituted or unsubstituted aryl group. n is an integer of 2 or more.

29. The light-emitting element according to any one of claims 20 to 22, wherein the organic compound is a high molecular weight compound represented by a general formula (3) 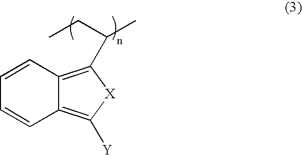
wherein X represents an oxygen atom (O) or a sulfur atom (S). Y represents a hydrogen atom, an alkyl group, an aryl group, or a silyl group having an alkyl group or an aryl group as a substituent. n is an integer of 2 or more.

30. The light-emitting element according to any one of claims 20 to 22,
wherein the organic compound is a high molecular weight compound represented by a general formula (4) 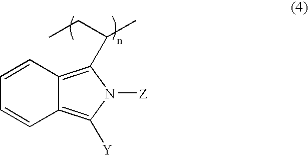
wherein Y represents a hydrogen atom, an alkyl group, an aryl group, or a silyl group having an alkyl group or an aryl group as a substituent. Z represents a hydrogen atom, an alkyl group, or a substituted or unsubstituted aryl group. n is an integer of 2 or more.

31. The light-emitting element according to any one of claims 20 to 22,
wherein the organic compound is a high molecular weight compound represented by a general formula (5) 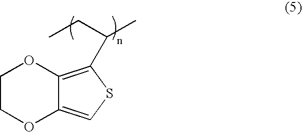
wherein n is an integer of 2 or more.

32. The light-emitting element according to any one of claims 20 to 22,
wherein the organic compound is a high molecular weight compound represented by a general formula (6) 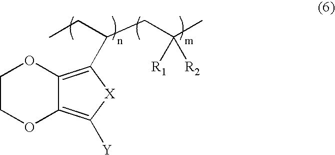
wherein X represents an oxygen atom (O) or a sulfur atom (S). Y represents a hydrogen atom, an alkyl group, an aryl group, or a silyl group having an alkyl group or an aryl group as a substituent. R₁ represents a hydrogen atom or an alkyl group. R₂ represents a substituted or unsubstituted aryl group, an ester group, a cyano group, an amide group, an alkoxy group, an oxycarbonyl alkyl group, or a diaryl amino group. n and m are individually an integer of 1 or more.

33. The light-emitting element according to any one of claims 20 to 22,
wherein the organic compound is a high molecular weight compound represented by a general formula (7) 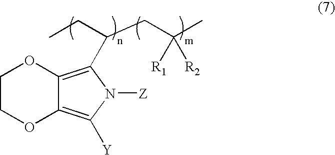
wherein Y represents a hydrogen atom, an alkyl group, an aryl group, or a silyl group having an alkyl group or an aryl group as a substituent. Z represents a hydrogen atom, an alkyl group, or a substituted or unsubstituted aryl group. R₁ represents a hydrogen atom or an alkyl group. R₂ represents a substituted or unsubstituted aryl group, an ester group, a cyano group, an amide group, an alkoxy group, an oxycarbonyl alkyl group, or a diaryl amino group. n and m are individually an integer of 1 or more.

34. The light-emitting element according to any one of claims 20 to 22, wherein the organic compound is a high molecular weight compound represented by a general formula (8) 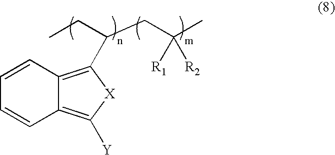
wherein X represents an oxygen atom (O) or a sulfur atom (S). Y represents a hydrogen atom, an alkyl group, an aryl group, or a silyl group having an alkyl group or an aryl group as a substituent. R₁ represents a hydrogen atom or an alkyl group. R₂ represents a substituted or unsubstituted aryl group, an ester group, a cyano group, an amide group, an alkoxy group, an oxycarbonyl alkyl group, or a diaryl amino group. n and m are individually an integer of 1 or more.

35. The light-emitting element according to any one of claims 20 to 22,
wherein the organic compound is a high molecular weight compound represented by a general formula (9) 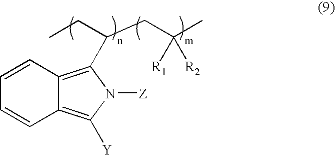
wherein Y represents a hydrogen atom, an alkyl group, an aryl group, or a silyl group having an alkyl group or an aryl group as a substituent. Z represents a hydrogen atom, an alkyl group, or a substituted or unsubstituted aryl group. R₁ represents a hydrogen atom or an alkyl group. R₂ represents a substituted or unsubstituted aryl group; an ester group, a cyano group, an amide group, an alkoxy group, an oxycarbonyl alkyl group, or a diaryl amino group. n and m are individually an integer of 1 or more.

36. The light-emitting element according to any one of claims 20 to 22,
wherein the organic compound is a high molecular weight compound represented,by a general formula (10) 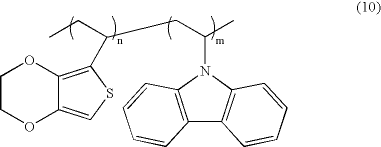
wherein n and m are individually an integer of 1 or more.

37. The light-emitting element according to any one of claims 17 to 22,
wherein the inorganic compound is an oxide containing a transition metal.

38. The light-emitting element according to any one of claims 17 to 22, wherein the inorganic compound is one or plural of titanium oxide, vanadium oxide, molybdenum oxide, tungsten oxide, rhenium oxide, and ruthenium oxide.

39. A light-emitting element comprising:
a first layer, a second layer and a third layer, which are each stacked sequentially, between a pair of electrodes,
wherein the first layer comprises a first composite material having a first organic compound, a first binder substance, and a first inorganic compound showing an electron accepting property to the first organic compound,
wherein the second layer comprises a luminescent substance, and
wherein the third layer comprises a second composite material having a second organic compound, a second binder substance, and a second inorganic compound showing an electron donating property to the second organic compound.

40. A light-emitting element comprising:
a first layer, a second layer and a third layer, which are each stacked sequentially, between a pair of electrodes,
wherein the first layer comprises a first composite material having a first organic compound of a high molecular weight compound, and a first inorganic compound showing an electron accepting property to the first organic compound,
wherein the second layer comprises a luminescent substance, and
wherein the third layer comprises a second composite material having a second organic compound, a binder substance, and a second inorganic compound showing an electron donating property to the second organic compound.

41. A light-emitting element comprising:
a first layer, a second layer and a third layer, which are each stacked sequentially, between a pair of electrodes,
wherein the first layer comprises a first composite material having a first organic compound, a binder substance, and a first inorganic compound showing an electron accepting property to the first organic compound,
wherein the second layer comprises a luminescent substance, and
wherein the third layer comprises a second composite material having a second organic compound of a high molecular weight compound, and a second inorganic compound showing an electron donating property to the second organic compound.

42. A light-emitting element comprising:
a first layer, a second layer and a third layer, which are each stacked sequentially, between a pair of electrodes,
wherein the first layer comprises a first composite material having a first organic compound of a high molecular weight compound, and a first inorganic compound showing an electron accepting property to the first organic compound,
wherein the second layer comprises a luminescent substance, and
wherein the third layer comprises a second composite material having a second organic compound of a high molecular weight compound, and a second inorganic compound showing an electron donating property to the second organic compound.

43. The light-emitting element according to claim 39, wherein the first binder substance is polyvinyl alcohol, polymethyl methacrylate, polycarbonate, or phenol resin.

44. The light-emitting element according to claim 39, wherein the second binder substance is polyvinyl alcohol, polymethyl methacrylate, polycarbonate, or phenol resin.

45. The light-emitting element according to claim 40 or 41, wherein the binder substance is polyvinyl alcohol, polymethyl methacrylate, polycarbonate, or phenol resin.

46. The light-emitting element according to any one of claims 39 to 42, wherein the first organic compound includes an arylamine skeleton.

47. The light-emitting element according to any one of claims 39 to 42, wherein the second organic compound includes one or plural of a pyridine skeleton, an imidazole skeleton, a triazole skeleton, an oxadiazole skeleton, a thiadiazole skeleton, an oxazole skeleton, and a thiazole skeleton.

48. The light-emitting element according to any one of claims 39 to 42, wherein the first inorganic compound is an oxide including a transition metal.

49. The light-emitting element according to any one of claims 39 to 42, wherein the first inorganic compound is one or plural of titanium oxide, vanadium oxide, molybdenum oxide, tungsten oxide, rhenium oxide, and ruthenium oxide.

50. The light-emitting element according to any one of claims 39 to 42, wherein the second inorganic compound is an oxide including an alkali metal or an alkali earth metal.

51. The light-emitting element according to any one of claims 39 to 42, wherein the second inorganic compound is one or plural of lithium oxide, calcium oxide, and barium oxide.

52. The light-emitting element according to any one of claims 39 to 42, the light-emitting element further comprises a fourth layer which is in contact with the third layer, and the fourth layer includes a third composite material having a third organic compound, and a third inorganic compound showing an electron accepting property to the third organic compound.

53. The light-emitting element according to claim 52, wherein the third organic compound includes an arylamine skeleton.

54. The light-emitting element according to claim 52, wherein the third inorganic compound is an oxide including a transition metal.

55. The light-emitting element according to claim 52, wherein the third inorganic compound is one or plural of titanium oxide, vanadium oxide, molybdenum oxide, tungsten oxide, rhenium oxide, and ruthenium oxide.

56. A light-emitting device having the light-emitting element according to any one of claims 1 to 55.

57. A manufacturing method of a light-emitting element, comprising the steps of:
forming a first layer including a luminescent substance over a first electrode;
forming, by a wet method, a second layer including an organic compound, and an inorganic compound showing an electron donating property to the organic compound, over the first layer; and
forming a second electrode over the second layer.

58. A manufacturing method of a light-emitting element, comprising the steps of:
forming, by a wet method, a second layer including an organic compound, and an inorganic compound showing an electron donating property to the organic compound over a second electrode;
forming a first layer including a luminescent substance over the second layer; and
forming a first electrode over the first layer.

59. The manufacturing method of a light-emitting element according to claim 57, the method further comprises a step of forming a third layer which generates holes over the second layer.

60. The manufacturing method of a light-emitting element according to claim 58, the method further comprises a step of forming a third layer which generates holes over the second electrode.

61. The manufacturing method of a light-emitting element according to claim 57 or 58, wherein the step of forming the second layer is a step in which a solution including a metal alkoxide and an organic compound is applied, and then, is baked.

62. The manufacturing method of?a light-emitting element according to claim 57 or 58, wherein the step of forming the second layer is a step in which a solution including a metal alkoxide and an organic compound is applied, is exposed to water vapor, and then, is baked.

63. The manufacturing method of a light-emitting method according to claim 61 or 62, wherein the solution includes a stabilizer additionally.

64. The manufacturing method of a light-emitting method according to claim 63, the stabilizer is β-diketone.

65. The manufacturing method of a light-emitting method according to claim 61 or 62, wherein the solution includes water additionally.

66. The manufacturing method of a light-emitting method according to claim 61 or 62, wherein the solution includes a binder substance additionally.

67. The manufacturing method of a light-emitting method according to claim 66, wherein the binder substance is polyvinyl alcohol, polymethyl methacrylate, polycarbonate, or phenol resin.

68. The manufacturing method of a light-emitting method according to claim 57 or 58, wherein the organic compound is one or plural of a pyridine skeleton, an imidazole skeleton, a triazole skeleton, an oxadiazole skeleton, a thiadiazole skeleton, an oxazole skeleton, and a thiazole skeleton.

69. The manufacturing method of a light-emitting method according to claim 61 or 62, wherein the metal is an alkali metal or an alkali earth metal.

70. The manufacturing method of a light-emitting method according to claim 61 or 62, wherein the metal is one or plural of lithium, calcium, and barium.

71. A manufacturing method of a light-emitting element, comprising the steps of:
forming, by a wet method, a first layer including an organic compound, and an inorganic compound showing an electron accepting property to the organic compound over a first electrode;
forming a second layer including a luminescent substance over the first layer; and
forming a second electrode over the second layer.

72. A manufacturing method of a light-emitting element, comprising the steps of:
forming a second layer including a luminescent substance over a second electrode;
forming, by a wet method, a first layer including an organic compound, and an inorganic compound showing an electron accepting property to the organic compound over the second layer; and
forming a first electrode over the first layer.

73. A manufacturing method of a light-emitting element comprising the steps of:
forming a first layer including a material generating holes over a first electrode;
forming a second layer including a luminescent substance over the first layer;
forming a third layer including a material generating electrons over the second layer;
forming, by a wet method, a fourth layer including an organic compound and an inorganic compound showing an electron accepting property to the organic compound over the third layer; and
forming a second electrode over the fourth layer.

74. A manufacturing method of a light-emitting element, comprising the steps of:
forming, by a wet method, a fourth layer including an organic compound, and an inorganic compound showing an electron accepting property to the organic compound over a second electrode;
forming a third layer including a material generating electrons over the fourth layer;
forming a second layer including a luminescent substance over the third layer;
forming a first layer including a material generating holes over the second layer; and
forming a first electrode over the first layer.

75. The manufacturing method of a light-emitting element according to claim 71, the method further comprises steps of forming a third layer which generates electrons over the second layer, and forming a fourth layer including a material generating holes over the third layer.

76. The manufacturing method of a light-emitting element according to claim 72, the method further comprising steps of forming a fourth layer which generates holes over the second electrode, and forming a third layer including a material generating electrons over the fourth layer.

77. The manufacturing method of a light-emitting element according to claim 71 or 72, wherein the step of forming the first layer is a step in which a solution including a metal alkoxide and an organic compound is applied, and baked.

78. The manufacturing method of a light-emitting element according to claim 71 or 72, wherein the step of forming the first layer is a step in which a solution including a metal alkoxide and an organic compound is applied, is exposed to water vapor, and then, is baked.

79. The manufacturing method of a light-emitting element according to claim 73 or 74, wherein the step of forming the fourth layer is a step in which a solution including a metal alkoxide and an organic compound is applied, and baked.

80. The manufacturing method of a light-emitting element according to claim 73 or 74, wherein the step of forming the fourth layer is a step in which a solution including a metal alkoxide and an organic compound is applied, is exposed to water vapor, and then, is baked.

81. The manufacturing method of a light-emitting element according to any one of claims 77 to 80, wherein the solution includes a stabilizer additionally.

82. The manufacturing method of a light-emitting method according to claim 81, the stabilizer is β-diketone.

83. The manufacturing method of a light-emitting method according to any one of claims 77 to 80, wherein the solution includes water additionally.

84. The manufacturing method of a light-emitting method according to claim 71 or 72, wherein the step of forming the first layer is a step in which a solution including an organic compound, and a sol obtained by deflocculating a metal hydroxide is applied and baked.

85. The manufacturing method of a light-emitting method according to claim 73 or 74, wherein the step of forming the fourth layer is a step in which a solution including an organic compound, and a sol obtained by deflocculating a second metal hydroxide is applied and baked.

86. The manufacturing method of a light-emitting element according to claim 84 or 85, wherein the solution includes a binder substance additionally.

87. The manufacturing method of a light-emitting element according to claim 77 to 80, 84 and 85, wherein the binder substance is polyvinyl alcohol, polymethyl methacrylate, polycarbonate, or phenol resin.

88. The manufacturing method of a light-emitting element according to any one of claims 71 to 74, wherein the organic compound includes an arylamine skeleton.

89. The manufacturing method of a light-emitting element according to any one of claims 71 to 74, wherein the organic compound is a high molecular weight compound represented by a general formula (1) 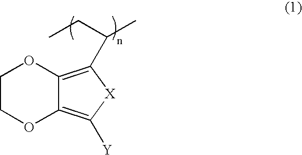
wherein X represents an oxygen atom (O) or a sulfur atom (S). Y represents a hydrogen atom, an alkyl group, an aryl group, or a silyl group having an alkyl group or an aryl group as a substituent. n is an integer of 2 or more.

90. The manufacturing method of a light-emitting element according to any one of claims 71 to 74, wherein the organic compound is a high molecular weight compound represented by a general formula (2) 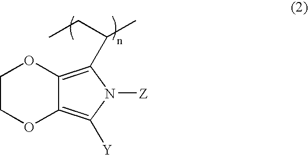
wherein Y represents a hydrogen atom, an alkyl group, an aryl group, or a silyl group having an alkyl group or an aryl group as a substituent. Z represents a hydrogen atom, an alkyl group, or a substituted or unsubstituted aryl group. n is an integer of 2 or more.

91. The manufacturing method of a light-emitting element according to any one of claims 71 to 74, wherein the organic compound is a high molecular weight compound represented by a general formula (3) 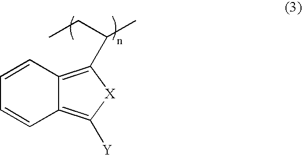
wherein X represents an oxygen atom (O) or a sulfur atom (S). Y represents a hydrogen atom, an alkyl group, an aryl group, or a silyl group having an alkyl group or an aryl group as a substituent. n is an integer of 2 or more.

92. The manufacturing method of a light-emitting element according to any one of claims 71 to 74, wherein the organic compound is a high molecular weight compound represented by a general formula (4) 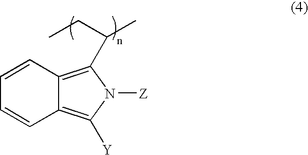
wherein Y represents a hydrogen atom, an alkyl group, an aryl group, or a silyl group having an alkyl group or an aryl group as a substituent. Z represents a hydrogen atom, an alkyl group, or a substituted or unsubstituted aryl group. n is an integer of 2 or more.

93. The manufacturing method of a light-emitting element according to any one of claims 71 to 74, wherein the organic compound is a high molecular weight compound represented by a general formula (5) 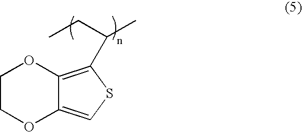
wherein n is an integer of 2 or more.

94. The manufacturing method of a light-emitting element according to any one of claims 71 to 74, wherein the organic compound is a high molecular weight compound represented by a general formula (6) 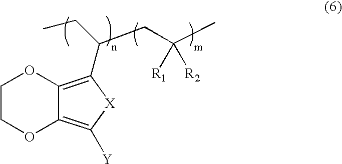
wherein X represents an oxygen atom (O) or a sulfur atom (S). Y represents a hydrogen atom, an alkyl group, an aryl group, or a silyl group having an alkyl group or an aryl group as a substituent. R₁ represents a hydrogen atom or an alkyl group. R₂ represents a substituted or unsubstituted aryl group, an ester group, a cyano group, an amide group, an alkoxy group, an oxycarbonyl alkyl group, or a diaryl amino group. n and m are individually an integer of 1 or more.

95. The manufacturing method of a light-emitting element according to any one of claims 71 to 74, wherein the organic compound is a high molecular weight compound represented by a general formula (7) 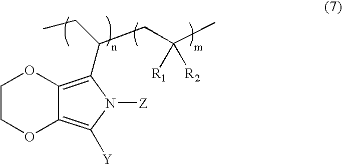
wherein Y represents a hydrogen atom, an alkyl group, an aryl group, or a silyl group having an alkyl group or an aryl group as a substituent. Z represents a hydrogen atom, an alkyl group, or a substituted or unsubstituted aryl group. R₁ represents a hydrogen atom or an alkyl group. R₂ represents a substituted or unsubstituted aryl group, an ester group, a cyano group, an amide group, an alkoxy group, an oxycarbonyl alkyl group, or a diaryl amino group. n and m are individually an integer of 1 or more.

96. The manufacturing method of a light-emitting element according to any one of claims 71 to 74, wherein the organic compound is a high molecular weight compound represented by a general formula (8) 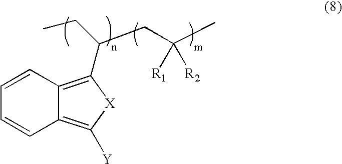
wherein X represents an oxygen atom (O) or a sulfur atom (S). Y represents a hydrogen atom, an alkyl group, an aryl group, or a silyl group having an alkyl group or an aryl group as a substituent. R₁ represents a hydrogen atom or an alkyl group. R₂ represents a substituted or unsubstituted aryl group, an ester group, a cyano group, an amide group, an alkoxy group, an oxycarbonyl alkyl group, or a diaryl amino group. n and m are individually an integer of 1 or more.

97. The manufacturing method of a light-emitting element according to any one of claims 71 to 74, wherein the organic compound is a high molecular weight compound represented by a general formula (9) 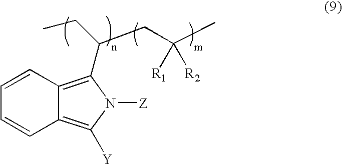
wherein Y represents a hydrogen atom, an alkyl group, an aryl group, or a silyl group having an alkyl group or an aryl group as a substituent. Z represents a hydrogen atom, an alkyl group, or a substituted or unsubstituted aryl group. R₁ represents a hydrogen atom or an alkyl group. R₂ represents a substituted or unsubstituted aryl group, an ester group, a cyano group, an amide group, an alkoxy group, an oxycarbonyl alkyl group, or a diaryl amino group. n and m are individually an integer of 1 or more.

98. The manufacturing method of a light-emitting element according to any one of claims 71 to 74, wherein the organic compound is a high molecular weight compound represented by a general formula (10) 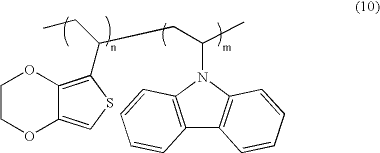
wherein n and m are individually an integer of 1 or more.

99. The manufacturing method of a light-emitting element according to any one of claims 77 to 80, 84 and 85, wherein the metal is a transition metal.

100. The manufacturing method of a light-emitting element according to any one of claims 77 to 80, 84 and 85, wherein the metal is one or plural of titanium, vanadium, molybdenum, tungsten, rhenium, and ruthenium.

101. A manufacturing method of a light-emitting element, comprising the steps of:
forming, by a wet method, a layer including a first organic compound and a first inorganic compound showing an electron accepting property to the first organic compound over a first electrode;
forming a second layer including a luminescent substance over the first layer;
forming, by a wet method, a third layer including a second organic compound, and a second inorganic compound showing an electron donating property to the second organic compound over the second layer; and
forming a second electrode over the third layer.

102. A manufacturing method of a light-emitting element, comprising the steps of:
forming, by a wet method, a third layer including a second organic compound and a second inorganic compound showing an electron donating property to the second organic compound over a second electrode;
forming a second layer including a luminescent substance over the third layer;
forming, by a wet method, a first layer including a first organic compound, and a first inorganic compound showing an electron accepting property to the first organic compound over the second layer; and
forming a first electrode over the first layer.

103. The manufacturing method of a light-emitting element according to claim 101, the method further comprises a step of forming a fourth layer including a third organic compound and a third inorganic compound showing an electron accepting property to the third organic compound over the third layer.

104. The manufacturing method of a light-emitting element according to claim 102, the method further comprises a step of forming a fourth layer including a third organic compound and a third inorganic compound showing an electron accepting property to the third organic compound over the second electrode.

105. The manufacturing method of a light-emitting element according to claim 103, wherein the step of forming the fourth layer is conducted by a wet method.

106. The manufacturing method of a light-emitting element according to claim 104, wherein the step of forming the fourth layer is conducted by a wet method.

107. The manufacturing method of a light-emitting element according to claim 103 or 104, wherein the step of forming the fourth layer is a step in which a third solution including a third metal alkoxide and a third organic compound is applied and baked.

108. The manufacturing method of a light-emitting element according to claim 103 or 104, wherein the step of forming the fourth layer is a step in which a third solution including a third metal alkoxide and a third organic compound is applied, exposed to water vapor and baked.

109. The manufacturing method of a light-emitting element according to claim 107 or 108, wherein the third solution includes a stabilizer additionally.

110. The manufacturing method of a light-emitting element according to claim 109, the stabilizer is β-diketone.

111. The manufacturing method of a light-emitting element according to claim 107 or 108, wherein the third solution includes water additionally.

112. The manufacturing method of a light-emitting element according to claim 103 or 104, wherein the step of forming the fourth layer is a step in which a solution including the third organic compound, and a sol obtained by deflocculating a third metal hydroxide is applied and baked.

113. The manufacturing method of a light-emitting element according to any one of claims 107, 108 and 112, wherein the third solution includes a binder substance additionally.

114. The manufacturing method of a light-emitting element according to claim 113, wherein the binder substance is polyvinyl alcohol, polymethyl methacrylate, polycarbonate, or phenol resin.

115. The manufacturing method of a light-emitting element according to any one of claims 107, 108 and 112, wherein the third organic compound includes an arylamine skeleton.

116. The manufacturing method of a light-emitting element according to any one of claims 107, 108 and 112, wherein the third metal is a transition metal.

117. The manufacturing method of a light-emitting element according to any one of claims 107, 108 and 112, wherein the third metal is one or plural of titanium, vanadium, molybdenum, tungsten, rhenium, and ruthenium.

118. The manufacturing method of a light-emitting element according to claim 101 or 102, wherein the step of forming the first layer is a step in which a first solution including a first metal alkoxide and the first organic compound is applied and baked.

119. The manufacturing method of a light-emitting element according to claim 101 or 102, wherein the step of forming the first layer is a step in which a first solution including a first metal alkoxide and the first organic compound is applied, exposed to water vapor and baked.

120. The manufacturing method of a light-emitting element according to claim 118 or 119, wherein the first solution includes a stabilizer additionally.

121. The manufacturing method of a light-emitting element according to claim 120, wherein the stabilizer is β-diketone.

122. The manufacturing method of a light-emitting element according to claim 118 or 119, wherein the first solution includes water additionally.

123. The manufacturing method of a light-emitting element according to claim 101 or 102, wherein the step of forming the first layer is a step in which the first solution including the first organic compound and a sol obtained by deflocculating a first metal hydroxide is applied and baked.

124. The manufacturing method of a light-emitting element according to any one of claims 118, 119 and 123, wherein the first solution includes a binder substance additionally.

125. The manufacturing method of a light-emitting element according to claim 124, wherein the binder substance is polyvinyl alcohol, polymethyl methacrylate, polycarbonate, or phenol resin.

126. The manufacturing method of a light-emitting element according to any one of claims 118, 119 and 123, wherein the first metal is a transition metal.

127. The manufacturing method of a light-emitting element according to any one of claims 118, 119 and 123, wherein the first metal is one or plural of titanium, vanadium, molybdenum, tungsten, rhenium, and ruthenium.

128. The manufacturing method of a light-emitting element according to claim 101 or 102, wherein the step of forming the third layer is a step in which a second solution including a second alkoxide and the second organic compound is applied, and baked.

129. The manufacturing method of a light-emitting element according to claim 101 or 102, wherein the step of forming the third layer is a step in which a second solution including a second alkoxide and the second organic compound is applied, exposed to water vapor and baked.

130. The manufacturing method of a light-emitting element according to claim 128 or 129, wherein the second solution includes a stabilizer additionally.

131. The manufacturing method of a light-emitting element according to claim 130, wherein the stabilizer is β-diketone.

132. The manufacturing method of a light-emitting element according to claim 128 or 129, wherein the second solution includes water additionally.

133. The manufacturing method of a light-emitting element according to claim 128 or 129, wherein the second solution includes a binder substance additionally.

134. The manufacturing method of a light-emitting element according to claim 133, wherein the binder substance is polyvinyl alcohol, polymethyl methacrylate, polycarbonate, or phenol resin.

135. The manufacturing method of a light-emitting element according to claim 128 or 129, wherein the second metal is an alkali metal or an alkali earth metal.

136. The manufacturing method of a light-emitting element according to claim 128 or 129, wherein the second metal is one or plural of lithium, calcium, and barium.

137. The manufacturing method of a light-emitting element according to claim 101 or 102, wherein the first organic compound includes an arylamine skeleton.

138. The manufacturing method of a light-emitting element according to claim 101 or 102, wherein the second organic compound includes one or plural of a pyridine skeleton, an imidazole skeleton, a triazole skeleton, an oxadiazole skeleton, a thiadiazole skeleton, an oxazole skeleton, and a thiazole skeleton.

139. The light-emitting element according to claim 40 or 42, wherein the first organic compound is a high molecular weight compound represented by a general formula (1) 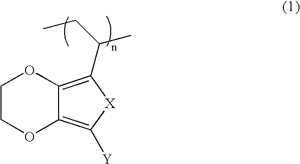
wherein X represents an oxygen atom (O) or a sulfur atom (S). Y represents a hydrogen atom, an alkyl group, an aryl group, or a silyl group having an alkyl group or an aryl group as a substituent. n is an integer of 2 or more.

140. The light-emitting element according to claim 40 or 42, wherein the first organic compound is a high molecular weight compound represented by a general formula (2) 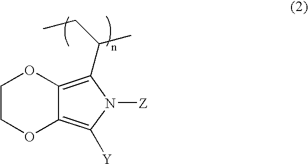
wherein Y represents a hydrogen atom, an alkyl group, an aryl group, or a silyl group having an alkyl group or an aryl group as a substituent. Z represents a hydrogen atom, an alkyl group, or a substituted or unsubstituted aryl group. n is an integer of 2 or more.

141. The light-emitting element according to claim 40 or 42, wherein the first organic compound is a high molecular weight compound represented by a general formula (3) 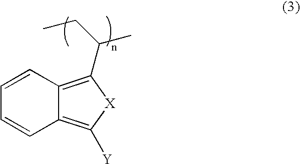
wherein X represents an oxygen atom (O) or a sulfur atom (S). Y represents a hydrogen atom, an alkyl group, an aryl group, or a silyl group having an alkyl group or an aryl group as a substituent. n is an integer of 2 or more.

142. The light-emitting element according to claim 40 or 42, wherein the first organic compound is a high molecular weight compound represented by a general formula (4) 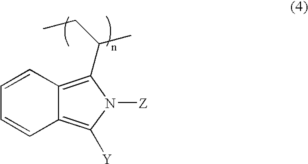
wherein Y represents a hydrogen atom, an alkyl group, an aryl group, or a silyl group having an alkyl group or an aryl group as a substituent. Z represents a hydrogen atom, an alkyl group, or a substituted or unsubstituted aryl group. n is an integer of 2 or more.

143. The light-emitting element according to claim 40 or 42, wherein the first organic compound is a high molecular weight compound represented by a general formula (5) 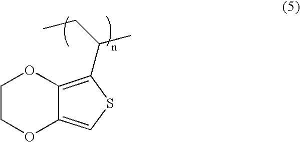
wherein n is an integer of 2 or more.

144. The light-emitting element according to claim 40 or 42, wherein the first organic compound is a high molecular weight compound represented by a general formula (6) 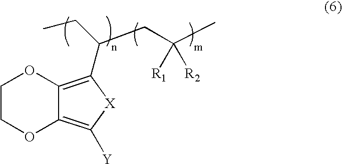
wherein X represents an oxygen atom (O) or a sulfur atom (S). Y represents a hydrogen atom, an alkyl group, an aryl group, or a silyl group having an alkyl group or an aryl group as a substituent. R₁ represents a hydrogen atom or an alkyl group. R₂ represents a substituted or unsubstituted aryl group, an ester group, a cyano group, an amide group, an alkoxy group, an oxycarbonyl alkyl group, or a diaryl amino group. n and m are individually an integer of 1 or more.

145. The light-emitting element according to claim 40 or 42, wherein the first organic compound is a high molecular weight compound represented by a general formula (7) 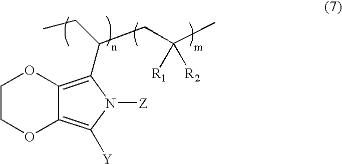
wherein Y represents a hydrogen atom, an alkyl group, an aryl group, or a silyl group having an alkyl group or an aryl group as a substituent. Z represents a hydrogen atom, an alkyl group, or a substituted or unsubstituted aryl group. R₁ represents a hydrogen atom or an alkyl group. R₂ represents a substituted or unsubstituted aryl group, an ester group, a cyano group, an amide group, an alkoxy group, an oxycarbonyl alkyl group, or a diaryl amino group. n and m are individually an integer of 1 or more.

146. The light-emitting element according to claim 40 or 42, wherein the first organic compound is a high molecular weight compound represented by a general formula (8) 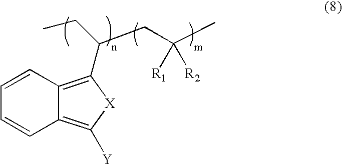
wherein X represents an oxygen atom (O) or a sulfur atom (S). Y represents a hydrogen atom, an alkyl group, an aryl group, or a silyl group having an alkyl group or an aryl group as a substituent. R₁ represents a hydrogen atom or an alkyl group. R₂ represents a substituted or unsubstituted aryl group, an ester group, a cyano group, an amide group, an alkoxy group, an oxycarbonyl alkyl group, or a diaryl amino group. n and m are individually an integer of 1 or more.

147. The light-emitting element according to claim 40 or 42, wherein the first organic compound is a high molecular weight compound represented by a general formula (9) 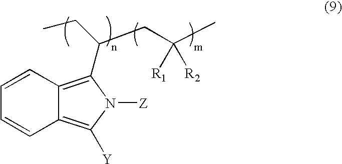
wherein Y represents a hydrogen atom, an alkyl group, an aryl group, or a silyl group having an alkyl group or an aryl group as a substituent. Z represents a hydrogen atom, an alkyl group, or a substituted or unsubstituted aryl group. R₁ represents a hydrogen atom or an alkyl group. R₂ represents a substituted or unsubstituted aryl group, an ester group, a cyano group, an amide group, an alkoxy group, an oxycarbonyl alkyl group, or a diaryl amino group. n and m are individually an integer of 1 or more.

148. The light-emitting element according to claim 40 or 42, wherein the first organic compound is a high molecular weight compound represented by a general formula (10) 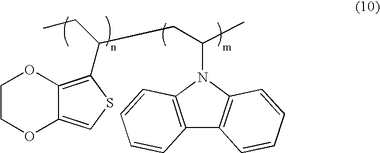
wherein n and m are individually an integer of 1 or more.

149. The manufacturing method of a light-emitting element according to claim 101 or 102, wherein the first organic compound is a high molecular weight compound represented by a general formula (1) 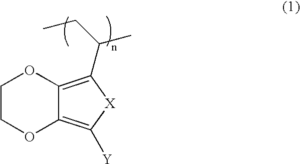
wherein X represents an oxygen atom (O) or a sulfur atom (S). Y represents a hydrogen atom, an alkyl group, an aryl group, or a silyl group having an alkyl group or an aryl group as a substituent. n is an integer of 2 or more.

150. The manufacturing method of a light-emitting element according to claim 101 or 102, wherein the first organic compound is a high molecular weight compound represented by a general formula (2) 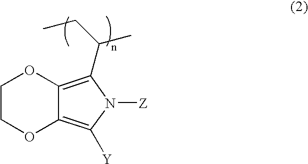
wherein Y represents a hydrogen atom, an alkyl group, an aryl group, or a silyl group having an alkyl group or an aryl group as a substituent. Z represents a hydrogen atom, an alkyl group, or a substituted or unsubstituted aryl group. n is an integer of 2 or more.

151. The manufacturing method of a light-emitting element according to claim 101 or 102, wherein the first organic compound is a high molecular weight compound represented by a general formula (3) 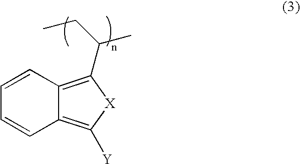
wherein X represents an oxygen atom (O) or a sulfur atom (S). Y represents a hydrogen atom, an alkyl group, an aryl group, or a silyl group having an alkyl group or an aryl group as a substituent. n is an integer of 2 or more.

152. The manufacturing method of a light-emitting element according to claim 101 or 102, wherein the first organic compound is a high molecular weight compound represented by a general formula (4) 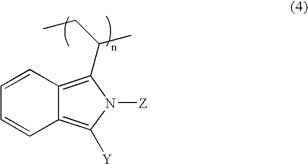
wherein Y represents a hydrogen atom, an alkyl group, an aryl group, or a silyl group having an alkyl group or an aryl group as a substituent. Z represents a hydrogen atom, an alkyl group, or a substituted or unsubstituted aryl group. n is an integer of 2 or more.

153. The manufacturing method of a light-emitting element according to claim 101 or 102, wherein the first organic compound is a high molecular weight compound represented by a general formula (5) 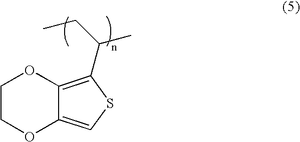
wherein n is an integer of 2 or more.

154. The manufacturing method of a light-emitting element according to claim 101 or 102, wherein the first organic compound is a high molecular weight compound represented by a general formula (6) 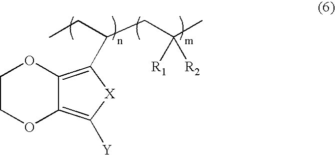
wherein X represents an oxygen atom (O) or a sulfur atom (S). Y represents a hydrogen atom, an alkyl group, an aryl group, or a silyl group having an alkyl group or an aryl group as a substituent. R₁ represents a hydrogen atom or an alkyl group. R₂ represents a substituted or unsubstituted aryl group, an ester group, a cyano group, an amide group, an alkoxy group, an oxycarbonyl alkyl group, or a diaryl amino group. n and m are individually an integer of 1 or more.

155. The manufacturing method of a light-emitting element according to claim 101 or 102, wherein the first organic compound is a high molecular weight compound represented by a general formula (7) 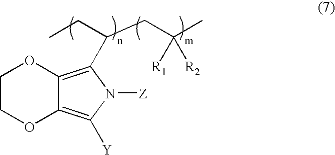
wherein Y represents a hydrogen atom, an alkyl group, an aryl group, or a silyl group having an alkyl group or an aryl group as a substituent. Z represents a hydrogen atom, an alkyl group, or a substituted or unsubstituted aryl group. R₁ represents a hydrogen atom or an alkyl group. R₂ represents a substituted or unsubstituted aryl group, an ester group, a cyano group, an amide group, an alkoxy group, an oxycarbonyl alkyl group, or a diaryl amino group. n and m are individually an integer of 1 or more.

156. The manufacturing method of a light-emitting element according to claim 101 or 102, wherein the first organic compound is a high molecular weight compound represented by a general formula (8) 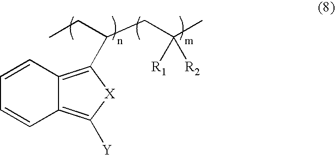
wherein X represents an oxygen atom (O) or a sulfur atom (S). Y represents a hydrogen atom, an alkyl group, an aryl group, or a silyl group having an alkyl group or an aryl group as a substituent. R₁ represents a hydrogen atom or an alkyl group. R₂ represents a substituted or unsubstituted aryl group, an ester group, a cyano group, an amide group, an alkoxy group, an oxycarbonyl alkyl group, or a diaryl amino group. n and m are individually an integer of 1 or more.

157. The manufacturing method of a light-emitting element according to claim 101 or 102, wherein the first organic compound is a high molecular weight compound represented by a general formula (9) 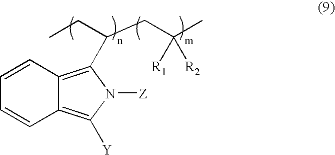
wherein Y represents a hydrogen atom, an alkyl group, an aryl group, or a silyl group having an alkyl group or an aryl group as a substituent. Z represents a hydrogen atom, an alkyl group, or a substituted or unsubstituted aryl group. R₁ represents a hydrogen atom or an alkyl group. R₂ represents a substituted or unsubstituted aryl group, an ester group, a cyano group, an amide group, an alkoxy group, an oxycarbonyl alkyl group, or a diaryl amino group. n and m are individually an integer of 1 or more.

158. The manufacturing method of a light-emitting element according to claim 101 or 102, wherein the first organic compound is a high molecular weight compound represented by a general formula (10) 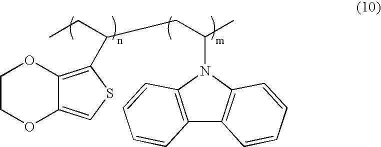
wherein n and m are individually an integer of 1 or more.
